(19) United States
(12) Patent Application Publication
(10) Pub. No.: US 2023/0263047 A1
(43) Pub. Date: Aug. 17, 2023

(54) LIGHT EMITTING ELEMENT AND POLYCYCLIC COMPOUND FOR LIGHT EMITTING ELEMENT

(71) Applicant: Samsung Display Co., Ltd., Yongin-si (KR)

(72) Inventors: Yoshiro SUGITA, Yokohama (JP); Keigo HOSHI, Yokohama (JP); Ryuhei FURUE, Yokohama (JP)

(21) Appl. No.: 17/988,637

(22) Filed: Nov. 16, 2022

(30) Foreign Application Priority Data
Jan. 4, 2022 (KR) 10-2022-0001170

(51) Int. Cl. H01L 51/00; C07F 5/02; C09K 11/06

(52) U.S. Cl. CPC H01L 51/008; C07F 5/027; C09K 11/06; H01L 51/5012

(57) ABSTRACT

A light emitting element includes a first electrode, a second electrode, and an emission layer disposed between the first electrode and the second electrode and including a polycyclic compound represented by Formula 1 below, thereby showing high emission efficiency. The substituents of Formula 1 are the same as defined in the detailed descriptions.

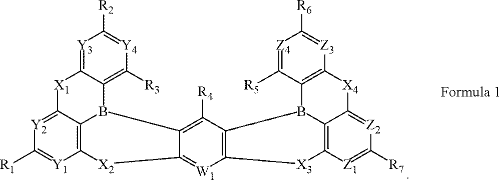

### CROSS-REFERENCE TO RELATED APPLICATION

This application claims priority to and the benefit of Korean Patent Application No. 10-2022-0001170, filed on Jan. 4, 2022, the entire content of which is hereby incorporated by reference.

### BACKGROUND

The present disclosure herein relates to a light emitting element and a polycyclic compound for a light emitting element, and for example, to a light emitting element including a polycyclic compound in an emission layer and a polycyclic compound utilized therein.

Recently, the development of an organic electroluminescence display device as an image display device is being actively conducted. The organic electroluminescence display is different from a liquid crystal display and is a so-called self-luminescent display, in which holes and electrons injected from a first electrode and a second electrode recombine in an emission layer so that a light emitting material in the emission layer can emit light to achieve display (e.g., to display an image).

In the application of a light emitting element to a display device, the decrease of a driving voltage and the increase of an emission efficiency and a lifespan of the light emitting element are desirable or required, and development on materials for a light emitting element capable of stably achieving the requirements is being continuously pursued.

### SUMMARY

Aspects according to embodiments of the present disclosure are directed toward a light emitting element with high emission efficiency properties and a polycyclic compound utilized therein.

According to embodiments of the present disclosure, a light emitting element includes a first electrode, a second electrode on the first electrode, and an emission layer between the first electrode and the second electrode and including a first compound represented by Formula 1, and at least one selected from among a second compound to a fourth compound, wherein the first compound to the fourth compound are different from each other.

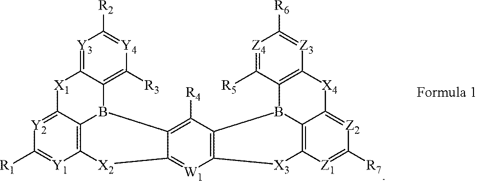

In Formula 1, R₁ to R₇ may each independently be a hydrogen atom, a deuterium atom, a substituted or unsubstituted oxy group, a substituted or unsubstituted thio group, a substituted or unsubstituted amino group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or combined with an adjacent group to form a ring, X₁ to X₄ may each independently be CRₐR_{b}, or NR_{c}, a case where X₁ to X₄ are all CRₐR_{b} is excluded, at least one selected from among Y₁ to Y₄, Z₁ to Z₄, and W₁ is N, and the remainder of Y₁ to Y₄, Z₁ to Z₄, and W₁ are each independently CR_{d}, when W₁ is CR_{d}, a case where Y₁ and Z₁ are N at the same time, a case where Y₂ and Z₂ are N at the same time, a case where Y₃ and Z₃ are N at the same time, and a case where Y₄ and Z₄ are N at the same time are excluded, and Rₐ to R_{d} may each independently be a hydrogen atom, a deuterium atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or combined with an adjacent group to form a ring.

In an embodiment, the first compound represented by Formula 1 may be represented by Formula 2-1 or Formula 2-2.

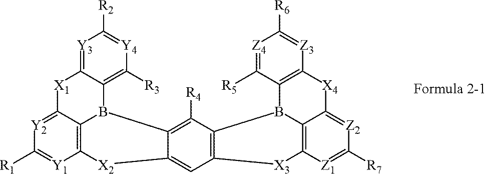

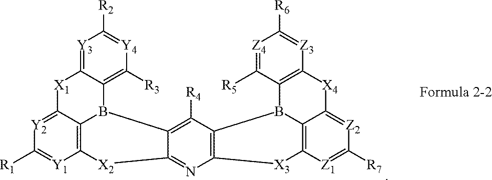

In Formula 2-1 and Formula 2-2, X₁ to X₄, Y₁ to Y₄, Z₁ to Z₄, and R₁ to R₇ may each independently be the same as defined in Formula 1.

In an embodiment,

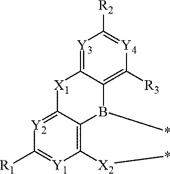

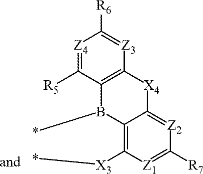

in Formula 2-1 may be different from each other.

In an embodiment, X₁ and X₄ in Formula 1 may be different from each other.

In an embodiment, the first compound represented by Formula 1 may be represented by Formula 3.

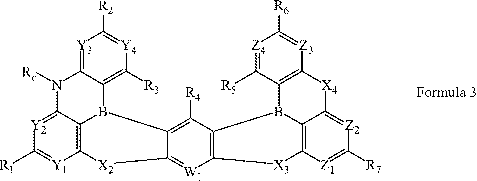

In Formula 3, W₁, X₂ to X₄, Y₁ to Y₄, Z₁ to Z₄, R₁ to R₇, and R_{c} may each independently be the same as defined in Formula 1.

In an embodiment, X₂ and X₃ in Formula 1 may be different from each other.

In an embodiment, the first compound represented by Formula 1 may be represented by Formula 4.

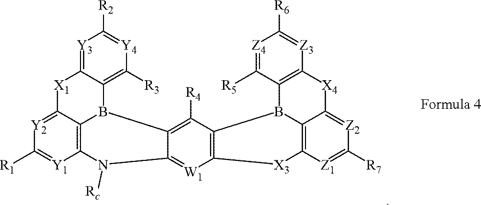

In Formula 4, W₁, X₁, X₂, X₄, Y₁ to Y₄, Z₁ to Z₄, R₁ to R₇, and R_{c} may each independently be the same as defined in Formula 1.

In an embodiment, the emission layer may be to emit blue light.

In an embodiment, the first compound may be to emit thermally activated delayed fluorescence.

In an embodiment, the emission layer may include the second compound and the third compound, and the second compound may be represented by any one selected from among HT-1 to HT-4.

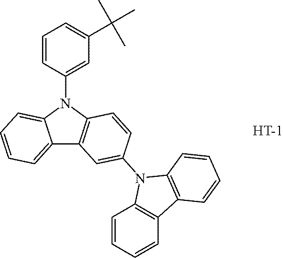 [SMILES: CC(C)(C)c1cccc(-n2c3ccccc3c3cc(-n4c5ccccc5c5ccccc54)ccc32)c1]

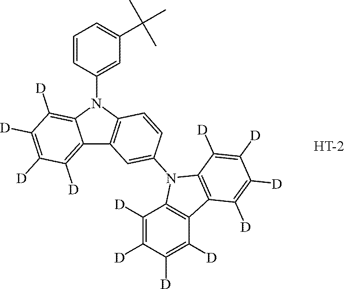 [SMILES: [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1]

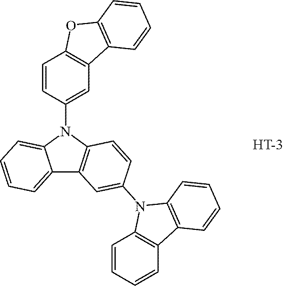 [SMILES: c1ccc2c(c1)oc1ccc(-n3c4ccccc4c4cc(-n5c6ccccc6c6ccccc65)ccc43)cc12]

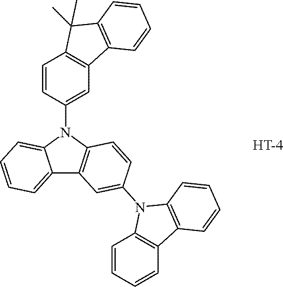 [SMILES: CC1(C)c2ccccc2-c2cc(-n3c4ccccc4c4cc(-n5c6ccccc6c6ccccc65)ccc43)ccc21]

In an embodiment, the third compound may be represented by any one selected from among ET-1 to ET-3.

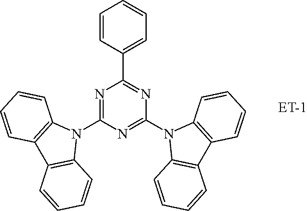 [SMILES: c1ccc(-c2nc(-n3c4ccccc4c4ccccc43)nc(-n3c4ccccc4c4ccccc43)n2)cc1]

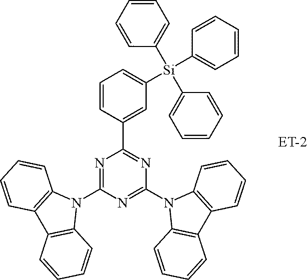 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1]

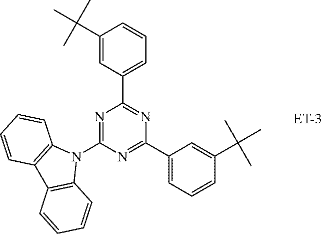 [SMILES: CC(C)(C)c1cccc(-c2nc(-c3cccc(C(C)(C)C)c3)nc(-n3c4ccccc4c4ccccc43)n2)c1]

In an embodiment, the emission layer may further include the fourth compound, and the fourth compound may be represented by Formula M-b.

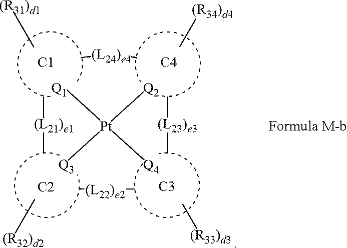

In Formula M-b, Q₁ to Q₄ may each independently be C or N, C1 to C4 may each independently be a substituted or unsubstituted hydrocarbon ring having 5 to 30 ring-forming carbon atoms, or a substituted or unsubstituted heterocycle having 2 to 30 ring-forming carbon atoms, L₂₁ to L₂₄ may each independently be a direct linkage,

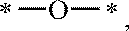

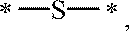

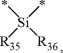

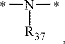

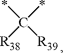

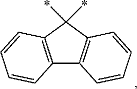

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, e1 to e4 may each independently be 0 or 1, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or combined with an adjacent group to form a ring, and d1 to d4 may each independently be an integer of 0 to 4.

In an embodiment, the first compound may be a light emitting dopant, the second compound may be a hole transport host, the third compound may be an electron transport host, and the fourth compound may be an auxiliary dopant.

According to another embodiment of the present disclosure, a polycyclic compound is represented by Formula 1.

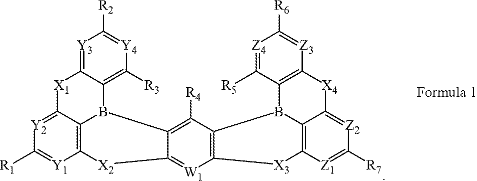

In Formula 1, R₁ to R₇ may each independently be a hydrogen atom, a deuterium atom, a substituted or unsubstituted oxy group, a substituted or unsubstituted thio group, a substituted or unsubstituted amino group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or combined with an adjacent group to form a ring, X₁ to X₄ may each independently be CRₐR_{b}, or NR_{c}, a case where X₁ to X₄ are all CRₐR_{b} is excluded, at least one selected from among Y₁ to Y₄, Z₁ to Z₄, and W₁ is N, and the remainder of Y₁ to Y₄, Z₁ to Z₄, and W₁ are each independently CR_{d}, when W₁ is CR_{d}, a case where Y₁ and Z₁ are N at the same time, a case where Y₂ and Z₂ are N at the same time, a case where Y₃ and Z₃ are N at the same time, and a case where Y₄ and Z₄ are N at the same time are excluded, and Rₐ to R_{d} may each independently be a hydrogen atom, a deuterium atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or combined with an adjacent group to form a ring.

In an embodiment, the first compound represented by Formula 1 may be represented by Formula 2-1 or Formula 2-2.

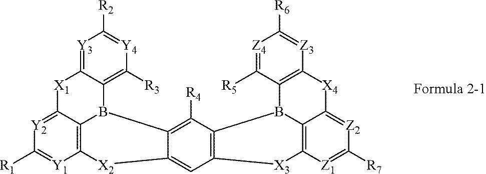

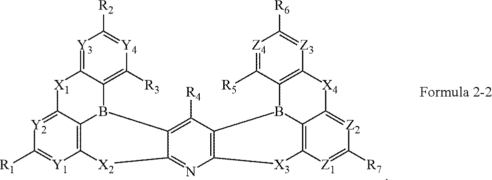

In Formula 2-1 and Formula 2-2, X₁ to X₄, Y₁ to Y₄, Z₁ to Z₄, and R₁ to R₇ may each independently be the same as defined in Formula 1.

In an embodiment,

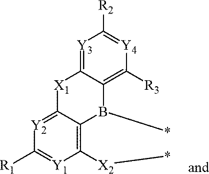

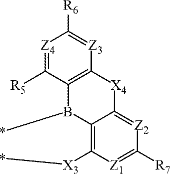

in Formula 2-1 may be different from each other.

In an embodiment, the first compound represented by Formula 1 may be represented by Formula 3.

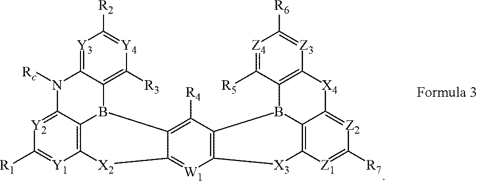

In Formula 3, W₁, X₂ to X₄, Y₁ to Y₄, Z₁ to Z₄, R₁ to R₇, and R_{c} may each independently be the same as defined in Formula 1.

In an embodiment, the first compound represented by Formula 1 may be represented by Formula 4.

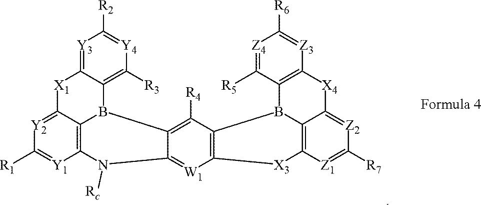

In Formula 4, W₁, X₁, X₂, X₄, Y₁ to Y₄, Z₁ to Z₄, R₁ to R₇, and R_{c} may each independently be the same as defined in Formula 1.

### BRIEF DESCRIPTION OF THE FIGURES

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIG. 1 is a plan view showing a display apparatus according to an embodiment;

FIG. 2 is a cross-sectional view showing a display apparatus according to an embodiment;

FIG. 3 is a cross-sectional view schematically showing a light emitting element according to an embodiment;

FIG. 4 is a cross-sectional view schematically showing a light emitting element according to an embodiment;

FIG. 5 is a cross-sectional view schematically showing a light emitting element according to an embodiment;

FIG. 6 is a cross-sectional view schematically showing a light emitting element according to an embodiment;

FIG. 7 is a cross-sectional view of a display apparatus according to an embodiment;

FIG. 8 is a cross-sectional view of a display apparatus according to an embodiment;

FIG. 9 is a cross-sectional view of a display apparatus according to an embodiment; and

FIG. 10 is a cross-sectional view of a display apparatus according to an embodiment.

### DETAILED DESCRIPTION

The present disclosure may have one or more suitable modifications and may be embodied in different forms, and example embodiments will be explained in more detail with reference to the accompany drawings. The present disclosure may, however, be embodied in different forms and should not be construed as limited to the embodiments set forth herein. Rather, all modifications, equivalents, and substituents which are included in the spirit and technical scope of the present disclosure should be included in the present disclosure.

Like reference numerals refer to like elements throughout, and duplicative descriptions thereof may not be provided. In the drawings, the dimensions of structures may be exaggerated for clarity of illustration. It will be understood that, although the terms first, second, etc. may be used herein to describe various elements, these elements should not be limited by these terms. These terms are only used to distinguish one element from another element. Thus, a first element could be termed a second element without departing from the teachings of the present disclosure. Similarly, a second element could be termed a first element. As used herein, the singular forms are intended to include the plural forms as well, unless the context clearly indicates otherwise.

In the description, it will be further understood that the terms “comprises” and/or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

In the description, when a layer, a film, a region, a plate, etc. is referred to as being “on” or “above” another part, it can be “directly on” the other part, or intervening layer(s) may also be present. In contrast, when a layer, a film, a region, a plate, etc. is referred to as being “under” or “below” another part, it can be “directly under” the other part, or intervening layer(s) may also be present. Also, when an element is referred to as being disposed “on” another element, it can be disposed under the other element.

In the description, the term “substituted or unsubstituted” corresponds to an unsubstituted group or a group substituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In addition, each of the example substituents may be substituted or unsubstituted. For example, a biphenyl group may be interpreted as an aryl group or a phenyl group substituted with a phenyl group.

In the description, the term “forming a ring via the combination with an adjacent group” may refer to forming a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocycles or polycycles. In addition, the ring formed via the combination with an adjacent group may be combined with another ring to form a spiro structure.

In the description, the term “adjacent group” may refer to a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. In addition, in 4,5-dimethylphenanthrene, two methyl groups may be interpreted as “adjacent groups” to each other.

In the description, a halogen atom may be a fluorine atom, a chlorine atom, a bromine atom or an iodine atom.

In the description, an alkyl group may be a linear, branched, or cyclic alkyl group. The number of carbon atoms in the alkyl group may be 1 to 50, 1 to 30, 1 to 20, 1 to 10, or 1 to 6. Non-limiting examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc.

In the description, a cycloalkyl group may refer to a ring-type or kind alkyl group. The number of carbon atoms in the cycloalkyl group may be 3 to 50, 3 to 30, 3 to 20, or 3 to 10. Non-limiting examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc.

In the description, an alkenyl group refers to a hydrocarbon group including one or more carbon double bonds in the middle or at the terminal of an alkyl group having a carbon number of 2 or more. The alkenyl group may be a linear chain or a branched chain. The number of carbon atoms is not specifically limited, but may be 2 to 30, 2 to 20, or 2 to 10. Non-limiting examples of the alkenyl group may include a vinyl group, a 1-butenyl group, a 1-pentenyl group, a 1,3-butadienyl aryl group, a styrenyl group, a styrylvinyl group, etc.

In the description, an alkynyl group refers to a hydrocarbon group including one or more carbon triple bonds in the middle or at the terminal of an alkyl group having a carbon number of 2 or more. The alkynyl group may be a linear chain or a branched chain. The number of carbon atoms is not specifically limited, but may be 2 to 30, 2 to 20, or 2 to 10. Non-limiting examples of the alkynyl group may include an ethynyl group, a propynyl group, etc.

In the description, a hydrocarbon ring group refers to an optional functional group or substituent derived from an aliphatic hydrocarbon ring. The hydrocarbon ring group may be a saturated hydrocarbon ring group having 5 to 20 ring-forming carbon atoms.

In the description, an aryl group refers to an optional functional group or substituent derived from an aromatic hydrocarbon ring. The aryl group may be a monocyclic aryl group or a polycyclic aryl group. The number of carbon atoms for forming rings in the aryl group may be 6 to 30, 6 to 20, or 6 to 15. Non-limiting examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl, etc.

In the description, a fluorenyl group may be substituted, and two substituents may be combined with each other to form a spiro structure. Examples of a substituted fluorenyl group may be as follows, but an embodiment of the present disclosure is not limited thereto.

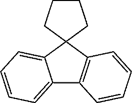 [SMILES: c1ccc2c(c1)-c1ccccc1C21CCCC1]

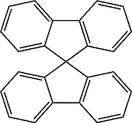 [SMILES: c1ccc2c(c1)-c1ccccc1C21c2ccccc2-c2ccccc21]

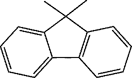

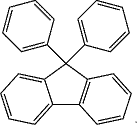

In the description, a heterocyclic group refers to an optional functional group or substituent derived from a ring including one or more selected from among B, O, N, P, Si, and S as heteroatoms. The heterocyclic group includes an aliphatic heterocyclic group and an aromatic heterocyclic group. The aromatic heterocyclic group may be a heteroaryl group. The aliphatic heterocyclic group and the aromatic heterocyclic group may be a monocycle or a polycycle.

When the heterocyclic group includes two or more heteroatoms, the two or more heteroatoms may be the same or different. The heterocyclic group may be a monocyclic heterocyclic group or a polycyclic heterocyclic group, and has the concept including a heteroaryl group. The number of carbon atoms for forming rings of the heterocyclic group may be 2 to 30, 2 to 20, and 2 to 10.

In the description, an aliphatic heterocyclic group may include one or more selected from among B, O, N, P, Si, and S as heteroatoms. The number of ring-forming carbon atoms of the aliphatic heterocyclic group may be 2 to 30, 2 to 20, or 2 to 10. Non-limiting examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc.

In the description, a heteroaryl group may include one or more selected from among B, O, N, P, Si, and S as heteroatoms. When the heteroaryl group includes two or more heteroatoms, the two or more heteroatoms may be the same or different. The heteroaryl group may be a monocyclic heterocyclic group or polycyclic heterocyclic group. The number of carbon atoms for forming rings of the heteroaryl group may be 2 to 30, 2 to 20, or 2 to 10. Non-limiting examples of the heteroaryl group may include a thiophene group, a furan group, a pyrrole group, an imidazole group, a triazole group, a pyridine group, a bipyridine group, a pyrimidine group, a triazine group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isooxazole group, an oxazole group, an oxadiazole group, a thiadiazole group, a phenothiazine group, a dibenzosilole group, a dibenzofuran, etc.

In the description, the same explanation on the above-described aryl group may be applied to an arylene group except that the arylene group is a divalent group. The same explanation on the above-described heteroaryl group may be applied to a heteroarylene group except that the heteroarylene group is a divalent group.

In the description, a silyl group includes an alkyl silyl group and an aryl silyl group. Non-limiting examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc.

In the description, the number of carbon atoms of an amino group is not specifically limited, but may be 1 to 30. The amino group may include an alkyl amino group, an aryl amino group, or a heteroaryl amino group. Non-limiting examples of the amino group include a methylamino group, a dimethylamino group, a phenylamino group, a diphenylamino group, a naphthylamino group, a 9-methyl-anthracenylamino group, a triphenylamino group, etc.

In the description, the number of carbon atoms of a carbonyl group is not specifically limited, but may be 1 to 40, 1 to 30, or 1 to 20. For example, the carbonyl group may have the structures below, but the present disclosure is not limited thereto.

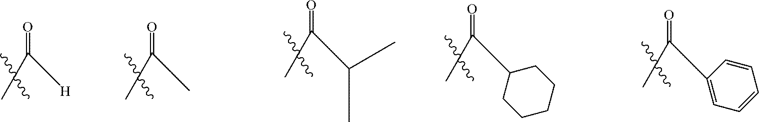

In the description, the number of carbon atoms of a sulfinyl group and a sulfonyl group is not specifically limited, but may be 1 to 30. The sulfinyl group may include an alkyl sulfinyl group and an aryl sulfinyl group. The sulfonyl group may include an alkyl sulfonyl group and an aryl sulfonyl group.

In the description, a thio group may include an alkyl thio group and an aryl thio group. The thio group may refer to the above-defined alkyl group or aryl group combined with a sulfur atom. Non-limiting examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc.

In the description, an oxy group may refer to the above-defined alkyl group or aryl group which is combined with an oxygen atom. The oxy group may include an alkoxy group and an aryl oxy group. The alkoxy group may be a linear, branched or cyclic chain. The number of carbon atoms of the alkoxy group is not specifically limited but may be, for example, 1 to 20 or 1 to 10. Examples of the oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy, etc. However, an embodiment of the present disclosure is not limited thereto.

In the description, a boron group may refer to the above-defined alkyl group or aryl group, combined with a boron atom. The boron group includes an alkyl boron group and an aryl boron group. Non-limiting examples of the boron group may include a trimethylboron group, a triethylboron group, a t-butylmethylboron group, a triphenylboron group, a diphenylboron group, a phenylboron group, etc.

In the description, an alkenyl group may be a linear chain or a branched chain. The number of carbon atoms is not specifically limited but may be 2 to 30, 2 to 20, or 2 to 10. Non-limiting examples of the alkenyl group may include a vinyl group, a 1-butenyl group, a 1-pentenyl group, a 1,3-butadienyl aryl group, a styrenyl group, a styryl vinyl group, etc.

In the description, the number of carbon atoms of an amine group is not specifically limited, but may be 1 to 30. The amine group may include an alkyl amine group and an aryl amine group. Non-limiting examples of the amine group may include a methylamine group, a dimethylamine group, a phenylamine group, a diphenylamine group, a naphthylamine group, a 9-methyl-anthracenylamine group, a triphenylamine group, etc.

In the description, alkyl groups in an alkylthio group, alkylsulfoxy group, alkylaryl group, alkylamino group, alkylboron group, alkyl silyl group, and alkyl amine group may be the same as the examples of the above-described alkyl group.

In the description, aryl groups in an aryloxy group, arylthio group, arylsulfoxy group, aryl amino group, arylboron group, and aryl silyl group may be the same as the examples of the above-described aryl group.

In the description, a direct linkage may refer to a single bond.

Meanwhile, in the description,

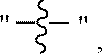

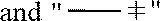

each refer to positions to be connected.

Hereinafter, embodiments of the present disclosure will be explained referring to the drawings.

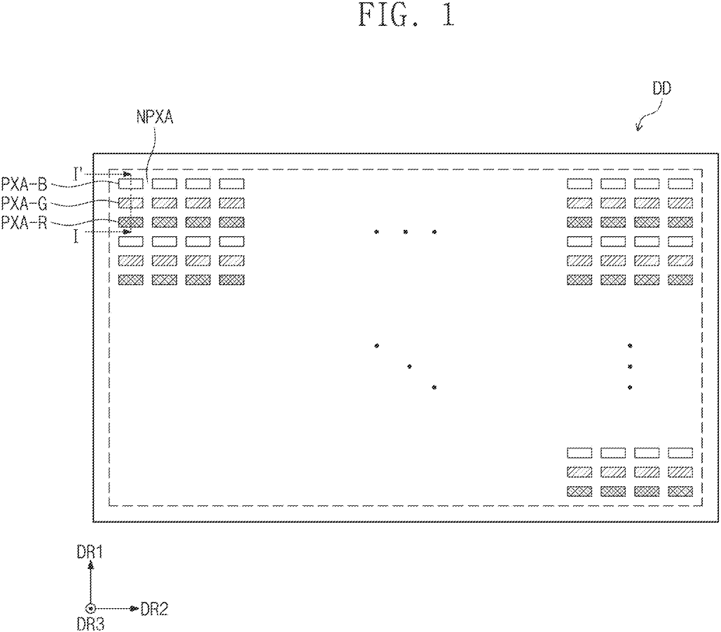

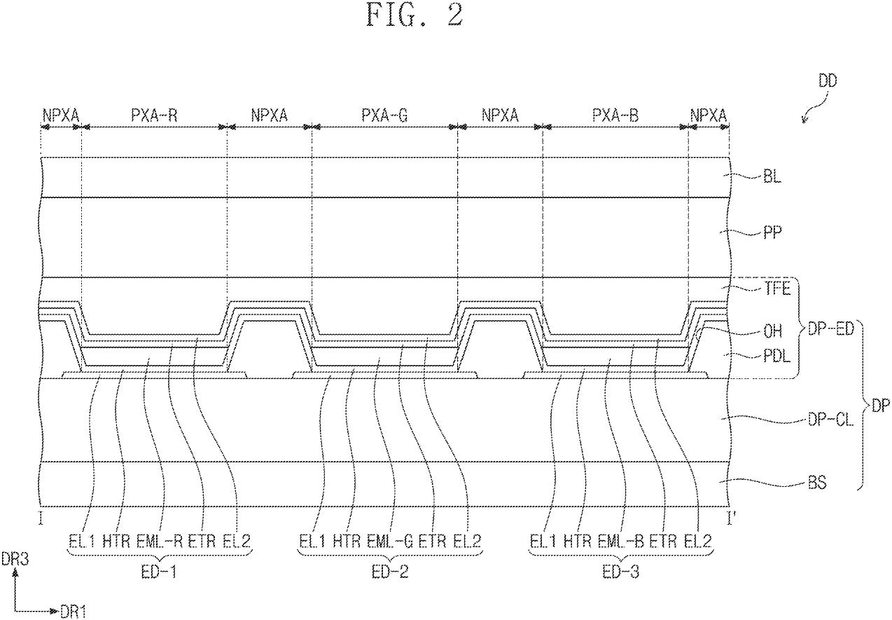

FIG. 1 is a plan view showing an embodiment of a display apparatus DD. FIG. 2 is a cross-sectional view of a display apparatus DD of an embodiment. FIG. 2 is a cross-sectional view showing a part corresponding to the line l-l′ of FIG. 1.

The display apparatus DD may include a display panel DP and an optical layer PP disposed on the display panel DP. The display panel DP includes light emitting elements ED-1, ED-2 and ED-3. The display apparatus DD may include multiple light emitting elements ED-1, ED-2 and ED-3. The optical layer PP may be disposed on the display panel DP and control reflection of external light at the display panel DP. The optical layer PP may include, for example, a polarization layer or a color filter layer. In some embodiments, different from the drawings, the optical layer PP may not be provided in the display apparatus DD of an embodiment.

On the optical layer PP, a base substrate BL may be disposed. The base substrate BL may be a member providing a base surface where the optical layer PP is disposed. The base substrate BL may be a glass substrate, a metal substrate, a plastic substrate, etc. However, an embodiment of the present disclosure is not limited thereto, and the base substrate BL may be an inorganic layer, an organic layer or a composite material layer. In some embodiments, different from the drawings, the base substrate BL may not be provided in an embodiment.

The display apparatus DD according to an embodiment may further include a plugging layer. The plugging layer may be disposed between a display device layer DP-ED and a base substrate BL. The plugging layer may be an organic layer. The plugging layer may include at least one selected from among an acrylic resin, a silicon-based resin and an epoxy-based resin.

The display panel DP may include a base layer BS, a circuit layer DP-CL provided on the base layer BS and a display device layer DP-ED. The display device layer DP-ED may include a pixel definition layer PDL, light emitting elements ED-1, ED-2 and ED-3 disposed in the pixel definition layer PDL, and an encapsulating layer TFE disposed on the light emitting elements ED-1, ED-2 and ED-3.

The base layer BS may be a member providing a base surface where the display device layer DP-ED is disposed. The base layer BS may be a glass substrate, a metal substrate, a plastic substrate, etc. However, an embodiment of the present disclosure is not limited thereto, and the base layer BS may be an inorganic layer, an organic layer or a composite material layer.

In an embodiment, the circuit layer DP-CL is disposed on the base layer BS, and the circuit layer DP-CL may include multiple transistors. Each of the transistors may include a control electrode, an input electrode, and an output electrode. For example, the circuit layer DP-CL may include switching transistors and driving transistors for driving the light emitting elements ED-1, ED-2 and ED-3 of the display device layer DP-ED.

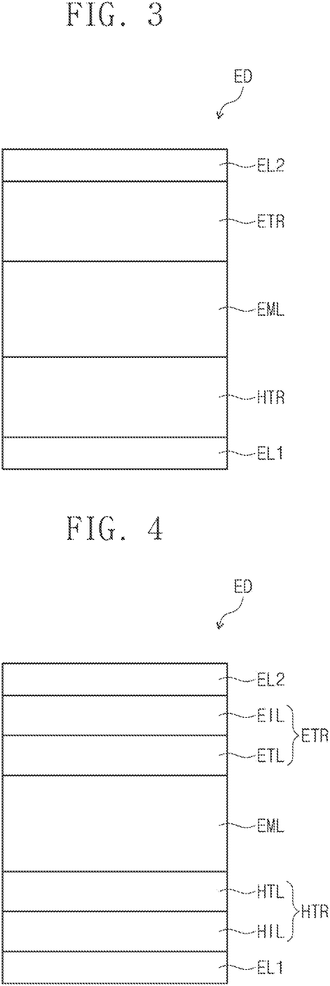

Each of the light emitting elements ED-1, ED-2 and ED-3 may have the structures of light emitting elements ED of embodiments according to FIG. 3 to FIG. 6, which will be explained in more detail later. Each of the light emitting elements ED-1, ED-2 and ED-3 may include a first electrode EL1, a hole transport region HTR, emission layers EML-R, EML-G and EML-B, an electron transport region ETR, and a second electrode EL2.

FIG. 2 shows an embodiment where the emission layers EML-R, EML-G and EML-B of light emitting elements ED-1, ED-2 and ED-3 are disposed in opening portions OH defined in a pixel definition layer PDL, and a hole transport region HTR, an electron transport region ETR and a second electrode EL2 are provided as common layers in all light emitting elements ED-1, ED-2 and ED-3. However, an embodiment of the present disclosure is not limited thereto. Different from FIG. 2, in an embodiment, the hole transport region HTR and the electron transport region ETR may be patterned and provided in the opening portions OH defined in the pixel definition layer PDL. For example, in an embodiment, the hole transport region HTR, the emission layers EML-R, EML-G and EML-B, and the electron transport region ETR of the light emitting elements ED-1, ED-2 and ED-3 may be patterned and provided by an ink jet printing method.

An encapsulating layer TFE may cover the light emitting elements ED-1, ED-2 and ED-3. The encapsulating layer TFE may encapsulate the display device layer DP-ED. The encapsulating layer TFE may be a thin film encapsulating layer. The encapsulating layer TFE may be one layer or a stacked layer of multiple layers. The encapsulating layer TFE includes at least one insulating layer. The encapsulating layer TFE according to an embodiment may include at least one inorganic layer (hereinafter, encapsulating inorganic layer). In some embodiments, the encapsulating layer TFE according to an embodiment may include at least one organic layer (hereinafter, encapsulating organic layer) and at least one encapsulating inorganic layer.

The encapsulating inorganic layer protects the display device layer DP-ED from moisture/oxygen, and the encapsulating organic layer protects the display device layer DP-ED from foreign materials such as dust particles. The encapsulating inorganic layer may include silicon nitride, silicon oxy nitride, silicon oxide, titanium oxide, and/or aluminum oxide, without specific limitation. The encapsulating organic layer may include an acrylic compound, an epoxy-based compound, etc. The encapsulating organic layer may include a photopolymerizable organic material, without specific limitation.

The encapsulating layer TFE may be disposed on the second electrode EL2 and may be disposed while filling the opening portion OH.

Referring to FIG. 1 and FIG. 2, the display apparatus DD may include a non-luminous area NPXA and luminous areas PXA-R, PXA-G and PXA-B. The luminous areas PXA-R, PXA-G and PXA-B may be areas emitting light produced from the light emitting elements ED-1, ED-2 and ED-3, respectively. The luminous areas PXA-R, PXA-G and PXA-B may be separated from each other on a plane.

The luminous areas PXA-R, PXA-G and PXA-B may be areas separated by the pixel definition layer PDL. The non-luminous areas NPXA may be areas between neighboring luminous areas PXA-R, PXA-G and PXA-B and may be areas corresponding to the pixel definition layer PDL. In some embodiments, in the disclosure, each of the luminous areas PXA-R, PXA-G and PXA-B may correspond to a pixel. The pixel definition layer PDL may divide the light emitting elements ED-1, ED-2 and ED-3. The emission layers EML-R, EML-G and EML-B of the light emitting elements ED-1, ED-2 and ED-3 may be disposed and divided in the opening portions OH defined in the pixel definition layer PDL.

The luminous areas PXA-R, PXA-G and PXA-B may be divided into multiple groups according to the color of light produced from the light emitting elements ED-1, ED-2 and ED-3. In the display apparatus DD of an embodiment, shown in FIG. 1 and FIG. 2, three luminous areas PXA-R, PXA-G and PXA-B respectively emitting red light, green light and blue light are illustrated as an embodiment. For example, the display apparatus DD of an embodiment may include a red luminous area PXA-R, a green luminous area PXA-G and a blue luminous area PXA-B, which are separated from each other.

In the display apparatus DD according to an embodiment, multiple light emitting elements ED-1, ED-2 and ED-3 may be to emit light having different wavelength regions. For example, in an embodiment, the display apparatus DD may include a first light emitting element ED-1 emitting red light, a second light emitting element ED-2 emitting green light, and a third light emitting element ED-3 emitting blue light. For example, each of the red luminous area PXA-R, the green luminous area PXA-G, and the blue luminous area PXA-B of the display apparatus DD may correspond to the first light emitting element ED-1, the second light emitting element ED-2, and the third light emitting element ED-3.

However, an embodiment of the present disclosure is not limited thereto, and the first to third light emitting elements ED-1, ED-2 and ED-3 may be to emit light in substantially the same wavelength region, or at least one thereof may be to emit light in a different wavelength region. For example, all the first to third light emitting elements ED-1, ED-2 and ED-3 may be to emit blue light.

The luminous areas PXA-R, PXA-G and PXA-B in the display apparatus DD according to an embodiment may be arranged in a stripe shape. Referring to FIG. 1, multiple red luminous areas PXA-R may be arranged with each other along a second direction axis DR2, multiple green luminous areas PXA-G may be arranged with each other along the second direction axis DR2, and multiple blue luminous areas PXA-B may be arranged with each other along the second direction axis DR2. In some embodiments, the red luminous area PXA-R, the green luminous area PXA-G and the blue luminous area PXA-B may be arranged by turns (with each other) along a first directional axis DR1.

In FIG. 1 and FIG. 2, the areas of the luminous areas PXA-R, PXA-G and PXA-B are shown as being similar, but an embodiment of the present disclosure is not limited thereto. The areas of the luminous areas PXA-R, PXA-G and PXA-B may be different from each other according to the wavelength region of light emitted. In some embodiments, the areas of the luminous areas PXA-R, PXA-G and PXA-B may refer to areas in a plan view (e.g., on a plane defined by the first directional axis DR1 and the second directional axis DR2).

In some embodiments, the arrangement type or kind of the luminous areas PXA-R, PXA-G and PXA-B is not limited to the configuration shown in FIG. 1, and the arrangement order of the red luminous areas PXA-R, the green luminous areas PXA-G and the blue luminous areas PXA-B may be provided in one or more suitable combinations according to the properties of display quality required for the display apparatus DD. For example, the arrangement pattern of the luminous areas PXA-R, PXA-G and PXA-B may be a PENTILE™ arrangement, or a Diamond Pixel™ arrangement. PENTILE® and Diamond Pixel™ are both trademarks of Samsung Display Co., Ltd.

In some embodiments, the areas of the luminous areas PXA-R, PXA-G and PXA-B may be different from each other. For example, in an embodiment, the area of the green luminous area PXA-G may be smaller than the area of the blue luminous area PXA-B, but an embodiment of the present disclosure is not limited thereto.

Hereinafter, FIG. 3 to FIG. 6 are cross-sectional views schematically showing light emitting elements according to embodiments. The light emitting element ED according to an embodiment may include a first electrode EL1, a hole transport region HTR, an emission layer EML, an electron transport region ETR and a second electrode EL2, stacked in the stated order.

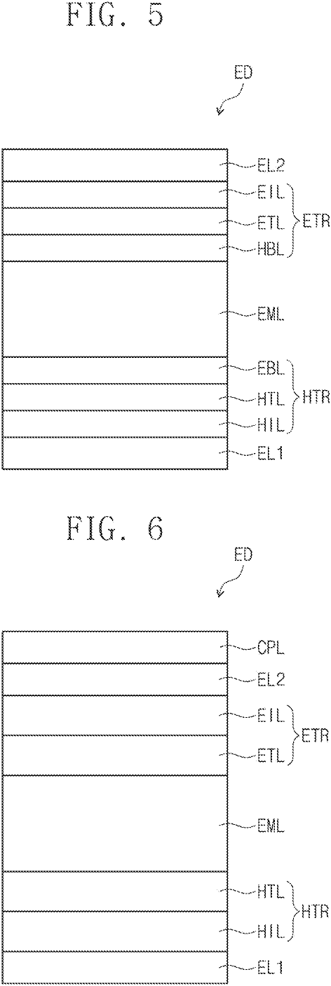

When compared with FIG. 3, FIG. 4 shows the cross-sectional view of a light emitting element ED of an embodiment, wherein a hole transport region HTR includes a hole injection layer HIL and a hole transport layer HTL, and an electron transport region ETR includes an electron injection layer ElL and an electron transport layer ETL. In addition, when compared with FIG. 3, FIG. 5 shows the cross-sectional view of a light emitting element ED of an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared with FIG. 4, FIG. 6 shows the cross-sectional view of a light emitting element ED of an embodiment, including a capping layer CPL disposed on the second electrode EL2.

The first electrode EL1 has conductivity (e.g., is a conductor). The first electrode EL1 may be formed utilizing a metal material, a metal alloy or a conductive compound. The first electrode EL1 may be an anode or a cathode. However, an embodiment of the present disclosure is not limited thereto. In some embodiments, the first electrode EL1 may be a pixel electrode. The first electrode EL1 may be a transmissive electrode, a transflective electrode, or a reflective electrode. When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, W, one or more compounds thereof, or one or more mixtures thereof (for example, a mixture of Ag and Mg). Also, the first electrode EL1 may have a structure including multiple layers including a reflective layer or a transflective layer formed utilizing the above materials, and a transmissive conductive layer formed utilizing ITO, IZO, ZnO, and/or ITZO. For example, the first electrode EL1 may have a three-layer structure of ITO/Ag/ITO. However, an embodiment of the present disclosure is not limited thereto. The first electrode EL1 may include the above-described metal materials, combinations of two or more metal materials selected from the above-described metal materials, or oxides of the above-described metal materials. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission auxiliary layer, or an emission blocking layer EBL. The thickness of the hole transport region HTR may be, for example, about 50 Å to about 15,000 Å.

The hole transport region HTR may have a single layer formed utilizing a single material, a single layer formed utilizing multiple different materials, or a multilayer structure including multiple layers formed utilizing multiple different materials.

For example, the hole transport region HTR may have the structure of a single layer of a hole injection layer HIL or a hole transport layer HTL, and may have a structure of a single layer formed utilizing a hole injection material and a hole transport material. In some embodiments, the hole transport region HTR may have a structure of a single layer formed utilizing multiple different materials, or a structure stacked from the first electrode EL1 of hole injection layer HIL/hole transport layer HTL, hole injection layer HIL/hole transport layer HTL/buffer layer, hole injection layer HIL/buffer layer, hole transport layer HTL/buffer layer, or hole injection layer HIL/hole transport layer HTL/electron blocking layer EBL, but the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1.

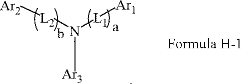

In Formula H-1 above, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. “a” and “b” may each independently be an integer of 0 to 10. In some embodiments, when “a” or “b” is an integer of 2 or more, two or more L₁ and L₂ may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms.

The compound represented by Formula H-1 may be a monoamine compound (e.g., a compound including a single amine group). In some embodiments, the compound represented by Formula H-1 may be a diamine compound in which at least one selected from among Ar₁ to Ar₃ includes an amine group as a substituent. In some embodiments, the compound represented by Formula H-1 may be a carbazole-based compound in which at least one selected from among Ar₁ and Ar₂ includes a substituted or unsubstituted carbazole group, or a fluorene-based compound in which at least one selected from among Ar₁ and Ar₂ includes a substituted or unsubstituted fluorene group.

The compound represented by Formula H-1 may be represented by any one selected from among the compounds in Compound Group H. However, the compounds shown in Compound Group H are only examples, and the compound represented by Formula H-1 is not limited to the compounds represented in Compound Group H.

### Compound Group H

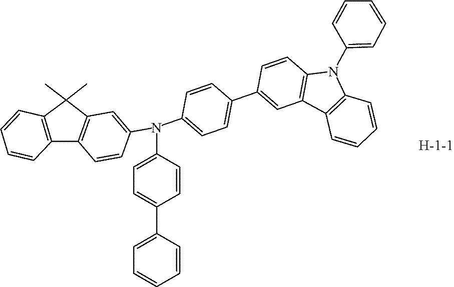 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21]

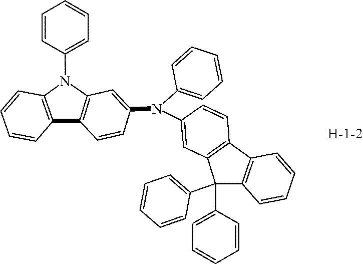

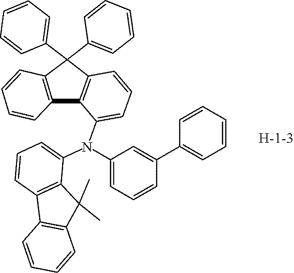

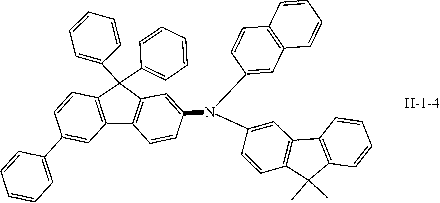

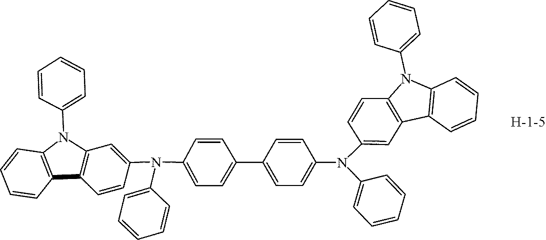

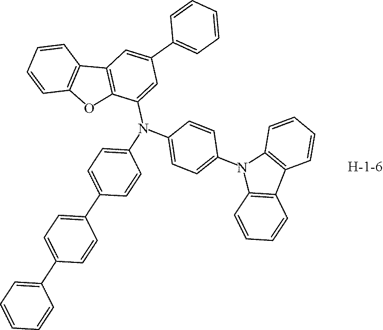 [SMILES: c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

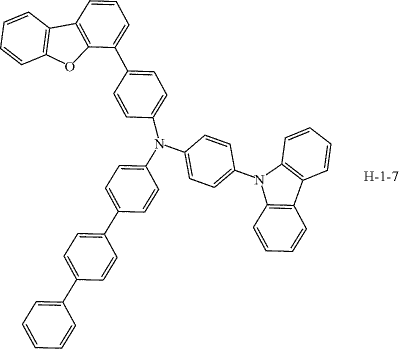 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

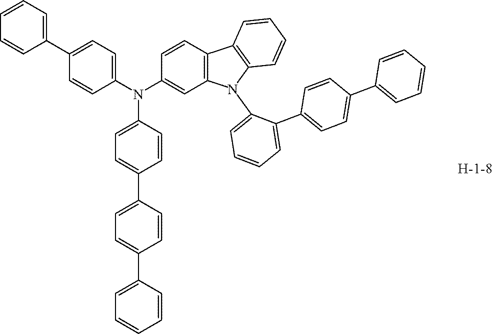 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1]

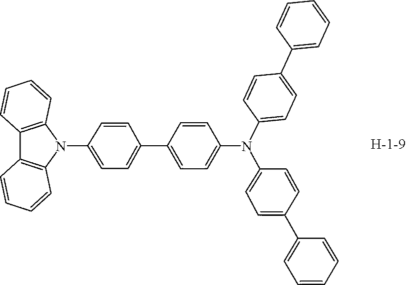 [SMILES: c1ccc(-c2ccc(N(c3ccc(-c4ccccc4)cc3)c3ccc(-c4ccc(-n5c6ccccc6c6ccccc65)cc4)cc3)cc2)cc1]

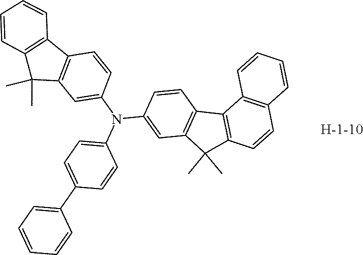 [SMILES: CC1(C)c2ccccc2-c2ccc(N(c3ccc(-c4ccccc4)cc3)c3ccc4c(c3)C(C)(C)c3ccc5ccccc5c3-4)cc21]

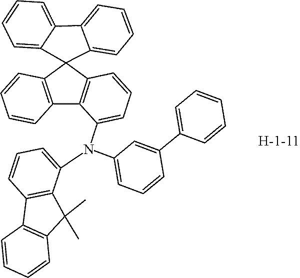 [SMILES: CC1(C)c2ccccc2-c2cccc(N(c3cccc(-c4ccccc4)c3)c3cccc4c3-c3ccccc3C43c4ccccc4-c4ccccc43)c21]

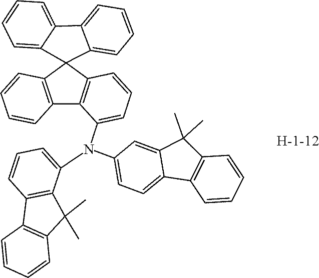 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21]

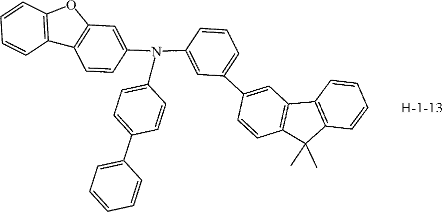 [SMILES: CC1(C)c2ccccc2-c2cc(-c3cccc(N(c4ccc(-c5ccccc5)cc4)c4ccc5c(c4)oc4ccccc45)c3)ccc21]

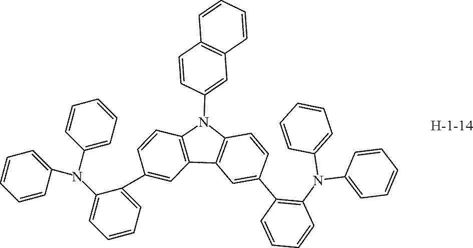 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1]

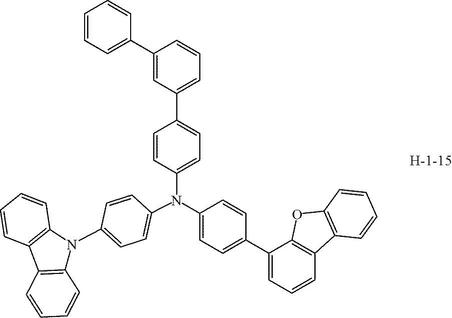 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

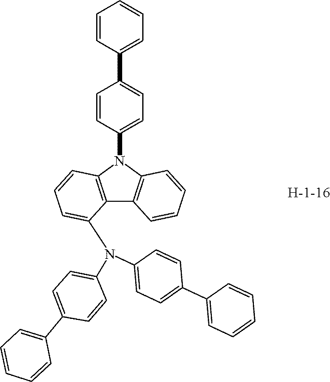

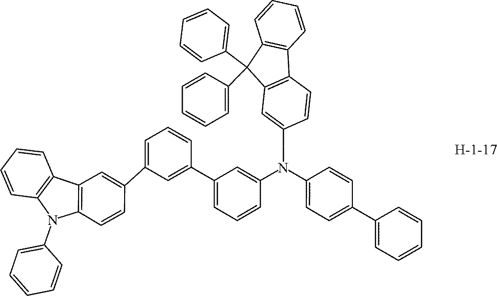 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

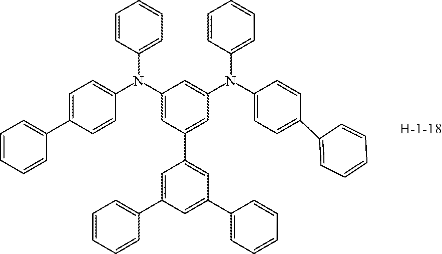 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

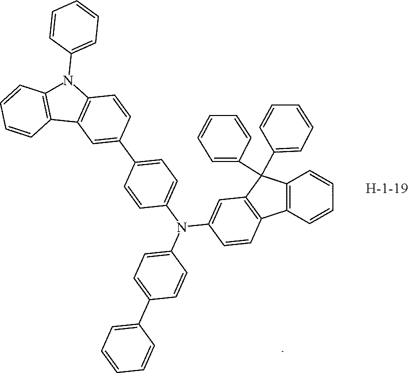

The hole transport region HTR may include a phthalocyanine compound such as copper phthalocyanine, N¹,N¹′-([1,1′-biphenyl]-4,4′-diyl)bis(N¹-phenyl-N⁴,N⁴-dim-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB or NPD), triphenylamine-containing polyetherketone (TPAPEK), 4-isopropyl-4′-methyldiphenyliodonium [tetrakis(pentafluorophenyl)borate], and dipyrazino[2,3-f:2′,3′-h] quinoxaline-2,3,6,7,10,11 -hexacarbonitrile (HAT-CN).

The hole transport region HTR may include one or more carbazole derivatives such as N-phenyl carbazole and/or polyvinyl carbazole, one or more fluorene-based derivatives, N,N′-bis(3-methylphenyl)-N,N′-diphenyl-[1,1′-biphenyl]-4,4′-diamine (TPD), one or more triphenylamine-based derivatives such as 4,4′,4″-tris(N-carbazolyl)triphenylamine (TCTA), N,N′-di(1-naphthalene-1-yl)-N,N′-diphenyl-benzidine (NPB), 4,4′-cyclohexylidene bis[N,N-bis(4-methylphenyl)benzeneamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region in at least one selected from among the hole injection layer HIL, hole transport layer HTL, and electron blocking layer EBL.

The thickness of the hole transport region HTR may be from about 100 Å to about 10.000 Å, for example, from about 100 Å to about 5.000 Å. When the hole transport region HTR includes a hole injection layer HIL, the thickness of the hole injection region HIL may be, for example, from about 30 Å to about 1.000 Å. When the hole transport region HTR includes a hole transport layer HTL, the thickness of the hole transport layer HTL may be from about 30 Å to about 1.000 Å. For example, when the hole transport region HTR includes an electron blocking layer EBL, the thickness of the electron blocking layer EBL may be from about 10 Å to about 1.000 Å. When the thicknesses of the hole transport region HTR, the hole injection layer HIL, the hole transport layer HTL and the electron blocking layer EBL satisfy the above-described ranges, satisfactory hole transport properties may be achieved without substantial increase of a driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one selected from amoung metal halide compounds, quinone derivatives, metal oxides, and cyano group-containing compounds, but the present disclosure is not limited thereto. For example, the p-dopant may include one or more metal halide compounds such as Cul and/or Rbl, quinone derivatives such as tetracyanoquinodimethane (TCNQ) and/or 2,3,5,6-tetrafluoro-7,7′,8,8-tetracyanoquinodimethane (F4-TCNQ), metal oxides such as tungsten oxide and/or molybdenum oxide, cyano group-containing compounds such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but the present disclosure is not limited thereto.

As described above, the hole transport region HTR may further include at least one selected from among a buffer layer and an electron blocking layer EBL in addition to the hole injection layer HIL and the hole transport layer HTL. The buffer layer may compensate for a resonance distance according to the wavelength of light emitted from an emission layer EML and may thus increase emission efficiency. As materials included in the buffer layer, materials which may be included in the hole transport region HTR may be utilized. The electron blocking layer EBL is a layer playing the role of blocking the injection of electrons from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed utilizing a single material, a single layer formed utilizing multiple different materials, or a multilayer structure having a plurality of layers formed utilizing a plurality of different materials.

In the light emitting element ED of an embodiment, the emission layer EML may include a first compound represented by Formula 1, and at least one selected from among a second to fourth compounds. The first compound to the fourth compound may be different from each other.

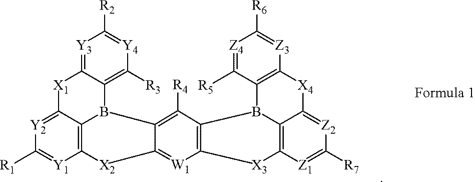

In Formula 1, R₁ to R₇ may each independently be a hydrogen atom, a deuterium atom, a substituted or unsubstituted oxy group, a substituted or unsubstituted thio group, a substituted or unsubstituted amino group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or combined with an adjacent group to form a ring. R₁ to R₇ may be all the same, or at least one may be different from the remainder.

A case where all X₁ to X₄ are CRₐR_{b} may be excluded, and X₁ to X₄ may each independently be CRₐR_{b}, or NR_{c}. For example, X₁ to X₄ may all be NR_{c}, or at least one selected from among X₁ to X₄ may be NR_{c}.

When W₁ is CR_{d}, a case where Y₁ and Z₁ are N at the same time, a case where Y₂ and Z₂ are N at the same time, Y₃ and Z₃ are N at the same time, and a case where Y₄ and Z₄ are N at the same time may all be excluded, and at least one selected from among Y₁ to Y₄, Z₁ to Z₄, and W₁ may be N, and the remainder of Y₁ to Y₄, Z₁ to Z₄, and W₁ may be CR_{d}. For example, when W₁ is N, Y₁ to Y₄, and Z₁ to Z₄ may all be the same, or at least one selected from among Y₁ to Y₄, and Z₁ to Z₄ may be different from the remainder thereof.

Rₐ to R_{d} may each independently be a hydrogen atom, a deuterium atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or combined with an adjacent group to form a ring. Rₐ to R_{d} may all be the same, or at least one selected from Rₐ to R_{d} may be different from the remainder thereof.

The first compound represented by Formula 1 may be represented by Formula 2-1 or Formula 2-2. Formula 2-1 and Formula 2-2 correspond to Formula 1 where W₁ is embodied (e.g., as CH or as N, respectively). Formula 2-1 corresponds to Formula 1 where W₁ is CR_{d}, and R_{d} is a hydrogen atom. Formula 2-2 corresponds to Formula 1 where W₁ is N.

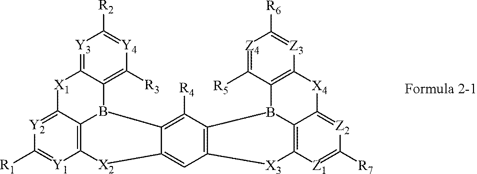

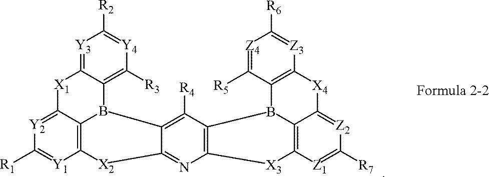

In Formula 2-1 and Formula 2-2, the same explanation on X₁ to X₄, Y₁ to Y₄, Z₁ to Z₄, and R₁ to R₇ defined in Formula 1 may be applied.

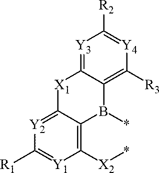

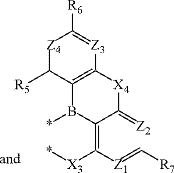

in Formula 2-1 may be different from each other. For example, in Formula 2-1, a case where Y₁ and Z₁ are N at the same time, a case where Y₂ and Z₂ are N at the same time, a case where Y₃ and Z₃ are N at the same time, and a case where Y₄ and Z₄ are N at the same time may be excluded.

In Formula 1, X₁ and X₄ may be different from each other. For example, the first compound represented by Formula 1 may be represented by Formula 3.

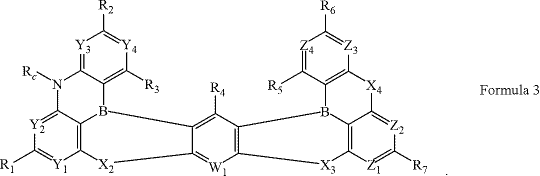

In Formula 3, the same explanation on W₁, X₂ to X₄, Y₁ to Y₄, Z₁ to Z₄, R₁ to R₇, and R_{c} defined in Formula 1 may be applied.

In Formula 1, X₂ and X₃ may be different from each other. For example, the first compound represented by Formula 1 may be represented by Formula 4.

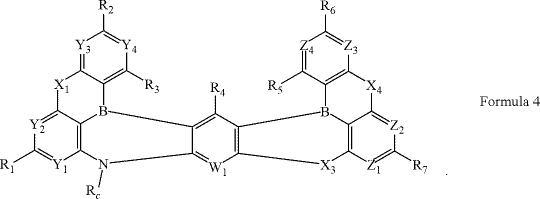

In Formula 4, the same explanation on W₁, X₁, X₂, X₄, Y₁ to Y₄, Z₁ to Z₄, R₁ to R₇, and R_{c} defined in Formula 1 may be applied.

In an embodiment, the first compound represented by Formula 1 may be represented by any one selected from among the compounds represented in Compound Group 1.

### Compound Group 1

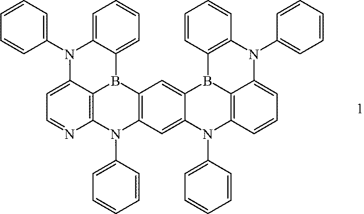 [SMILES: c1ccc(N2c3ccccc3B3c4cc5c(cc4N(c4ccccc4)c4cccc2c43)N(c2ccccc2)c2nccc3c2B5c2ccccc2N3c2ccccc2)cc1]

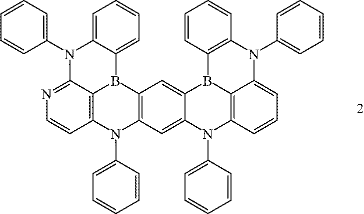 [SMILES: c1ccc(N2c3ccccc3B3c4cc5c(cc4N(c4ccccc4)c4cccc2c43)N(c2ccccc2)c2ccnc3c2B5c2ccccc2N3c2ccccc2)cc1]

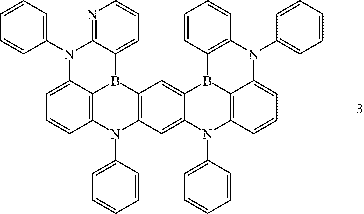 [SMILES: c1ccc(N2c3ccccc3B3c4cc5c(cc4N(c4ccccc4)c4cccc2c43)N(c2ccccc2)c2cccc3c2B5c2cccnc2N3c2ccccc2)cc1]

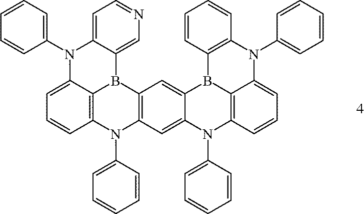 [SMILES: c1ccc(N2c3ccccc3B3c4cc5c(cc4N(c4ccccc4)c4cccc2c43)N(c2ccccc2)c2cccc3c2B5c2cnccc2N3c2ccccc2)cc1]

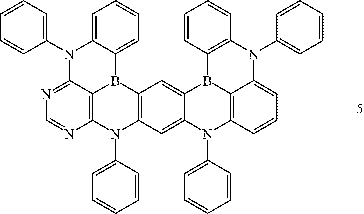 [SMILES: c1ccc(N2c3ccccc3B3c4cc5c(cc4N(c4ccccc4)c4cccc2c43)N(c2ccccc2)c2ncnc3c2B5c2ccccc2N3c2ccccc2)cc1]

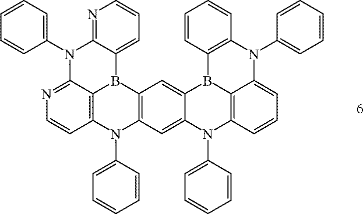 [SMILES: c1ccc(N2c3ccccc3B3c4cc5c(cc4N(c4ccccc4)c4cccc2c43)N(c2ccccc2)c2ccnc3c2B5c2cccnc2N3c2ccccc2)cc1]

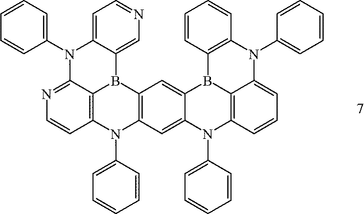 [SMILES: c1ccc(N2c3ccccc3B3c4cc5c(cc4N(c4ccccc4)c4cccc2c43)N(c2ccccc2)c2ccnc3c2B5c2cnccc2N3c2ccccc2)cc1]

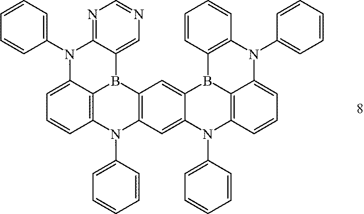 [SMILES: c1ccc(N2c3ccccc3B3c4cc5c(cc4N(c4ccccc4)c4cccc2c43)N(c2ccccc2)c2cccc3c2B5c2cncnc2N3c2ccccc2)cc1]

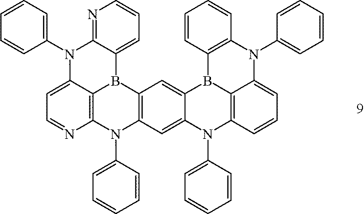 [SMILES: c1ccc(N2c3ccccc3B3c4cc5c(cc4N(c4ccccc4)c4cccc2c43)N(c2ccccc2)c2nccc3c2B5c2cccnc2N3c2ccccc2)cc1]

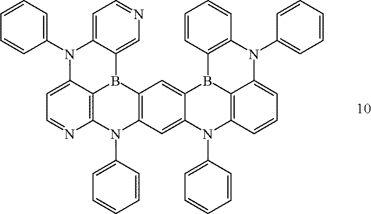 [SMILES: c1ccc(N2c3ccccc3B3c4cc5c(cc4N(c4ccccc4)c4cccc2c43)N(c2ccccc2)c2nccc3c2B5c2cnccc2N3c2ccccc2)cc1]

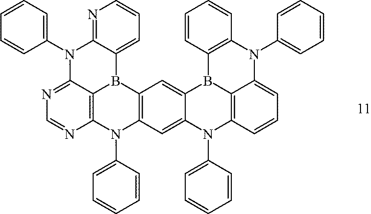 [SMILES: c1ccc(N2c3ccccc3B3c4cc5c(cc4N(c4ccccc4)c4cccc2c43)N(c2ccccc2)c2ncnc3c2B5c2cccnc2N3c2ccccc2)cc1]

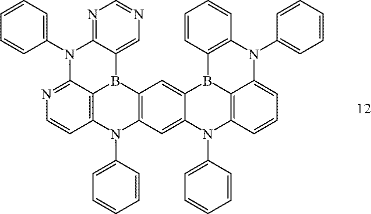 [SMILES: c1ccc(N2c3ccccc3B3c4cc5c(cc4N(c4ccccc4)c4cccc2c43)N(c2ccccc2)c2ccnc3c2B5c2cncnc2N3c2ccccc2)cc1]

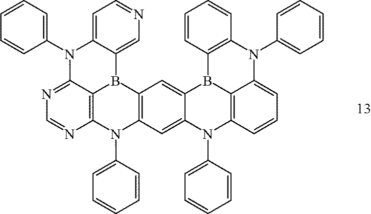 [SMILES: c1ccc(N2c3ccccc3B3c4cc5c(cc4N(c4ccccc4)c4cccc2c43)N(c2ccccc2)c2ncnc3c2B5c2cnccc2N3c2ccccc2)cc1]

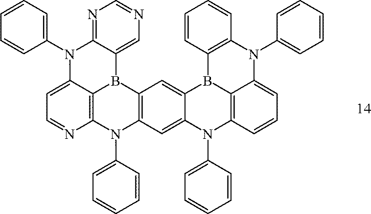 [SMILES: c1ccc(N2c3ccccc3B3c4cc5c(cc4N(c4ccccc4)c4cccc2c43)N(c2ccccc2)c2nccc3c2B5c2cncnc2N3c2ccccc2)cc1]

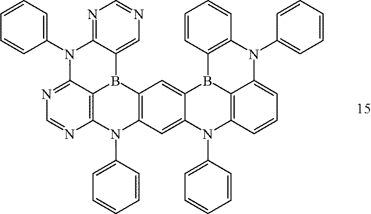 [SMILES: c1ccc(N2c3ccccc3B3c4cc5c(cc4N(c4ccccc4)c4cccc2c43)N(c2ccccc2)c2ncnc3c2B5c2cncnc2N3c2ccccc2)cc1]

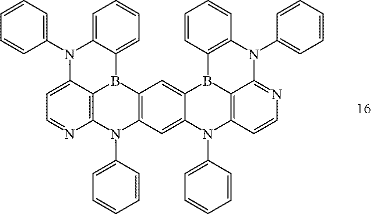 [SMILES: c1ccc(N2c3cc4c(cc3B3c5ccccc5N(c5ccccc5)c5nccc2c53)B2c3ccccc3N(c3ccccc3)c3ccnc(c32)N4c2ccccc2)cc1]

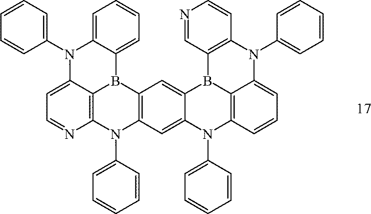 [SMILES: c1ccc(N2c3ccncc3B3c4cc5c(cc4N(c4ccccc4)c4cccc2c43)N(c2ccccc2)c2nccc3c2B5c2ccccc2N3c2ccccc2)cc1]

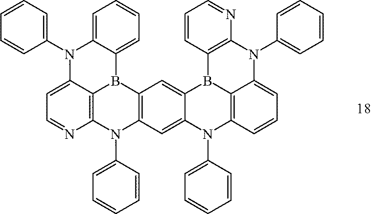 [SMILES: c1ccc(N2c3cc4c(cc3B3c5cccnc5N(c5ccccc5)c5cccc2c53)B2c3ccccc3N(c3ccccc3)c3ccnc(c32)N4c2ccccc2)cc1]

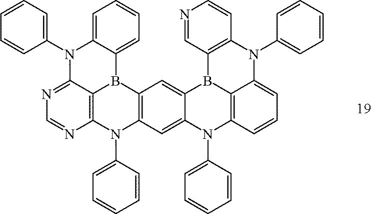 [SMILES: c1ccc(N2c3ccncc3B3c4cc5c(cc4N(c4ccccc4)c4cccc2c43)N(c2ccccc2)c2ncnc3c2B5c2ccccc2N3c2ccccc2)cc1]

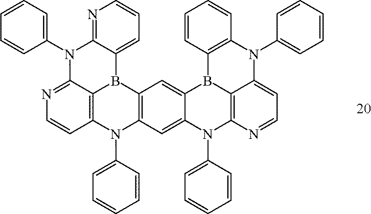 [SMILES: c1ccc(N2c3ccccc3B3c4cc5c(cc4N(c4ccccc4)c4nccc2c43)N(c2ccccc2)c2ccnc3c2B5c2cccnc2N3c2ccccc2)cc1]

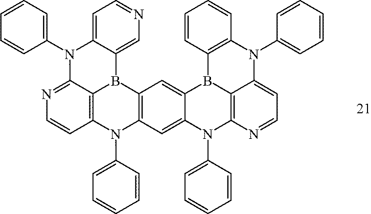 [SMILES: c1ccc(N2c3cc4c(cc3B3c5cnccc5N(c5ccccc5)c5nccc2c53)B2c3ccccc3N(c3ccccc3)c3ccnc(c32)N4c2ccccc2)cc1]

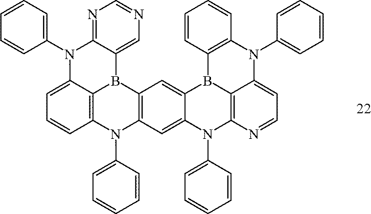 [SMILES: c1ccc(N2c3cc4c(cc3B3c5cncnc5N(c5ccccc5)c5cccc2c53)B2c3ccccc3N(c3ccccc3)c3ccnc(c32)N4c2ccccc2)cc1]

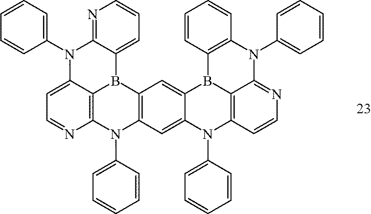 [SMILES: c1ccc(N2c3cc4c(cc3B3c5ccccc5N(c5ccccc5)c5nccc2c53)B2c3cccnc3N(c3ccccc3)c3ccnc(c32)N4c2ccccc2)cc1]

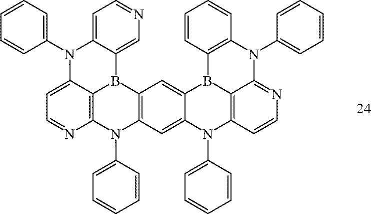 [SMILES: c1ccc(N2c3cc4c(cc3B3c5ccccc5N(c5ccccc5)c5nccc2c53)B2c3cnccc3N(c3ccccc3)c3ccnc(c32)N4c2ccccc2)cc1]

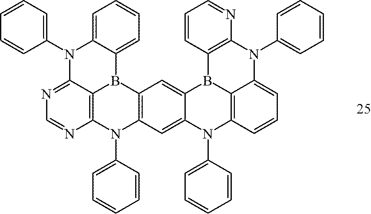 [SMILES: c1ccc(N2c3cc4c(cc3B3c5cccnc5N(c5ccccc5)c5cccc2c53)B2c3ccccc3N(c3ccccc3)c3ncnc(c32)N4c2ccccc2)cc1]

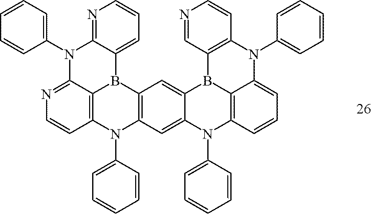 [SMILES: c1ccc(N2c3ccncc3B3c4cc5c(cc4N(c4ccccc4)c4cccc2c43)N(c2ccccc2)c2ccnc3c2B5c2cccnc2N3c2ccccc2)cc1]

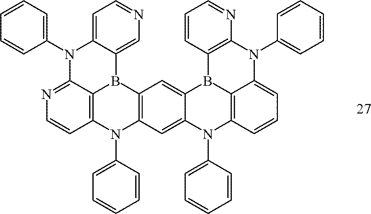 [SMILES: c1ccc(N2c3cc4c(cc3B3c5cccnc5N(c5ccccc5)c5cccc2c53)B2c3cnccc3N(c3ccccc3)c3nccc(c32)N4c2ccccc2)cc1]

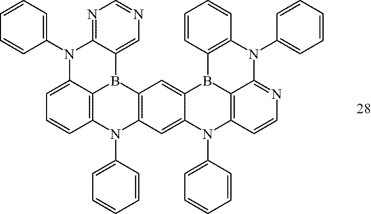 [SMILES: c1ccc(N2c3cc4c(cc3B3c5cncnc5N(c5ccccc5)c5cccc2c53)B2c3ccccc3N(c3ccccc3)c3nccc(c32)N4c2ccccc2)cc1]

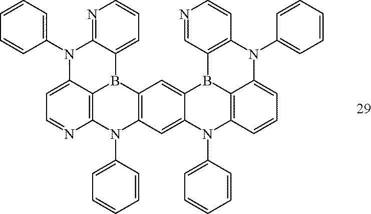 [SMILES: c1ccc(N2c3ccncc3B3c4cc5c(cc4N(c4ccccc4)c4cccc2c43)N(c2ccccc2)c2nccc3c2B5c2cccnc2N3c2ccccc2)cc1]

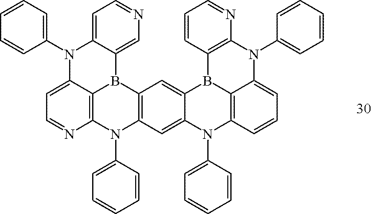 [SMILES: c1ccc(N2c3cc4c(cc3B3c5cccnc5N(c5ccccc5)c5cccc2c53)B2c3cnccc3N(c3ccccc3)c3ccnc(c32)N4c2ccccc2)cc1]

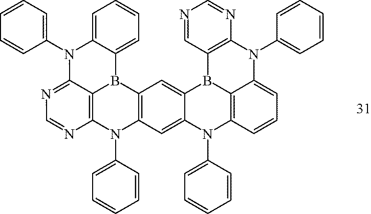 [SMILES: c1ccc(N2c3cc4c(cc3B3c5cncnc5N(c5ccccc5)c5cccc2c53)B2c3ccccc3N(c3ccccc3)c3ncnc(c32)N4c2ccccc2)cc1]

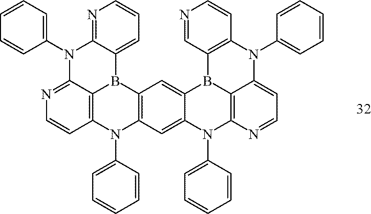 [SMILES: c1ccc(N2c3ccncc3B3c4cc5c(cc4N(c4ccccc4)c4nccc2c43)N(c2ccccc2)c2ccnc3c2B5c2cccnc2N3c2ccccc2)cc1]

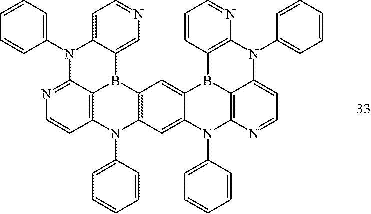 [SMILES: c1ccc(N2c3cc4c(cc3B3c5cnccc5N(c5ccccc5)c5nccc2c53)B2c3cccnc3N(c3ccccc3)c3ccnc(c32)N4c2ccccc2)cc1]

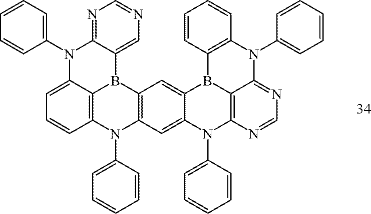 [SMILES: c1ccc(N2c3cc4c(cc3B3c5cncnc5N(c5ccccc5)c5cccc2c53)B2c3ccccc3N(c3ccccc3)c3ncnc(c32)N4c2ccccc2)cc1]

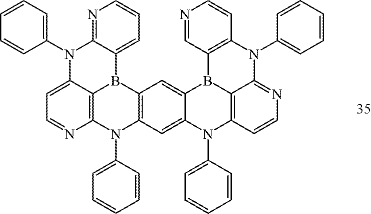 [SMILES: c1ccc(N2c3cc4c(cc3B3c5cnccc5N(c5ccccc5)c5nccc2c53)B2c3cccnc3N(c3ccccc3)c3ccnc(c32)N4c2ccccc2)cc1]

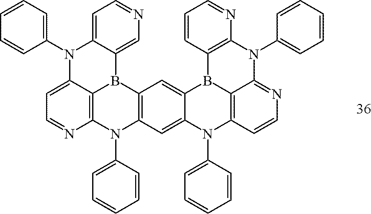 [SMILES: c1ccc(N2c3ccncc3B3c4cc5c(cc4N(c4ccccc4)c4nccc2c43)N(c2ccccc2)c2ccnc3c2B5c2cccnc2N3c2ccccc2)cc1]

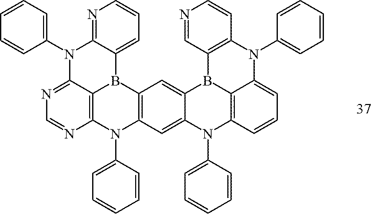 [SMILES: c1ccc(N2c3ccncc3B3c4cc5c(cc4N(c4ccccc4)c4cccc2c43)N(c2ccccc2)c2ncnc3c2B5c2cccnc2N3c2ccccc2)cc1]

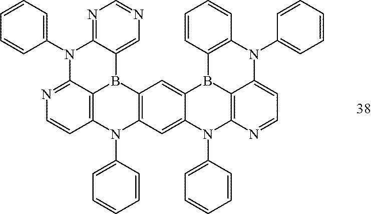 [SMILES: c1ccc(N2c3ccccc3B3c4cc5c(cc4N(c4ccccc4)c4nccc2c43)N(c2ccccc2)c2ccnc3c2B5c2cncnc2N3c2ccccc2)cc1]

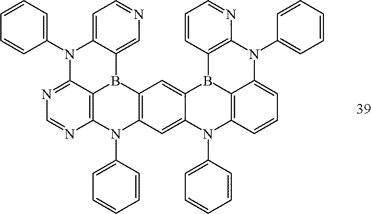 [SMILES: c1ccc(N2c3cc4c(cc3B3c5cccnc5N(c5ccccc5)c5cccc2c53)B2c3cnccc3N(c3ccccc3)c3ncnc(c32)N4c2ccccc2)cc1]

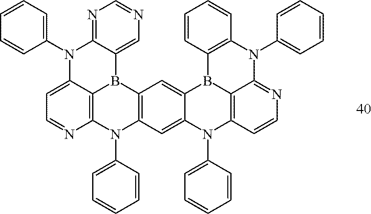 [SMILES: c1ccc(N2c3cc4c(cc3B3c5ccccc5N(c5ccccc5)c5nccc2c53)B2c3cncnc3N(c3ccccc3)c3ccnc(c32)N4c2ccccc2)cc1]

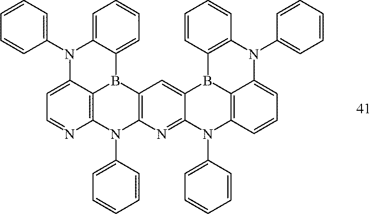 [SMILES: c1ccc(N2c3ccccc3B3c4cc5c(nc4N(c4ccccc4)c4cccc2c43)N(c2ccccc2)c2nccc3c2B5c2ccccc2N3c2ccccc2)cc1]

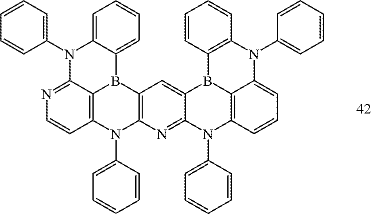 [SMILES: c1ccc(N2c3ccccc3B3c4cc5c(nc4N(c4ccccc4)c4cccc2c43)N(c2ccccc2)c2ccnc3c2B5c2ccccc2N3c2ccccc2)cc1]

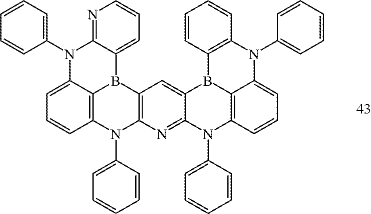 [SMILES: c1ccc(N2c3ccccc3B3c4cc5c(nc4N(c4ccccc4)c4cccc2c43)N(c2ccccc2)c2cccc3c2B5c2cccnc2N3c2ccccc2)cc1]

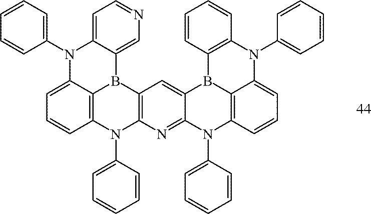 [SMILES: c1ccc(N2c3ccccc3B3c4cc5c(nc4N(c4ccccc4)c4cccc2c43)N(c2ccccc2)c2cccc3c2B5c2cnccc2N3c2ccccc2)cc1]

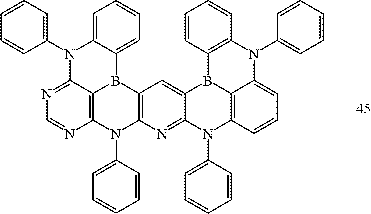 [SMILES: c1ccc(N2c3ccccc3B3c4cc5c(nc4N(c4ccccc4)c4cccc2c43)N(c2ccccc2)c2ncnc3c2B5c2ccccc2N3c2ccccc2)cc1]

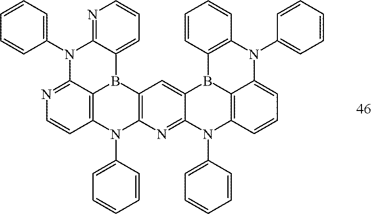 [SMILES: c1ccc(N2c3ccccc3B3c4cc5c(nc4N(c4ccccc4)c4cccc2c43)N(c2ccccc2)c2ccnc3c2B5c2cccnc2N3c2ccccc2)cc1]

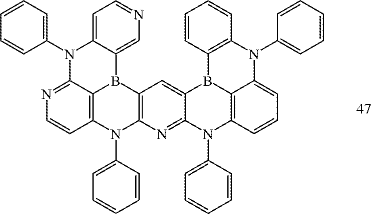 [SMILES: c1ccc(N2c3ccccc3B3c4cc5c(nc4N(c4ccccc4)c4cccc2c43)N(c2ccccc2)c2ccnc3c2B5c2cnccc2N3c2ccccc2)cc1]

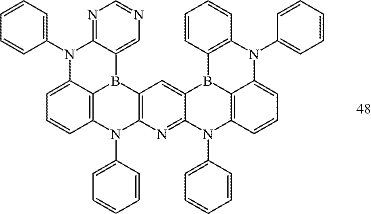 [SMILES: c1ccc(N2c3ccccc3B3c4cc5c(nc4N(c4ccccc4)c4cccc2c43)N(c2ccccc2)c2cccc3c2B5c2cncnc2N3c2ccccc2)cc1]

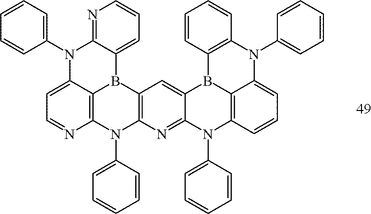 [SMILES: c1ccc(N2c3ccccc3B3c4cc5c(nc4N(c4ccccc4)c4cccc2c43)N(c2ccccc2)c2nccc3c2B5c2cccnc2N3c2ccccc2)cc1]

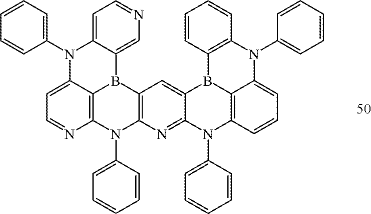 [SMILES: c1ccc(N2c3ccccc3B3c4cc5c(nc4N(c4ccccc4)c4cccc2c43)N(c2ccccc2)c2nccc3c2B5c2cnccc2N3c2ccccc2)cc1]

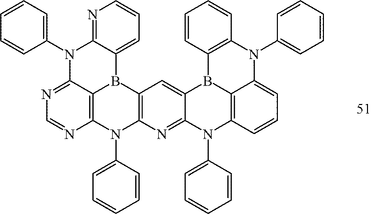 [SMILES: c1ccc(N2c3ccccc3B3c4cc5c(nc4N(c4ccccc4)c4cccc2c43)N(c2ccccc2)c2ncnc3c2B5c2cccnc2N3c2ccccc2)cc1]

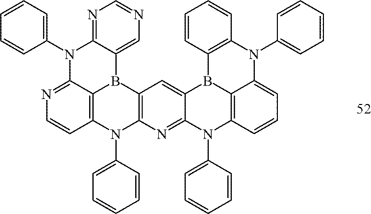 [SMILES: c1ccc(N2c3ccccc3B3c4cc5c(nc4N(c4ccccc4)c4cccc2c43)N(c2ccccc2)c2ccnc3c2B5c2cncnc2N3c2ccccc2)cc1]

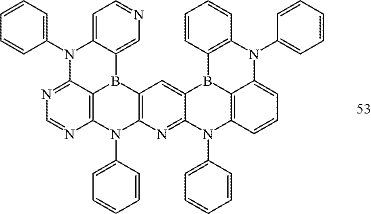 [SMILES: c1ccc(N2c3ccccc3B3c4cc5c(nc4N(c4ccccc4)c4cccc2c43)N(c2ccccc2)c2ncnc3c2B5c2cnccc2N3c2ccccc2)cc1]

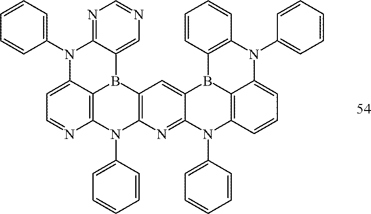 [SMILES: c1ccc(N2c3ccccc3B3c4cc5c(nc4N(c4ccccc4)c4cccc2c43)N(c2ccccc2)c2nccc3c2B5c2cncnc2N3c2ccccc2)cc1]

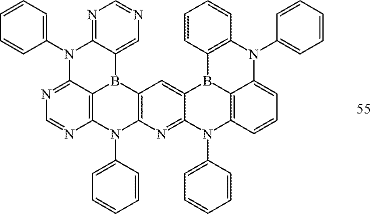 [SMILES: c1ccc(N2c3ccccc3B3c4cc5c(nc4N(c4ccccc4)c4cccc2c43)N(c2ccccc2)c2ncnc3c2B5c2cncnc2N3c2ccccc2)cc1]

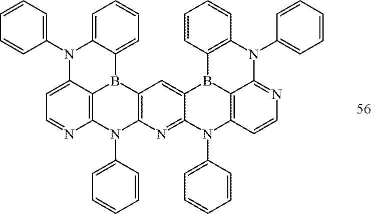 [SMILES: c1ccc(N2c3ccccc3B3c4cc5c(nc4N(c4ccccc4)c4nccc2c43)N(c2ccccc2)c2ccnc3c2B5c2ccccc2N3c2ccccc2)cc1]

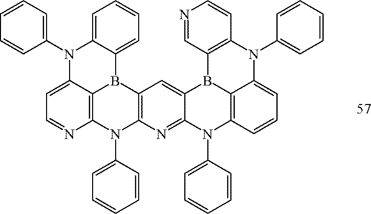 [SMILES: c1ccc(N2c3ccncc3B3c4cc5c(nc4N(c4ccccc4)c4cccc2c43)N(c2ccccc2)c2nccc3c2B5c2ccccc2N3c2ccccc2)cc1]

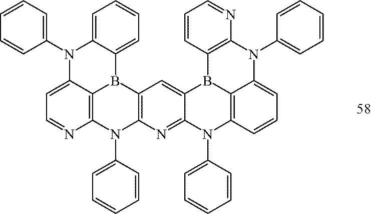 [SMILES: c1ccc(N2c3ccccc3B3c4cc5c(nc4N(c4ccccc4)c4nccc2c43)N(c2ccccc2)c2cccc3c2B5c2cccnc2N3c2ccccc2)cc1]

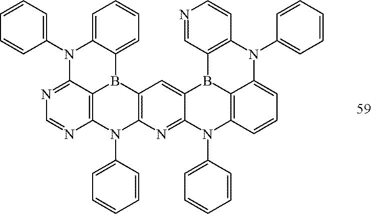 [SMILES: c1ccc(N2c3ccncc3B3c4cc5c(nc4N(c4ccccc4)c4cccc2c43)N(c2ccccc2)c2ncnc3c2B5c2ccccc2N3c2ccccc2)cc1]

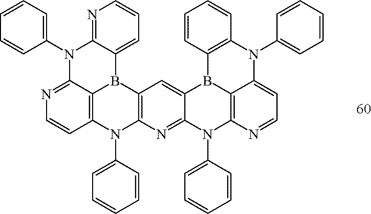 [SMILES: c1ccc(N2c3ccccc3B3c4cc5c(nc4N(c4ccccc4)c4nccc2c43)N(c2ccccc2)c2ccnc3c2B5c2cccnc2N3c2ccccc2)cc1]

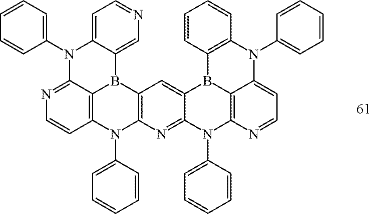 [SMILES: c1ccc(N2c3ccccc3B3c4cc5c(nc4N(c4ccccc4)c4nccc2c43)N(c2ccccc2)c2ccnc3c2B5c2cnccc2N3c2ccccc2)cc1]

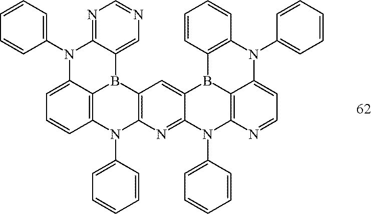 [SMILES: c1ccc(N2c3ccccc3B3c4cc5c(nc4N(c4ccccc4)c4nccc2c43)N(c2ccccc2)c2cccc3c2B5c2cncnc2N3c2ccccc2)cc1]

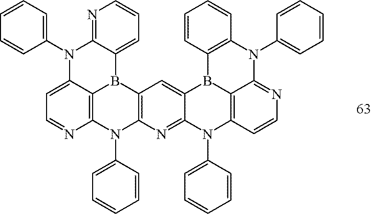 [SMILES: c1ccc(N2c3ccnc4c3B(c3ccccc3N4c3ccccc3)c3cc4c(nc32)N(c2ccccc2)c2nccc3c2B4c2cccnc2N3c2ccccc2)cc1]

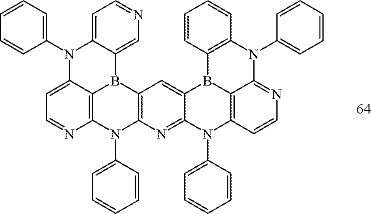 [SMILES: c1ccc(N2c3ccncc3B3c4cc5c(nc4N(c4ccccc4)c4nccc2c43)N(c2ccccc2)c2ccnc3c2B5c2ccccc2N3c2ccccc2)cc1]

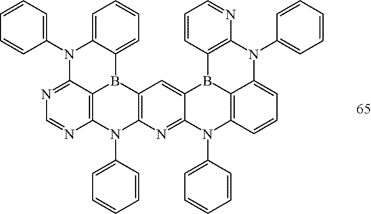 [SMILES: c1ccc(N2c3cccc4c3B(c3cccnc32)c2cc3c(nc2N4c2ccccc2)N(c2ccccc2)c2ncnc4c2B3c2ccccc2N4c2ccccc2)cc1]

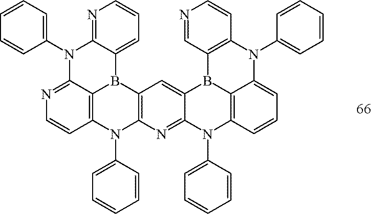 [SMILES: c1ccc(N2c3ccncc3B3c4cc5c(nc4N(c4ccccc4)c4cccc2c43)N(c2ccccc2)c2ccnc3c2B5c2cccnc2N3c2ccccc2)cc1]

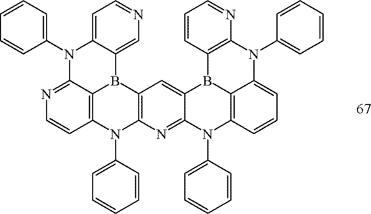 [SMILES: c1ccc(N2c3cccc4c3B(c3cccnc32)c2cc3c(nc2N4c2ccccc2)N(c2ccccc2)c2ccnc4c2B3c2cnccc2N4c2ccccc2)cc1]

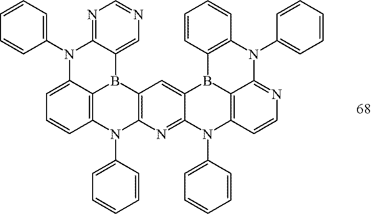 [SMILES: c1ccc(N2c3cccc4c3B(c3cncnc32)c2cc3c(nc2N4c2ccccc2)N(c2ccccc2)c2ccnc4c2B3c2ccccc2N4c2ccccc2)cc1]

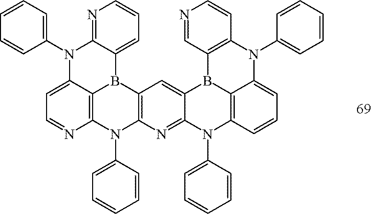 [SMILES: c1ccc(N2c3ccncc3B3c4cc5c(nc4N(c4ccccc4)c4cccc2c43)N(c2ccccc2)c2nccc3c2B5c2cccnc2N3c2ccccc2)cc1]

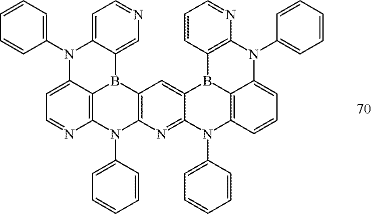 [SMILES: c1ccc(N2c3ccncc3B3c4cc5c(nc4N(c4ccccc4)c4nccc2c43)N(c2ccccc2)c2cccc3c2B5c2cccnc2N3c2ccccc2)cc1]

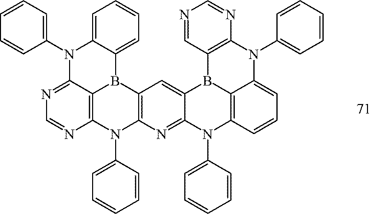 [SMILES: c1ccc(N2c3cccc4c3B(c3cncnc32)c2cc3c(nc2N4c2ccccc2)N(c2ccccc2)c2ncnc4c2B3c2ccccc2N4c2ccccc2)cc1]

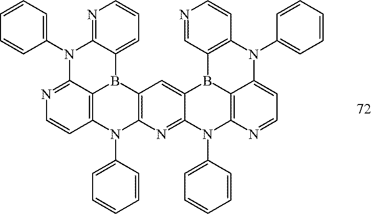 [SMILES: c1ccc(N2c3ccncc3B3c4cc5c(nc4N(c4ccccc4)c4nccc2c43)N(c2ccccc2)c2ccnc3c2B5c2cccnc2N3c2ccccc2)cc1]

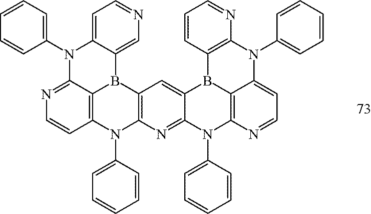 [SMILES: c1ccc(N2c3ccnc4c3B(c3cnccc3N4c3ccccc3)c3cc4c(nc32)N(c2ccccc2)c2nccc3c2B4c2cccnc2N3c2ccccc2)cc1]

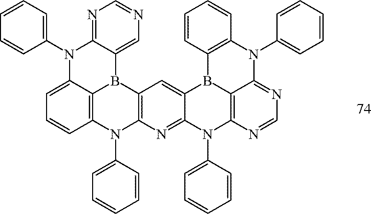 [SMILES: c1ccc(N2c3cccc4c3B(c3cncnc32)c2cc3c(nc2N4c2ccccc2)N(c2ccccc2)c2ncnc4c2B3c2ccccc2N4c2ccccc2)cc1]

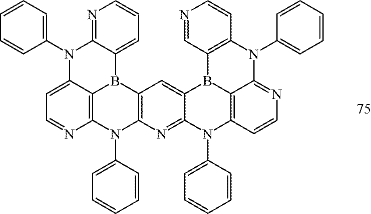 [SMILES: c1ccc(N2c3ccnc4c3B(c3cnccc3N4c3ccccc3)c3cc4c(nc32)N(c2ccccc2)c2nccc3c2B4c2cccnc2N3c2ccccc2)cc1]

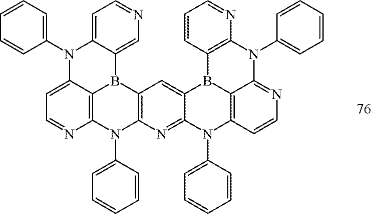 [SMILES: c1ccc(N2c3ccncc3B3c4cc5c(nc4N(c4ccccc4)c4nccc2c43)N(c2ccccc2)c2ccnc3c2B5c2cccnc2N3c2ccccc2)cc1]

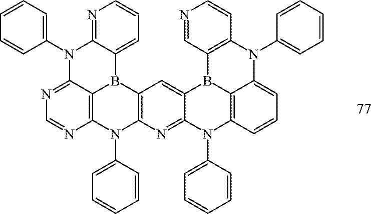 [SMILES: c1ccc(N2c3ccncc3B3c4cc5c(nc4N(c4ccccc4)c4cccc2c43)N(c2ccccc2)c2ncnc3c2B5c2cccnc2N3c2ccccc2)cc1]

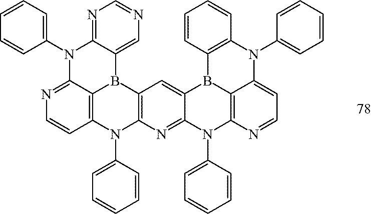 [SMILES: c1ccc(N2c3ccccc3B3c4cc5c(nc4N(c4ccccc4)c4nccc2c43)N(c2ccccc2)c2ccnc3c2B5c2cncnc2N3c2ccccc2)cc1]

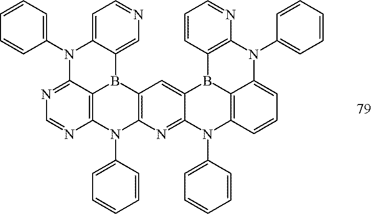 [SMILES: c1ccc(N2c3cccc4c3B(c3cccnc32)c2cc3c(nc2N4c2ccccc2)N(c2ccccc2)c2ncnc4c2B3c2cnccc2N4c2ccccc2)cc1]

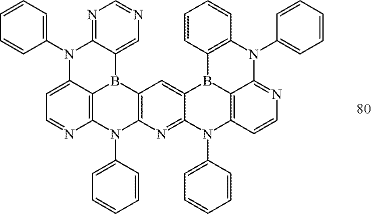 [SMILES: c1ccc(N2c3ccnc4c3B(c3ccccc3N4c3ccccc3)c3cc4c(nc32)N(c2ccccc2)c2nccc3c2B4c2cncnc2N3c2ccccc2)cc1]

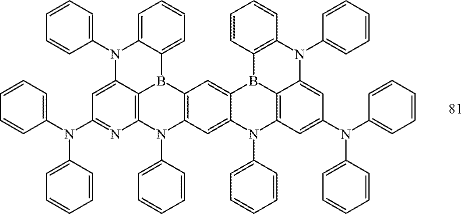 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)nc(c32)N5c2ccccc2)cc1]

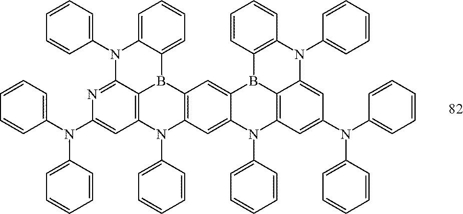 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3nc(N(c4ccccc4)c4ccccc4)cc(c32)N5c2ccccc2)cc1]

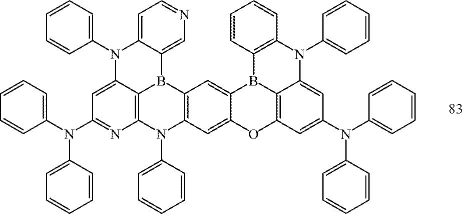 [SMILES: c1ccc(N(c2ccccc2)c2cc3c4c(c2)N(c2ccccc2)c2ccccc2B4c2cc4c(cc2O3)N(c2ccccc2)c2nc(N(c3ccccc3)c3ccccc3)cc3c2B4c2cnccc2N3c2ccccc2)cc1]

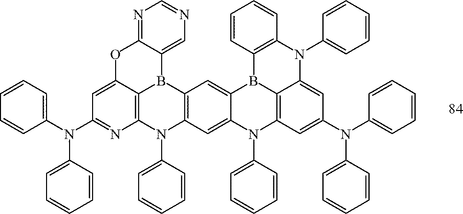 [SMILES: c1ccc(N(c2ccccc2)c2cc3c4c(c2)N(c2ccccc2)c2cc5c(cc2B4c2ccccc2N3c2ccccc2)B2c3cncnc3Oc3cc(N(c4ccccc4)c4ccccc4)nc(c32)N5c2ccccc2)cc1]

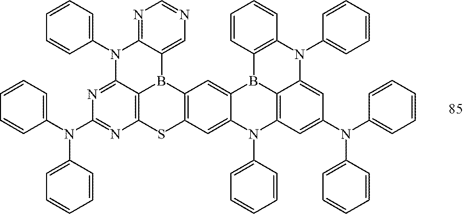 [SMILES: c1ccc(N(c2ccccc2)c2cc3c4c(c2)N(c2ccccc2)c2cc5c(cc2B4c2ccccc2N3c2ccccc2)B2c3cncnc3N(c3ccccc3)c3nc(N(c4ccccc4)c4ccccc4)nc(c32)S5)cc1]

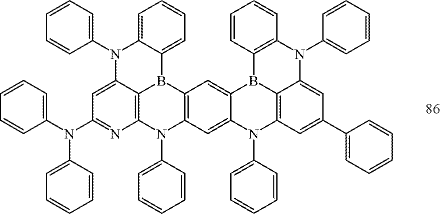 [SMILES: c1ccc(-c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)nc(c32)N5c2ccccc2)cc1]

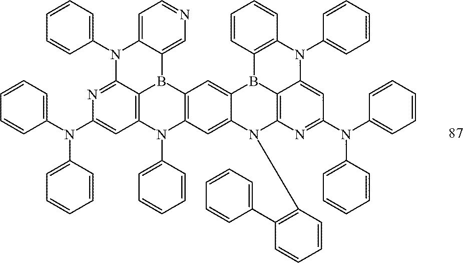 [SMILES: c1ccc(-c2ccccc2N2c3cc4c(cc3B3c5ccccc5N(c5ccccc5)c5cc(N(c6ccccc6)c6ccccc6)nc2c53)B2c3cnccc3N(c3ccccc3)c3nc(N(c5ccccc5)c5ccccc5)cc(c32)N4c2ccccc2)cc1]

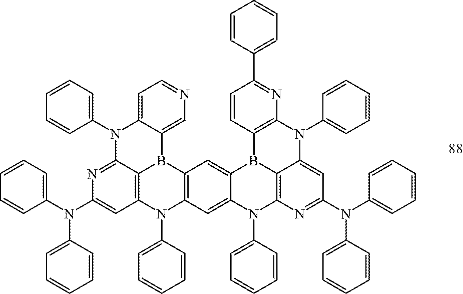 [SMILES: c1ccc(-c2ccc3c(n2)N(c2ccccc2)c2cc(N(c4ccccc4)c4ccccc4)nc4c2B3c2cc3c(cc2N4c2ccccc2)N(c2ccccc2)c2cc(N(c4ccccc4)c4ccccc4)nc4c2B3c2cnccc2N4c2ccccc2)cc1]

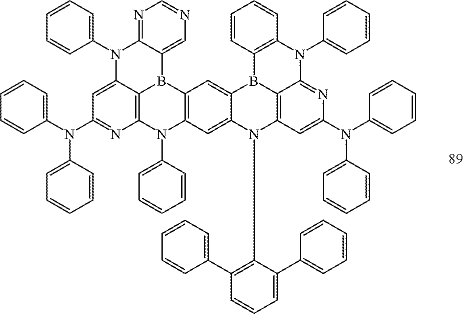 [SMILES: c1ccc(-c2cccc(-c3ccccc3)c2N2c3cc4c(cc3B3c5ccccc5N(c5ccccc5)c5nc(N(c6ccccc6)c6ccccc6)cc2c53)B2c3cncnc3N(c3ccccc3)c3cc(N(c5ccccc5)c5ccccc5)nc(c32)N4c2ccccc2)cc1]

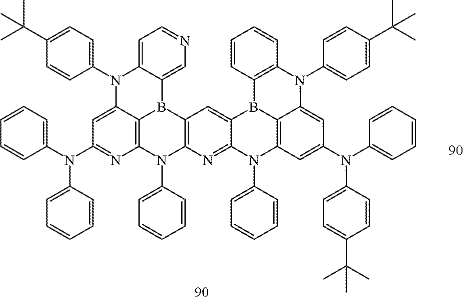

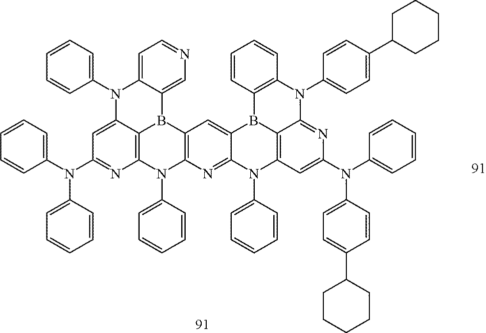

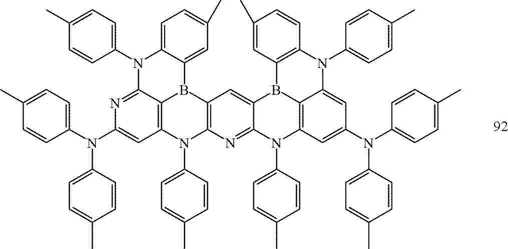

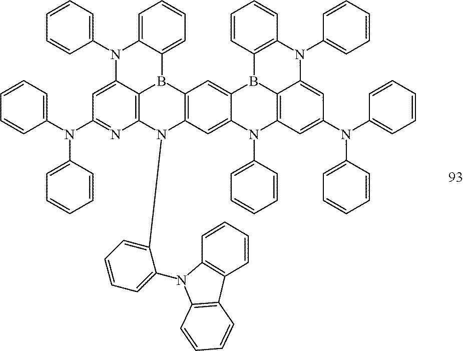 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)nc(c32)N5c2ccccc2-n2c3ccccc3c3ccccc32)cc1]

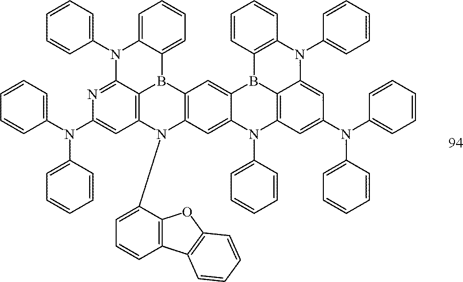 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3nc(N(c4ccccc4)c4ccccc4)cc(c32)N5c2cccc3c2oc2ccccc23)cc1]

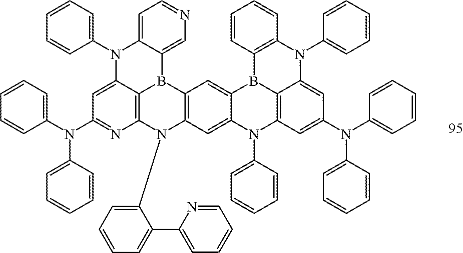 [SMILES: c1ccc(N(c2ccccc2)c2cc3c4c(c2)N(c2ccccc2)c2cc5c(cc2B4c2ccccc2N3c2ccccc2)B2c3cnccc3N(c3ccccc3)c3cc(N(c4ccccc4)c4ccccc4)nc(c32)N5c2ccccc2-c2ccccn2)cc1]

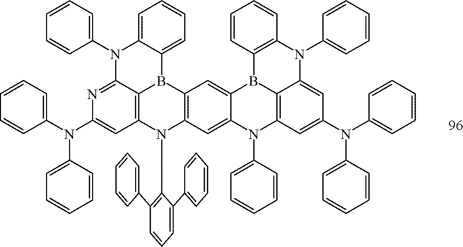 [SMILES: c1ccc(-c2cccc(-c3ccccc3)c2N2c3cc4c(cc3B3c5ccccc5N(c5ccccc5)c5nc(N(c6ccccc6)c6ccccc6)cc2c53)B2c3ccccc3N(c3ccccc3)c3cc(N(c5ccccc5)c5ccccc5)cc(c32)N4c2ccccc2)cc1]

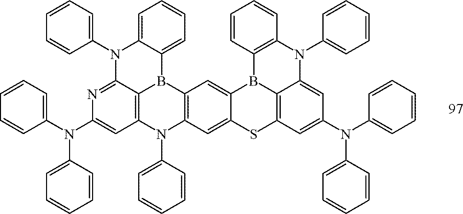 [SMILES: c1ccc(N(c2ccccc2)c2cc3c4c(c2)N(c2ccccc2)c2ccccc2B4c2cc4c(cc2S3)N(c2ccccc2)c2cc(N(c3ccccc3)c3ccccc3)nc3c2B4c2ccccc2N3c2ccccc2)cc1]

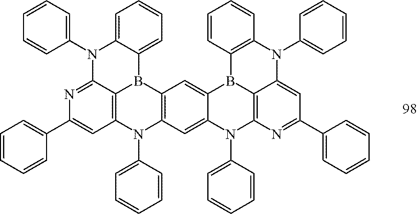 [SMILES: c1ccc(-c2cc3c4c(n2)N(c2ccccc2)c2ccccc2B4c2cc4c(cc2N3c2ccccc2)N(c2ccccc2)c2nc(-c3ccccc3)cc3c2B4c2ccccc2N3c2ccccc2)cc1]

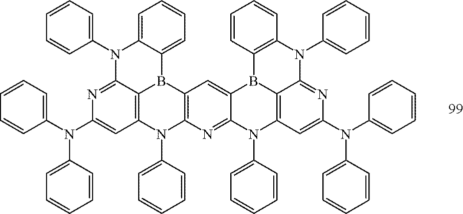 [SMILES: c1ccc(N(c2ccccc2)c2cc3c4c(n2)N(c2ccccc2)c2ccccc2B4c2cc4c(nc2N3c2ccccc2)N(c2ccccc2)c2cc(N(c3ccccc3)c3ccccc3)nc3c2B4c2ccccc2N3c2ccccc2)cc1]

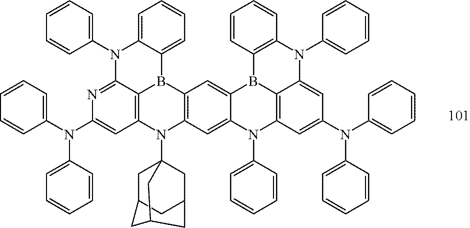 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3nc(N(c4ccccc4)c4ccccc4)cc(c32)N5C23CC4CC(CC(C4)C2)C3)cc1]

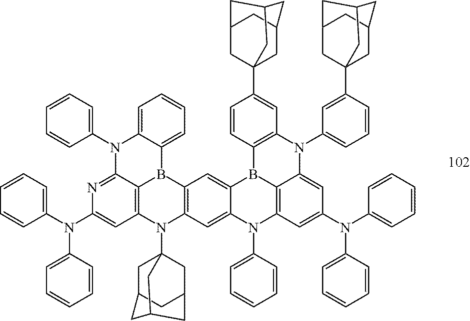 [SMILES: c1ccc(N(c2ccccc2)c2cc3c4c(c2)N(c2ccccc2)c2cc5c(cc2B4c2ccc(C46CC7CC(CC(C7)C4)C6)cc2N3c2cccc(C34CC6CC(CC(C6)C3)C4)c2)B2c3ccccc3N(c3ccccc3)c3nc(N(c4ccccc4)c4ccccc4)cc(c32)N5C23CC4CC(CC(C4)C2)C3)cc1]

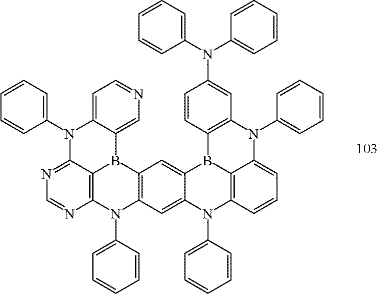 [SMILES: c1ccc(N(c2ccccc2)c2ccc3c(c2)N(c2ccccc2)c2cccc4c2B3c2cc3c(cc2N4c2ccccc2)N(c2ccccc2)c2ncnc4c2B3c2cnccc2N4c2ccccc2)cc1]

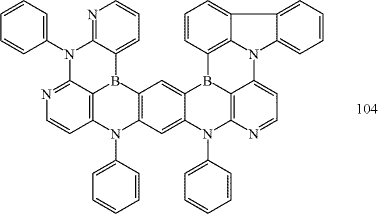 [SMILES: c1ccc(N2c3cc4c(cc3B3c5cccnc5N(c5ccccc5)c5nccc2c53)B2c3c(ccnc3N4c3ccccc3)-n3c4ccccc4c4cccc2c43)cc1]

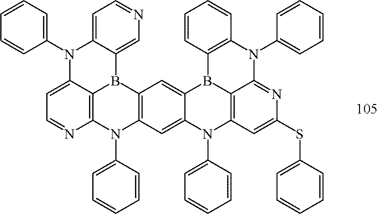 [SMILES: c1ccc(Sc2cc3c4c(n2)N(c2ccccc2)c2ccccc2B4c2cc4c(cc2N3c2ccccc2)N(c2ccccc2)c2nccc3c2B4c2cnccc2N3c2ccccc2)cc1]

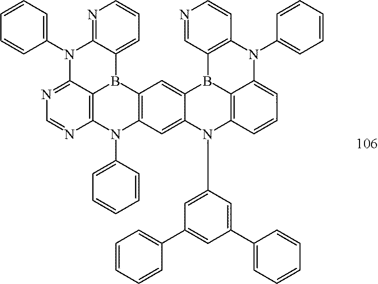 [SMILES: c1ccc(-c2cc(-c3ccccc3)cc(N3c4cc5c(cc4B4c6cnccc6N(c6ccccc6)c6cccc3c64)B3c4cccnc4N(c4ccccc4)c4ncnc(c43)N5c3ccccc3)c2)cc1]

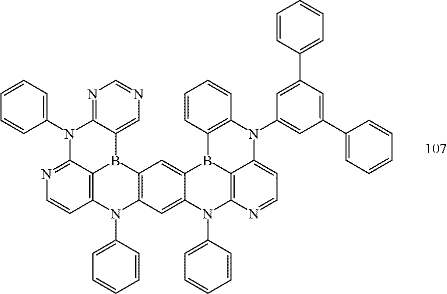 [SMILES: c1ccc(-c2cc(-c3ccccc3)cc(N3c4ccccc4B4c5cc6c(cc5N(c5ccccc5)c5nccc3c54)N(c3ccccc3)c3ccnc4c3B6c3cncnc3N4c3ccccc3)c2)cc1]

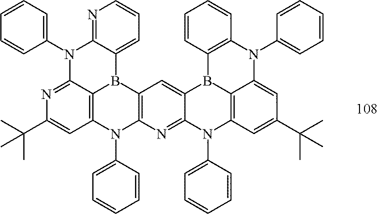 [SMILES: CC(C)(C)c1cc2c3c(c1)N(c1ccccc1)c1nc4c(cc1B3c1ccccc1N2c1ccccc1)B1c2cccnc2N(c2ccccc2)c2nc(C(C)(C)C)cc(c21)N4c1ccccc1]

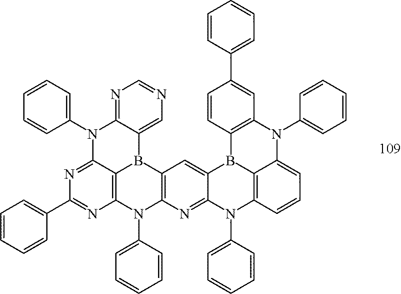 [SMILES: c1ccc(-c2ccc3c(c2)N(c2ccccc2)c2cccc4c2B3c2cc3c(nc2N4c2ccccc2)N(c2ccccc2)c2nc(-c4ccccc4)nc4c2B3c2cncnc2N4c2ccccc2)cc1]

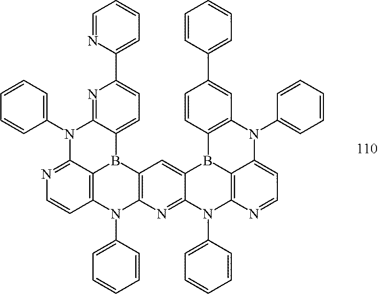 [SMILES: c1ccc(-c2ccc3c(c2)N(c2ccccc2)c2ccnc4c2B3c2cc3c(nc2N4c2ccccc2)N(c2ccccc2)c2ccnc4c2B3c2ccc(-c3ccccn3)nc2N4c2ccccc2)cc1]

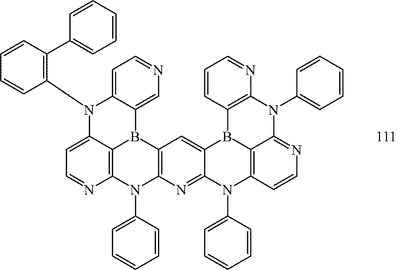 [SMILES: c1ccc(-c2ccccc2N2c3ccncc3B3c4cc5c(nc4N(c4ccccc4)c4nccc2c43)N(c2ccccc2)c2ccnc3c2B5c2cccnc2N3c2ccccc2)cc1]

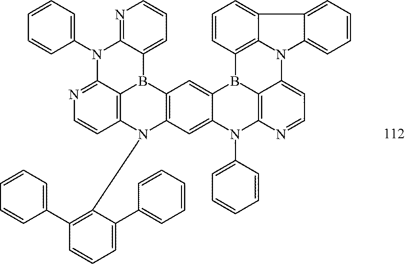 [SMILES: c1ccc(-c2cccc(-c3ccccc3)c2N2c3cc4c(cc3B3c5cccnc5N(c5ccccc5)c5nccc2c53)B2c3c(ccnc3N4c3ccccc3)-n3c4ccccc4c4cccc2c43)cc1]

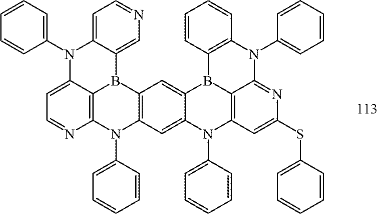 [SMILES: c1ccc(Sc2cc3c4c(n2)N(c2ccccc2)c2ccccc2B4c2cc4c(cc2N3c2ccccc2)N(c2ccccc2)c2nccc3c2B4c2cnccc2N3c2ccccc2)cc1]

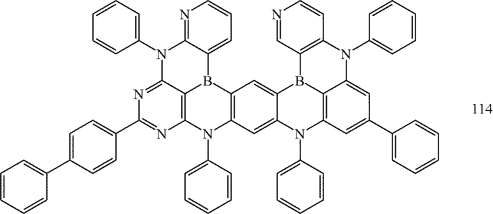 [SMILES: c1ccc(-c2ccc(-c3nc4c5c(n3)N(c3ccccc3)c3ncccc3B5c3cc5c(cc3N4c3ccccc3)N(c3ccccc3)c3cc(-c4ccccc4)cc4c3B5c3cnccc3N4c3ccccc3)cc2)cc1]

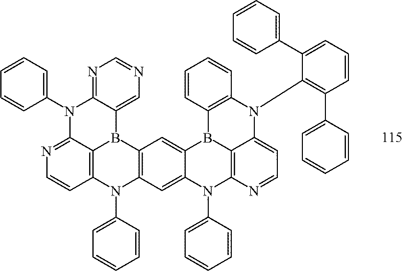 [SMILES: c1ccc(-c2cccc(-c3ccccc3)c2N2c3ccccc3B3c4cc5c(cc4N(c4ccccc4)c4nccc2c43)N(c2ccccc2)c2ccnc3c2B5c2cncnc2N3c2ccccc2)cc1]

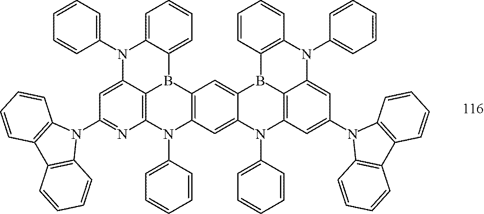 [SMILES: c1ccc(N2c3ccccc3B3c4cc5c(cc4N(c4ccccc4)c4cc(-n6c7ccccc7c7ccccc76)cc2c43)N(c2ccccc2)c2nc(-n3c4ccccc4c4ccccc43)cc3c2B5c2ccccc2N3c2ccccc2)cc1]

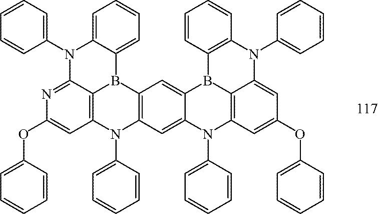 [SMILES: c1ccc(Oc2cc3c4c(c2)N(c2ccccc2)c2cc5c(cc2B4c2ccccc2N3c2ccccc2)B2c3ccccc3N(c3ccccc3)c3nc(Oc4ccccc4)cc(c32)N5c2ccccc2)cc1]

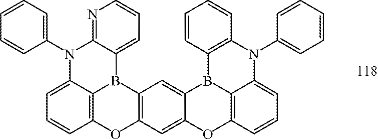 [SMILES: c1ccc(N2c3ccccc3B3c4cc5c(cc4Oc4cccc2c43)Oc2cccc3c2B5c2cccnc2N3c2ccccc2)cc1]

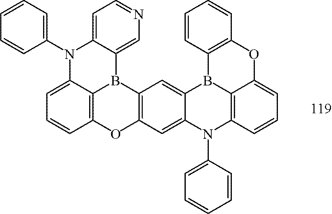 [SMILES: c1ccc(N2c3ccncc3B3c4cc5c(cc4Oc4cccc2c43)N(c2ccccc2)c2cccc3c2B5c2ccccc2O3)cc1]

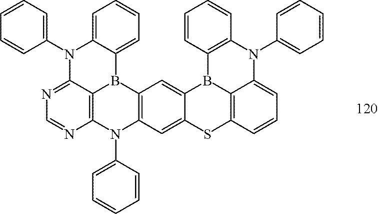 [SMILES: c1ccc(N2c3ccccc3B3c4cc5c(cc4Sc4cccc2c43)N(c2ccccc2)c2ncnc3c2B5c2ccccc2N3c2ccccc2)cc1]

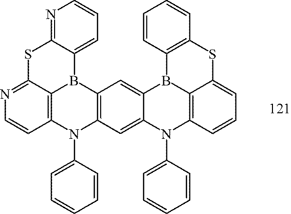 [SMILES: c1ccc(N2c3cc4c(cc3B3c5ccccc5Sc5cccc2c53)B2c3cccnc3Sc3nccc(c32)N4c2ccccc2)cc1]

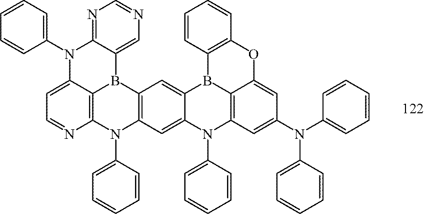 [SMILES: c1ccc(N(c2ccccc2)c2cc3c4c(c2)N(c2ccccc2)c2cc5c(cc2B4c2ccccc2O3)B2c3cncnc3N(c3ccccc3)c3ccnc(c32)N5c2ccccc2)cc1]

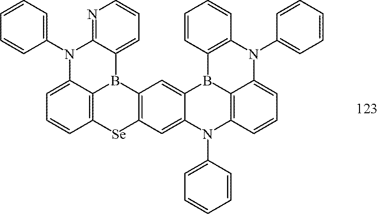 [SMILES: c1ccc(N2c3ccccc3B3c4cc5c(cc4N(c4ccccc4)c4cccc2c43)[Se]c2cccc3c2B5c2cccnc2N3c2ccccc2)cc1]

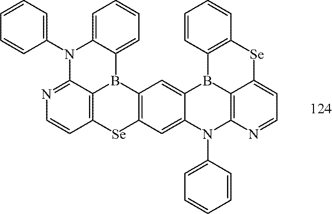 [SMILES: c1ccc(N2c3ccccc3B3c4cc5c(cc4[Se]c4ccnc2c43)N(c2ccccc2)c2nccc3c2B5c2ccccc2[Se]3)cc1]

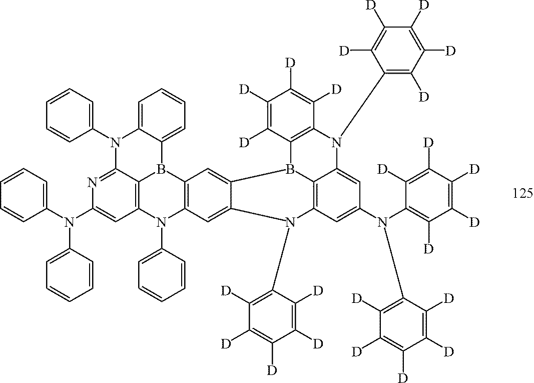 [SMILES: [2H]c1c([2H])c([2H])c(N(C)c2cc(N(c3c([2H])c([2H])c([2H])c([2H])c3[2H])c3c([2H])c([2H])c([2H])c([2H])c3[2H])cc3c2B(c2ccc4c(c2)B2c5ccccc5N(c5ccccc5)c5nc(N(c6ccccc6)c6ccccc6)cc(c52)N4c2ccccc2)c2c([2H])c([2H])c([2H])c([2H])c2N3c2c([2H])c([2H])c([2H])c([2H])c2[2H])c([2H])c1[2H]]

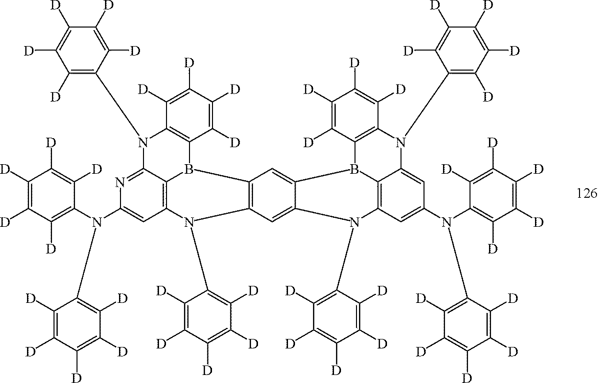 [SMILES: [2H]c1c([2H])c([2H])c(N(C)c2cc(N(c3c([2H])c([2H])c([2H])c([2H])c3[2H])c3c([2H])c([2H])c([2H])c([2H])c3[2H])cc3c2B(c2ccc4c(c2)B2c5c(cc(N(c6c([2H])c([2H])c([2H])c([2H])c6[2H])c6c([2H])c([2H])c([2H])c([2H])c6[2H])nc5N(c5c([2H])c([2H])c([2H])c([2H])c5[2H])c5c([2H])c([2H])c([2H])c([2H])c52)N4c2c([2H])c([2H])c([2H])c([2H])c2[2H])c2c([2H])c([2H])c([2H])c([2H])c2N3c2c([2H])c([2H])c([2H])c([2H])c2[2H])c([2H])c1[2H]]

The polycyclic compound of an embodiment has a structure including two boron atoms and at least one pyridinic nitrogen atom. Accordingly, the polycyclic compound of an embodiment may have the maximum emission wavelength of about 450 nm to less than about 470 nm and may be to emit blue light. In some embodiments, the light emitting element includes the polycyclic compound of an embodiment in an emission layer and may show high emission efficiency properties.

The polycyclic compound of an embodiment, represented by Formula 1, may be utilized as a fluorescence emitting material or a thermally activated delayed fluorescence (TADF) material. For example, the polycyclic compound of an embodiment may be utilized as a light emitting dopant which emits blue light. In some embodiments, the polycyclic compound of an embodiment may be utilized as a TADF dopant material.

The polycyclic compound of an embodiment, represented by Formula 1, may be a light emitting material having the maximum emission wavelength in a wavelength region of about 450 nm to less than about 470 nm. For example, the polycyclic compound of an embodiment may be a blue thermally activated delayed fluorescence dopant. However, an embodiment of the present disclosure is not limited thereto.

In the light emitting elements ED of embodiments, shown in FIG. 3 to FIG. 6, an emission layer EML may include a host and a dopant, and the emission layer EML may include the polycyclic compound of an embodiment as a light emitting dopant.

In the light emitting element ED of an embodiment, an emission layer EML may include a first compound to a third compound, which are different from each other. The first compound may be represented by Formula 1. The first compound may be a light emitting dopant, the second compound may be a first host, and the third compound may be a second host. In an embodiment, the second compound may be a hole transport host, and the third compound may be an electron transport host.

The light emitting element ED of an embodiment may include at least one compound selected from among HT-1 to HT-4 in an emission layer EML as a hole transport host.

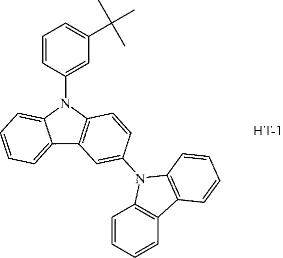 [SMILES: CC(C)(C)c1cccc(-n2c3ccccc3c3cc(-n4c5ccccc5c5ccccc54)ccc32)c1]

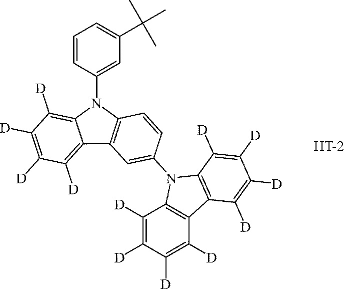 [SMILES: [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1]

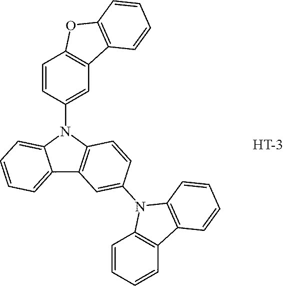 [SMILES: c1ccc2c(c1)oc1ccc(-n3c4ccccc4c4cc(-n5c6ccccc6c6ccccc65)ccc43)cc12]

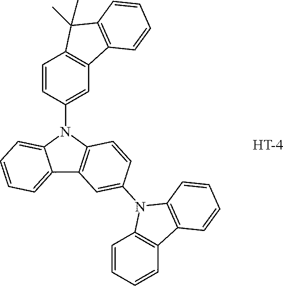 [SMILES: CC1(C)c2ccccc2-c2cc(-n3c4ccccc4c4cc(-n5c6ccccc6c6ccccc65)ccc43)ccc21]

In some embodiments, the light emitting element ED of an embodiment may include at least one compound selected from among ET-1 to ET-3 in an emission layer EML as an electron transport host.

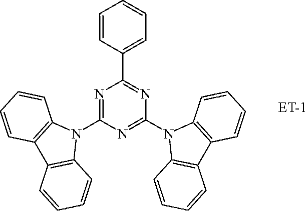 [SMILES: c1ccc(-c2nc(-n3c4ccccc4c4ccccc43)nc(-n3c4ccccc4c4ccccc43)n2)cc1]

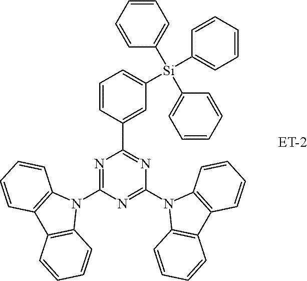 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1]

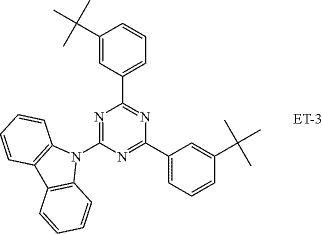 [SMILES: CC(C)(C)c1cccc(-c2nc(-c3cccc(C(C)(C)C)c3)nc(-n3c4ccccc4c4ccccc43)n2)c1]

The electron transport host and the hole transport host may be combined to form an exciplex. The exciplex may transfer energy through energy transition to a phosphorescence dopant and/or a thermally activated delayed fluorescence dopant to enable or improve light emission.

The triplet energy of the exciplex formed by the hole transport host and the electron transport host may correspond to a difference between the energy level of the lowest unoccupied molecular orbital (LUMO) of the electron transport host and the energy level of the highest occupied molecular orbital (HOMO) of the hole transport host. For example, the triplet energy of the exciplex formed by the hole transport host and the electron transport host in the light emitting element may be from about 2.4 eV to about 3.0 eV. In some embodiments, the triplet energy of the exciplex may be a value smaller than the energy gap of each host material. The energy gap may be a difference between the LUMO energy level and the HOMO energy level. For example, the energy gap of each of the hole transport host and the electron transport host may be about 3.0 eV or more, and the exciplex may have the triplet energy of about 3.0 eV or less.

In the light emitting element ED of an embodiment, the emission layer EML may further include a fourth compound represented by Formula M-b. The fourth compound may be an auxiliary dopant. In the light emitting element ED of an embodiment, the auxiliary dopant included in the emission layer EML may transfer energy to a light emitting dopant to increase the ratio of fluorescence emission by the light emitting dopant.

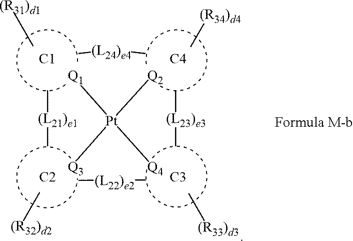

In Formula M-b, Q₁ to Q₄ may each independently be C or N, and C1 to C4 may each independently be a substituted or unsubstituted hydrocarbon ring having 5 to 30 ring-forming carbon atoms, or a substituted or unsubstituted heterocycle having 2 to 30 ring-forming carbon atoms. L₂₁ to L₂₄ may each independently be a direct linkage,

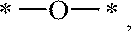

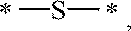

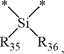

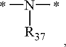

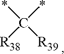

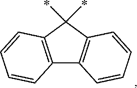

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

e1 to e4 may each independently be 0 or 1, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or combined with an adjacent group to form a ring, and d1 to d4 may each independently be an integer of 0 to 4.

In the light emitting element ED, the emission layer EML may include at least one selected from among M-b-1 to M-b-13 as the auxiliary dopant.

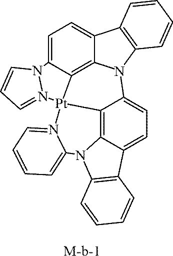

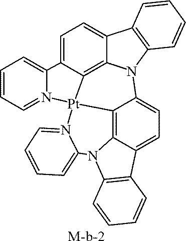

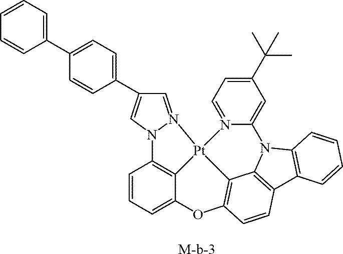

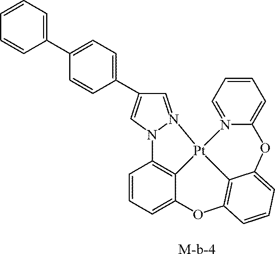

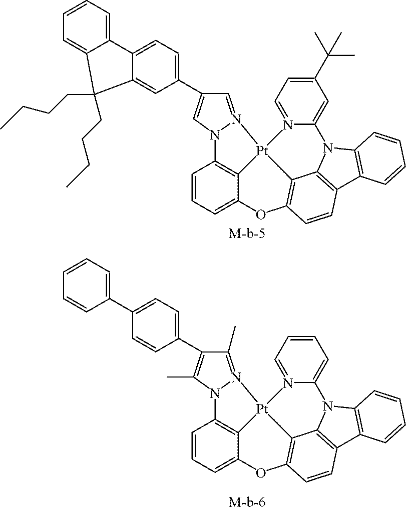

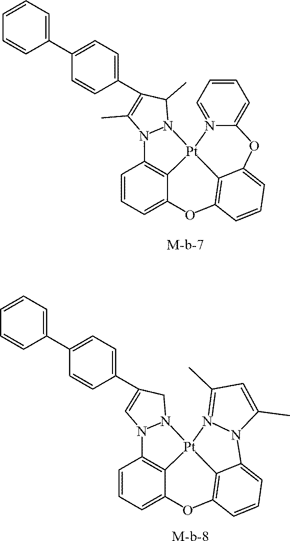

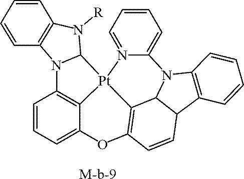

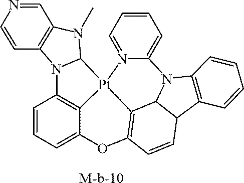

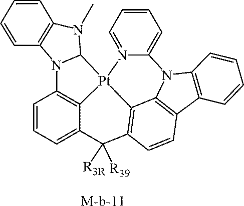

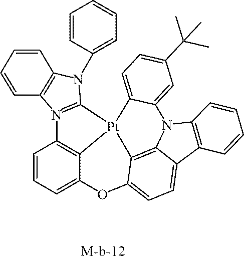

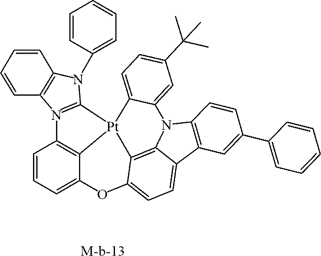

In M-b-1 to M-b-13 above, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

However, an embodiment of the present disclosure is not limited thereto, and the light emitting element ED of an embodiment may include a suitable phosphorescence dopant material which is an organometallic complex.

The light emitting element ED of an embodiment may include the first host, the second host, the auxiliary dopant and the polycyclic compound of an embodiment as the light emitting dopant in the emission layer EML, and may show improved emission efficiency properties.

The light emitting element ED of an embodiment may further include an emission layer material in addition to the polycyclic compound of an embodiment, the first and second hosts, and the auxiliary dopant material. In the light emitting element ED of an embodiment, the emission layer EML may include one or more derivatives, pyrene derivatives, fluoranthene derivatives, chrysene derivatives, dihydrobenzanthracene derivatives, and/or triphenylene derivatives. For example, the emission layer EML may include one or more anthracene derivatives and/or pyrene derivatives.

In the light emitting elements ED of embodiments, shown in FIG. 3 to FIG. 6, the emission layer EML may include a host and a dopant, and the emission layer EML may include a compound represented by Formula E-1. The compound represented by Formula E-1 may be utilized as a fluorescence host material.

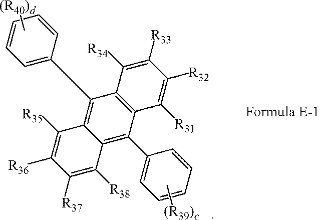

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be combined with an adjacent group to form a ring. In some embodiments, R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may each independently be an integer of 0 to 5.

Formula E-1 may be represented by any one selected from among Compound E1 to Compound E19.

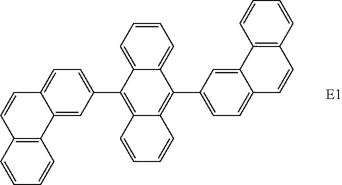 [SMILES: c1ccc2c(c1)ccc1ccc(-c3c4ccccc4c(-c4ccc5ccc6ccccc6c5c4)c4ccccc34)cc12]

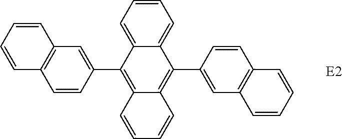 [SMILES: c1ccc2cc(-c3c4ccccc4c(-c4ccc5ccccc5c4)c4ccccc34)ccc2c1]

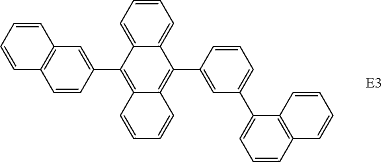 [SMILES: c1cc(-c2cccc3ccccc23)cc(-c2c3ccccc3c(-c3ccc4ccccc4c3)c3ccccc23)c1]

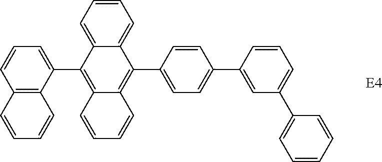 [SMILES: c1ccc(-c2cccc(-c3ccc(-c4c5ccccc5c(-c5cccc6ccccc56)c5ccccc45)cc3)c2)cc1]

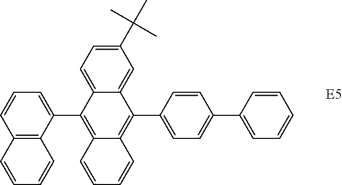 [SMILES: CC(C)(C)c1ccc2c(-c3cccc4ccccc34)c3ccccc3c(-c3ccc(-c4ccccc4)cc3)c2c1]

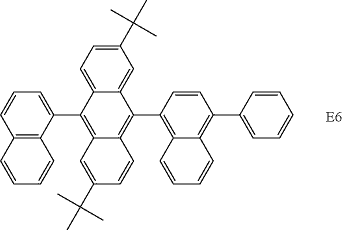 [SMILES: CC(C)(C)c1ccc2c(-c3ccc(-c4ccccc4)c4ccccc34)c3cc(C(C)(C)C)ccc3c(-c3cccc4ccccc34)c2c1]

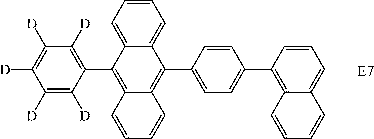 [SMILES: [2H]c1c([2H])c([2H])c(-c2c3ccccc3c(-c3ccc(-c4cccc5ccccc45)cc3)c3ccccc23)c([2H])c1[2H]]

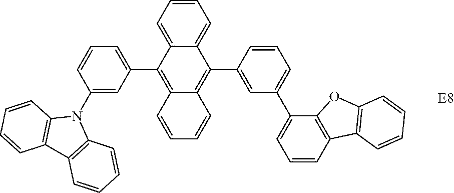 [SMILES: c1cc(-c2c3ccccc3c(-c3cccc(-n4c5ccccc5c5ccccc54)c3)c3ccccc23)cc(-c2cccc3c2oc2ccccc23)c1]

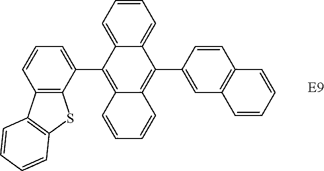 [SMILES: c1ccc2cc(-c3c4ccccc4c(-c4cccc5c4sc4ccccc45)c4ccccc34)ccc2c1]

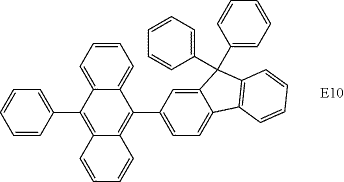 [SMILES: c1ccc(-c2c3ccccc3c(-c3ccc4c(c3)C(c3ccccc3)(c3ccccc3)c3ccccc3-4)c3ccccc23)cc1]

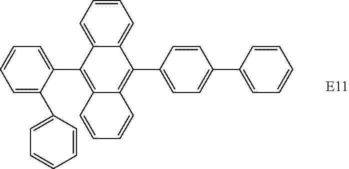 [SMILES: c1ccc(-c2ccc(-c3c4ccccc4c(-c4ccccc4-c4ccccc4)c4ccccc34)cc2)cc1]

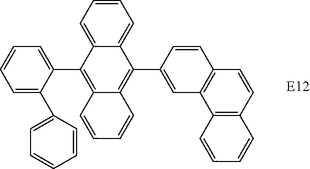 [SMILES: c1ccc(-c2ccccc2-c2c3ccccc3c(-c3ccc4ccc5ccccc5c4c3)c3ccccc23)cc1]

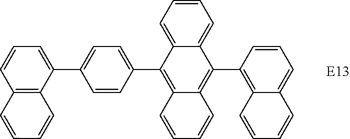 [SMILES: c1ccc2c(-c3ccc(-c4c5ccccc5c(-c5cccc6ccccc56)c5ccccc45)cc3)cccc2c1]

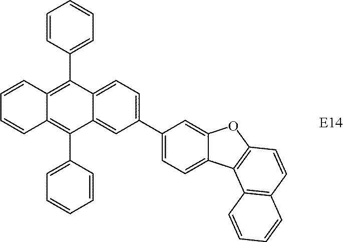 [SMILES: c1ccc(-c2c3ccccc3c(-c3ccccc3)c3cc(-c4ccc5c(c4)oc4ccc6ccccc6c45)ccc23)cc1]

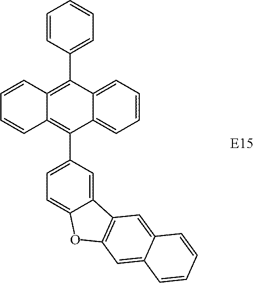 [SMILES: c1ccc(-c2c3ccccc3c(-c3ccc4oc5cc6ccccc6cc5c4c3)c3ccccc23)cc1]

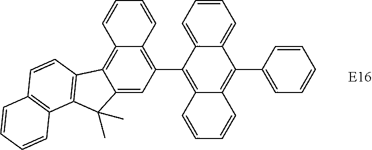 [SMILES: CC1(C)c2cc(-c3c4ccccc4c(-c4ccccc4)c4ccccc34)c3ccccc3c2-c2ccc3ccccc3c21]

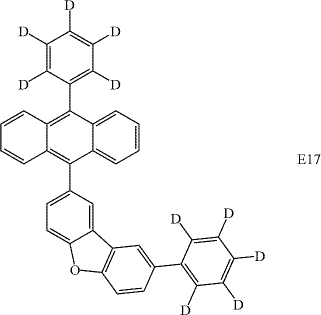 [SMILES: [2H]c1c([2H])c([2H])c(-c2ccc3oc4ccc(-c5c6ccccc6c(-c6c([2H])c([2H])c([2H])c([2H])c6[2H])c6ccccc56)cc4c3c2)c([2H])c1[2H]]

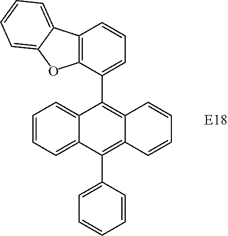 [SMILES: c1ccc(-c2c3ccccc3c(-c3cccc4c3oc3ccccc34)c3ccccc23)cc1]

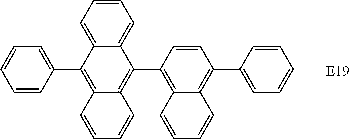 [SMILES: c1ccc(-c2ccc(-c3c4ccccc4c(-c4ccccc4)c4ccccc34)c3ccccc23)cc1]

In an embodiment, the emission layer EML may include a compound represented by Formula E-2a or Formula E-2b. The compound represented by Formula E-2a or Formula E-2b may be utilized as a phosphorescence host material.

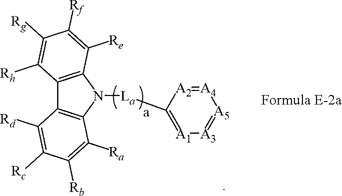

In Formula E-2a, “a” may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when “a” is an integer of 2 or more, two or more Lₐ may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRi. Rₐ to Ri may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be combined with an adjacent group to form a ring. Rₐ to Rᵢ may be combined with an adjacent group to form a hydrocarbon ring or a heterocycle including N, O, S, etc. as a ring-forming atom.

In some embodiments, in Formula E-2a, two or three selected from A₁ to A₅ may be N, and the remainder thereof may be CRᵢ.

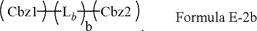

In Formula E-2b, Cbz1 and Cbz2 may each independently be an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. “b” is an integer of 0 to 10, and when “b” is an integer of 2 or more, two or more L_{b} may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among the compounds in Compound Group E-2. However, the compounds shown in Compound Group E-2 are only examples, and the compound represented by Formula E-2a or Formula E-2b is not limited to the compounds represented in Compound Group E-2.

### Compound Group E-2

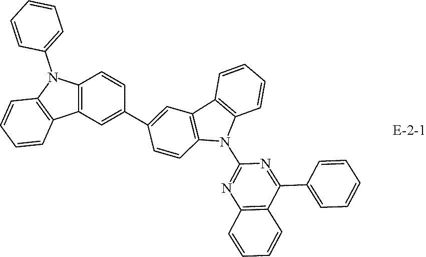 [SMILES: c1ccc(-c2nc(-n3c4ccccc4c4cc(-c5ccc6c(c5)c5ccccc5n6-c5ccccc5)ccc43)nc3ccccc23)cc1]

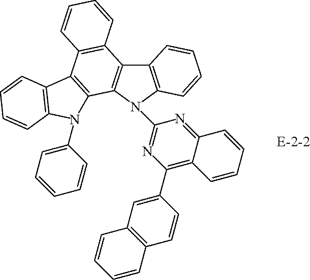 [SMILES: c1ccc(-n2c3ccccc3c3c4ccccc4c4c5ccccc5n(-c5nc(-c6ccc7ccccc7c6)c6ccccc6n5)c4c32)cc1]

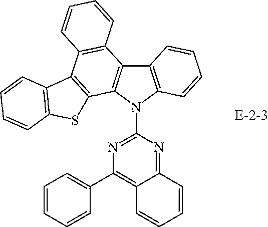 [SMILES: c1ccc(-c2nc(-n3c4ccccc4c4c5ccccc5c5c6ccccc6sc5c43)nc3ccccc23)cc1]

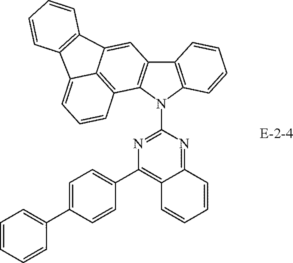 [SMILES: c1ccc(-c2ccc(-c3nc(-n4c5ccccc5c5cc6c7c(cccc7c54)-c4ccccc4-6)nc4ccccc34)cc2)cc1]

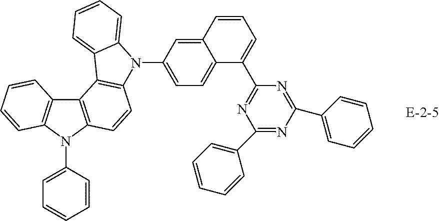 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1]

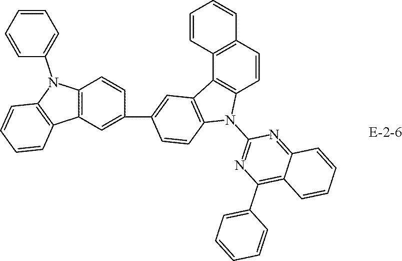 [SMILES: c1ccc(-c2nc(-n3c4ccc(-c5ccc6c(c5)c5ccccc5n6-c5ccccc5)cc4c4c5ccccc5ccc43)nc3ccccc23)cc1]

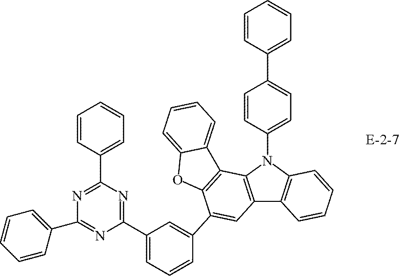 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

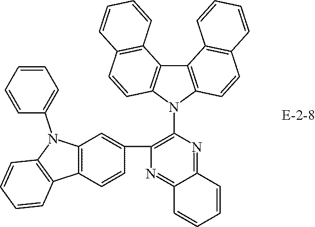 [SMILES: c1ccc(-n2c3ccccc3c3ccc(-c4nc5ccccc5nc4-n4c5ccc6ccccc6c5c5c6ccccc6ccc54)cc32)cc1]

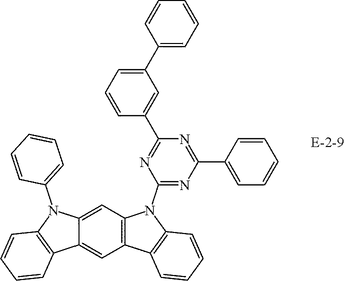 [SMILES: c1ccc(-c2cccc(-c3nc(-c4ccccc4)nc(-n4c5ccccc5c5cc6c7ccccc7n(-c7ccccc7)c6cc54)n3)c2)cc1]

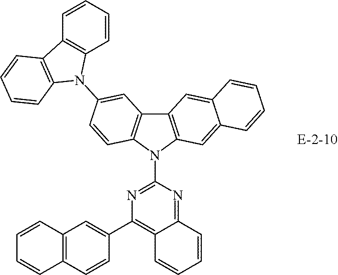 [SMILES: c1ccc2cc(-c3nc(-n4c5ccc(-n6c7ccccc7c7ccccc76)cc5c5cc6ccccc6cc54)nc4ccccc34)ccc2c1]

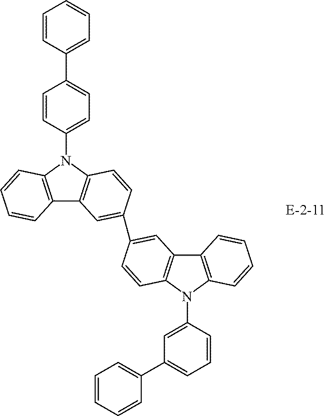 [SMILES: c1ccc(-c2ccc(-n3c4ccccc4c4cc(-c5ccc6c(c5)c5ccccc5n6-c5cccc(-c6ccccc6)c5)ccc43)cc2)cc1]

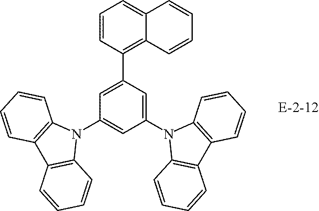 [SMILES: c1ccc2c(-c3cc(-n4c5ccccc5c5ccccc54)cc(-n4c5ccccc5c5ccccc54)c3)cccc2c1]

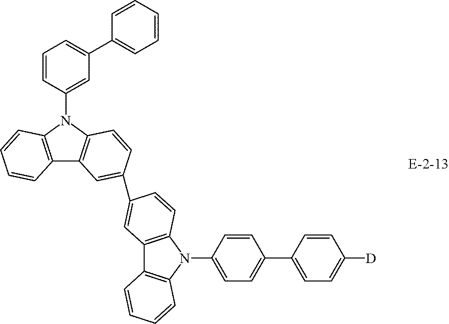 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1]

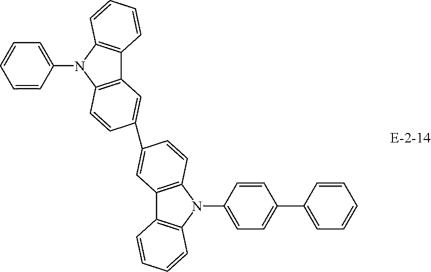 [SMILES: c1ccc(-c2ccc(-n3c4ccccc4c4cc(-c5ccc6c(c5)c5ccccc5n6-c5ccccc5)ccc43)cc2)cc1]

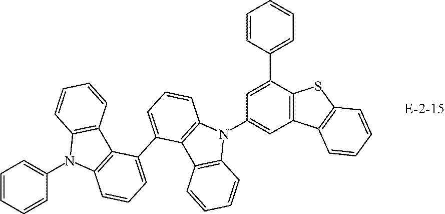 [SMILES: c1ccc(-c2cc(-n3c4ccccc4c4c(-c5cccc6c5c5ccccc5n6-c5ccccc5)cccc43)cc3c2sc2ccccc23)cc1]

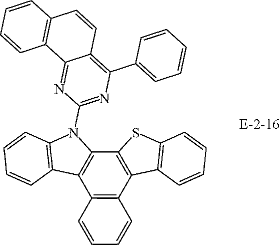 [SMILES: c1ccc(-c2nc(-n3c4ccccc4c4c5ccccc5c5c6ccccc6sc5c43)nc3c2ccc2ccccc23)cc1]

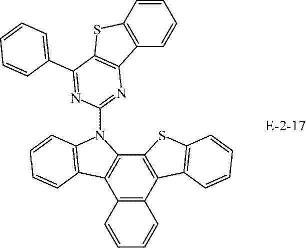 [SMILES: c1ccc(-c2nc(-n3c4ccccc4c4c5ccccc5c5c6ccccc6sc5c43)nc3c2sc2ccccc23)cc1]

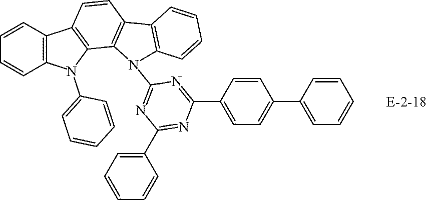 [SMILES: c1ccc(-c2ccc(-c3nc(-c4ccccc4)nc(-n4c5ccccc5c5ccc6c7ccccc7n(-c7ccccc7)c6c54)n3)cc2)cc1]

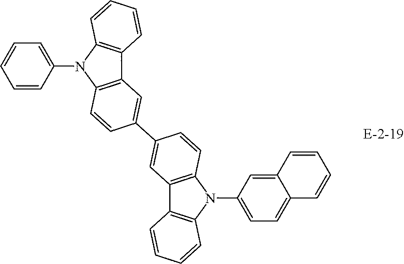 [SMILES: c1ccc(-n2c3ccccc3c3cc(-c4ccc5c(c4)c4ccccc4n5-c4ccc5ccccc5c4)ccc32)cc1]

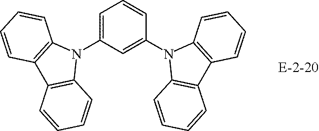 [SMILES: c1cc(-n2c3ccccc3c3ccccc32)cc(-n2c3ccccc3c3ccccc32)c1]

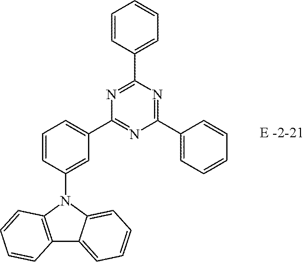 [SMILES: c1ccc(-c2nc(-c3ccccc3)nc(-c3cccc(-n4c5ccccc5c5ccccc54)c3)n2)cc1]

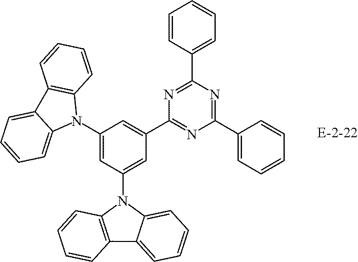 [SMILES: c1ccc(-c2nc(-c3ccccc3)nc(-c3cc(-n4c5ccccc5c5ccccc54)cc(-n4c5ccccc5c5ccccc54)c3)n2)cc1]

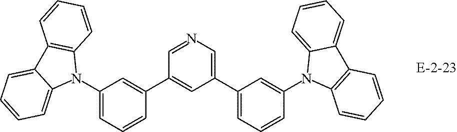 [SMILES: c1cc(-c2cncc(-c3cccc(-n4c5ccccc5c5ccccc54)c3)c2)cc(-n2c3ccccc3c3ccccc32)c1]

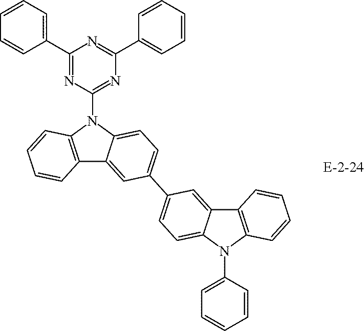 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a suitable common material in the art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(carbazol-9-yl)biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, an embodiment of the present disclosure is not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as the host material.

The emission layer EML may include a compound represented by Formula M-a or Formula M-b. The compound represented by Formula M-a or Formula M-b may be utilized as a phosphorescence dopant material.

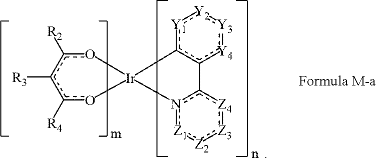

In Formula M-a, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be combined with an adjacent group to form a ring. In Formula M-a, “m” is 0 or 1, and “n” is 2 or 3. In Formula M-a, when “m” is 0, “n” is 3, and when “m” is 1, “n” is 2.

The compound represented by Formula M-a may be utilized as a phosphorescence dopant.

The compound represented by Formula M-a may be represented by any one selected from among Compounds M-a1 to M-a25. However, Compounds M-a1 to Ma25 are examples, and the compound represented by Formula M-a is not limited to the compounds represented by Compounds M-a1 to M-a25.

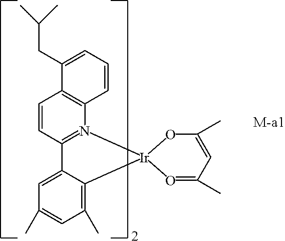

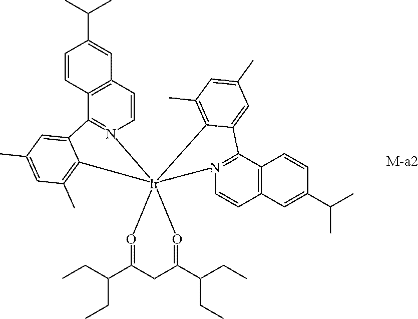

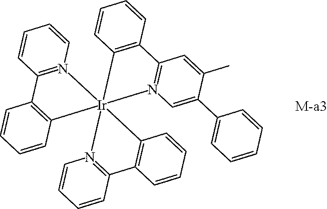

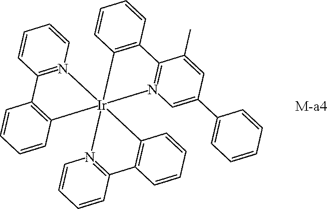

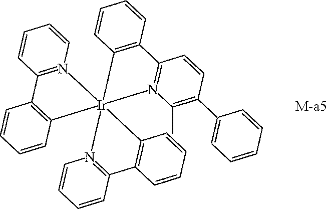

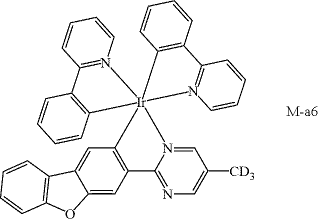

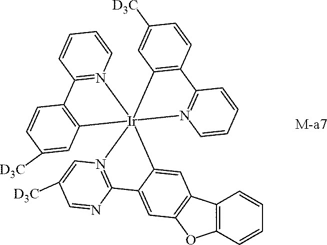

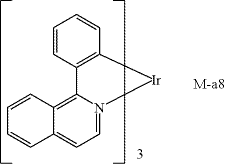

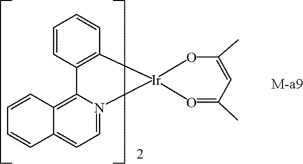

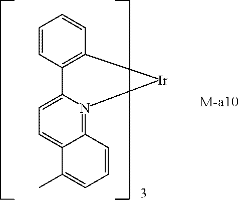

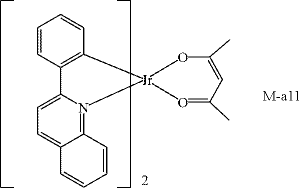

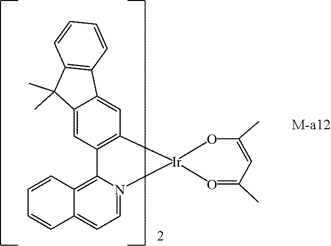

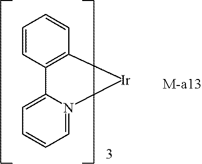

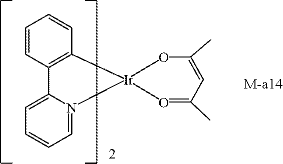

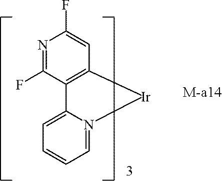

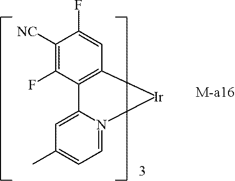

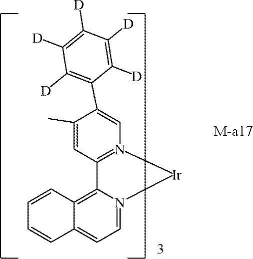

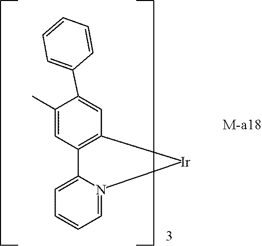

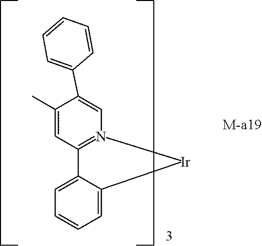

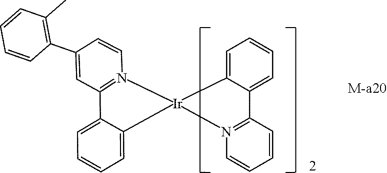

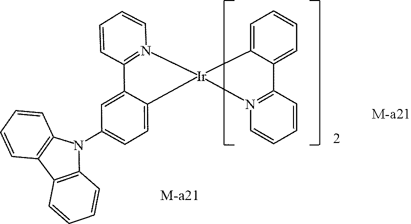

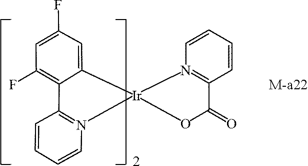

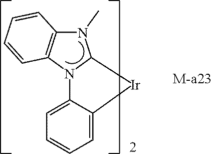

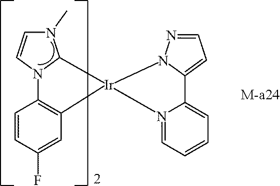

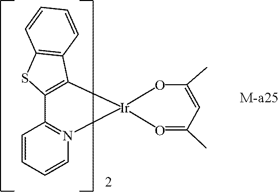

.

The emission layer EML may include a compound represented by any one selected from among Formula F-a to Formula F-c. The compounds represented by Formula F-a to Formula F-c may be utilized as fluorescence dopant materials.

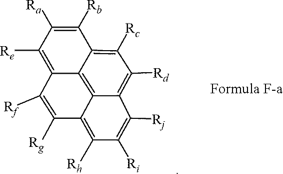

In Formula F-a, two groups selected from Rₐ to Rⱼ may each independently be substituted with *—^{NAr}₁^{Ar}₂. The remainder groups not substituted with *—NAr₁Ar₂ selected from among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *^{—NAr1Ar2}, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one selected from among Ar₁ and Ar₂ may be a heteroaryl group including O or S as a ring-forming atom.

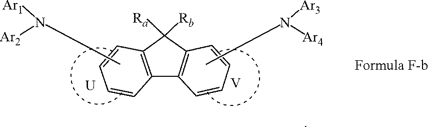

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be combined with an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, one ring indicated by U or V forms a fused ring at the designated part (e.g., at the part indicated by U or V),, and when the number of U or V is 0, a ring does not exist at the part designated by U or V. For example, when the number of U is 0, and the number of V is 1, or when the number of U is 1, and the number of V is 0, a fused ring having the fluorene core of Formula F-b may be a ring (e.g., cyclic) compound with four rings. In some embodiments, when the number of both (e.g., simultaneously) U and V is 0, the fused ring of Formula F-b may be a ring (e.g., cyclic) compound with three rings. In some embodiments, when the number of both (e.g., simultaneously) U and V is 1, a fused ring having the fluorene core of Formula F-b may be a ring compound with five rings.

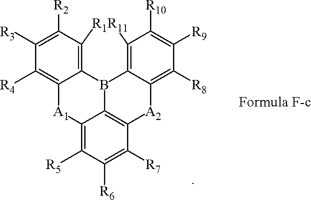

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or combined with an adjacent group to form a ring.

In Formula F-c, A₁ and A₂ may each independently be combined with the substituents of an adjacent ring to form a fused ring. For example, when A₁ and A₂ may each independently be NRₘ, A₁ may be combined with R₄ or R₅ to form a ring. In some embodiments, A₂ may be combined with R₇ or R₈ to form a ring.

In an embodiment, the emission layer EML may include as a suitable dopant material, one or more styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and/or 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and/or 1,4-bis(N,N-diphenylamino)pyrene), etc.

The EML may include a suitable phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb) and/or thulium (Tm). For example, iridium(III) bis(4,6-difluorophenylpyridinato-N,C2′) picolinate (Flrpic), bis(2,4-difluorophenylpyridinato)-tetrakis(1-pyrazolyl)borate iridium(III) (Fir6), and/or platinum octaethyl porphyrin (PtOEP) may be utilized as the phosphorescence dopant. However, an embodiment of the present disclosure is not limited thereto.

The emission layer EML may include a quantum dot material. The core of the quantum dot may be selected from a Group II-VI compound, a Group III-VI compound, a Group I-III-VI compound, a Group III-V compound, a Group III-II-V compound, a Group IV-VI compound, a Group IV element, a Group IV compound, and combinations thereof.

The Group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The Group III-VI compound may include a binary compound such as ln₂S₃, and In₂Se₃, a ternary compound such as InGaS₃, and InGaSe₃, or optional combinations thereof.

The Group I-III-VI compound may be selected from a ternary compound selected from the group consisting of AgInS, AgInS₂, CulnS, CulnS₂, AgGaS₂, CuGaS₂, CuGaO₂, AgGaO₂, AgAlO₂ and mixtures thereof, and/or a quaternary compound such as AgInGaS₂, and/or CuInGaS₂.

The Group III-V compound may be selected from the group consisting of a binary compound selected from the group consisting of GaN, GaP, GaAs, GaSb, AIN, AIP, AlAs, AISb, InN, InP, InAs, InSb, and mixtures thereof, a ternary compound selected from the group consisting of GaNP, GaNAs, GaNSb, GaPAs, GaPSb, AINP, AINAs, AINSb, AIPAs, AIPSb, InGaP, InAIP, InNP, InNAs, InNSb, InPAs, InPSb, and mixtures thereof, and a quaternary compound selected from the group consisting of GaAINP, GaAINAs, GaAINSb, GaAIPAs, GaAIPSb, GalnNP, GalnNAs, GaInNSb, GalnPAs, GalnPSb, InAINP, InAINAs, InAlNSb, InAIPAs, InAIPSb, and mixtures thereof. In some embodiments, the Group III-V group compound may further include a Group II metal. For example, InZnP, etc. may be selected as a Group III-II-V compound.

The Group IV-VI compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The Group IV element may be selected from the group consisting of Si, Ge, and a mixture thereof. The Group IV compound may be a binary compound selected from the group consisting of SiC, SiGe, and a mixture thereof.

In this case, the binary compound, the ternary compound and/or the quaternary compound may be present at substantially uniform concentration in a particle or may be present at a partially different concentration distribution state in substantially the same particle. In some embodiments, a core/shell structure in which one quantum dot is around (e.g., wraps) another quantum dot may be utilized. The interface of the core and the shell may have a concentration gradient in which the concentration of an element present in the shell is decreased toward the center of the core.

In some embodiments, the quantum dot may have the above-described core-shell structure including a core including a nanocrystal and a shell around (e.g., wrapping) the core. The shell of the quantum dot may play (e.g., serve) the role of a protection layer for preventing or reducing the chemical deformation of the core to maintain semiconductor properties and/or the role of a charging layer for imparting the quantum dot with electrophoretic properties. The shell may have a single layer or a multilayer structure. Examples of the shell of the quantum dot may include a metal or non-metal oxide, a semiconductor compound, or combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, and/or a ternary compound such as MgAl₂O₄, CoFe₂O₄, NiFe₂O₄ and/or CoMn₂O₄, but an embodiment of the present disclosure is not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AISb, etc., but an embodiment of the present disclosure is not limited thereto.

The quantum dot may have a full width of half maximum (FWHM) of emission wavelength spectrum of about 45 nm or less, about 40 nm or less, or, about 30 nm or less. Within these ranges, color purity and/or color reproducibility may be improved. In some embodiments, light emitted via such quantum dot is emitted in all directions, and light view angle properties may be improved.

In some embodiments, the shape of the quantum dot may be generally utilized shapes in the art, without specific limitation. For example, the shape of spherical, pyramidal, multi-arm, or cubic nanoparticle, nanotube, nanowire, nanofiber, nanoplate particle, etc. may be utilized.

The quantum dot may control the color of light emitted according to the particle size, and accordingly, the quantum dot may have one or more suitable emission colors such as blue, red and green.

In the light emitting elements ED of embodiments, as shown in FIG. 3 to FIG. 6, the electron transport region ETR is provided on the emission layer EML. The electron transport region ETR may include at least one of a hole blocking layer HBL, an electron transport layer ETL or an electron injection layer EIL. However, an embodiment of the present disclosure is not limited thereto.

The electron transport region ETR may have a single layer formed utilizing a single material, a single layer formed utilizing multiple different materials, or a multilayer structure having multiple layers formed utilizing multiple different materials.

For example, the electron transport region ETR may have a single layer structure of an electron injection layer EIL or an electron transport layer ETL, or a single layer structure formed utilizing an electron injection material and an electron transport material. Further, the electron transport region ETR may have a single layer structure formed utilizing multiple different materials, or a structure stacked from the emission layer EML of electron transport layer ETL/electron injection layer EIL, or hole blocking layer HBL/electron transport layer ETL/electron injection layer EIL, without limitation. The thickness of the electron transport region ETR may be, for example, from about 1.000 Å to about 1.500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1.

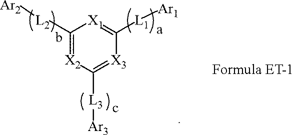

In Formula ET-1, at least one selected from among X₁ to X₃ may be N, and the remainder thereof may be CRₐ. Rₐ may be a hydrogen atom, a deuterium atom, a substituted or unsubstituted alkyl of 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, “a” to “c” may each independently be an integer of 0 to 10. In Formula ET-1, “L₁” to “L₃” may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when “a” to “c” are integers of 2 or more, “L₁” to “L₃” may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, an embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1 -ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), and mixtures thereof, but the present disclosure is not limited thereto.

The electron transport region ETR may include at least one selected from among Compounds ET1 to ET36.

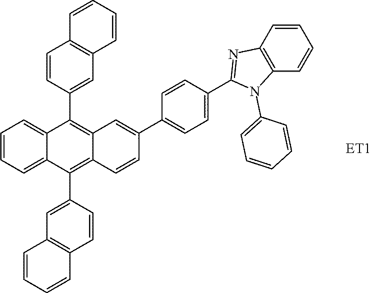 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

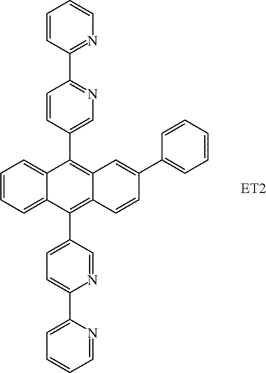 [SMILES: c1ccc(-c2ccc3c(-c4ccc(-c5ccccn5)nc4)c4ccccc4c(-c4ccc(-c5ccccn5)nc4)c3c2)cc1]

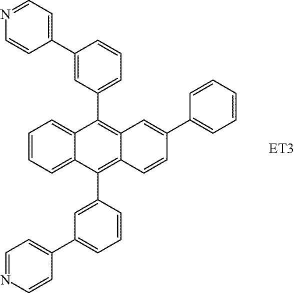 [SMILES: c1ccc(-c2ccc3c(-c4cccc(-c5ccncc5)c4)c4ccccc4c(-c4cccc(-c5ccncc5)c4)c3c2)cc1]

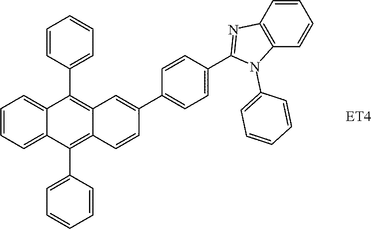 [SMILES: c1ccc(-c2c3ccccc3c(-c3ccccc3)c3cc(-c4ccc(-c5nc6ccccc6n5-c5ccccc5)cc4)ccc23)cc1]

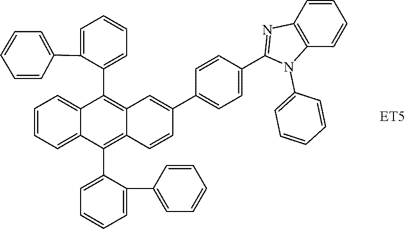 [SMILES: c1ccc(-c2ccccc2-c2c3ccccc3c(-c3ccccc3-c3ccccc3)c3cc(-c4ccc(-c5nc6ccccc6n5-c5ccccc5)cc4)ccc23)cc1]

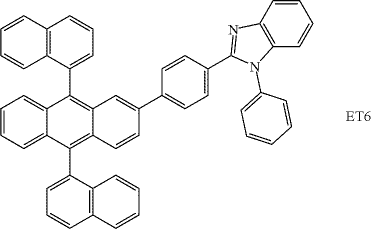 [SMILES: c1ccc(-n2c(-c3ccc(-c4ccc5c(-c6cccc7ccccc67)c6ccccc6c(-c6cccc7ccccc67)c5c4)cc3)nc3ccccc32)cc1]

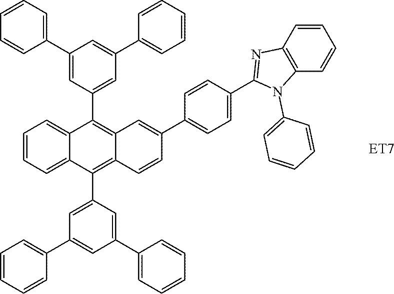 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

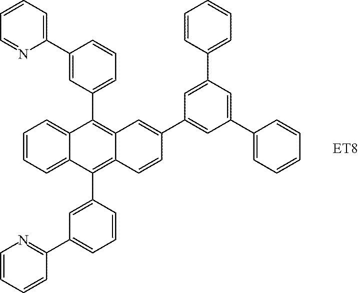 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1]

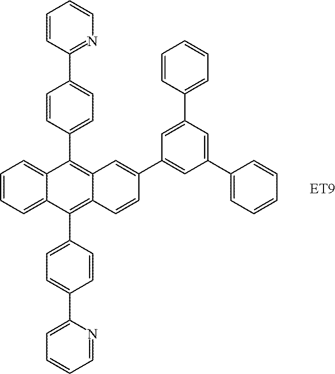 [SMILES: c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

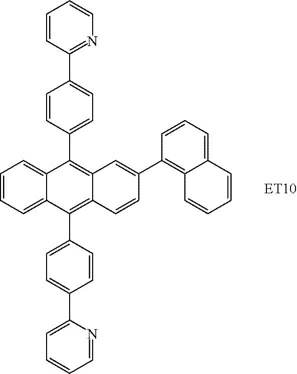 [SMILES: c1ccc(-c2ccc(-c3c4ccccc4c(-c4ccc(-c5ccccn5)cc4)c4cc(-c5cccc6ccccc56)ccc34)cc2)nc1]

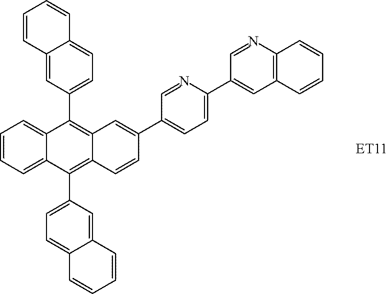 [SMILES: c1ccc2cc(-c3c4ccccc4c(-c4ccc5ccccc5c4)c4cc(-c5ccc(-c6cnc7ccccc7c6)nc5)ccc34)ccc2c1]

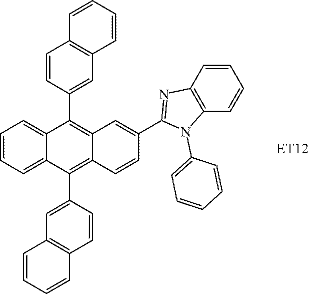 [SMILES: c1ccc(-n2c(-c3ccc4c(-c5ccc6ccccc6c5)c5ccccc5c(-c5ccc6ccccc6c5)c4c3)nc3ccccc32)cc1]

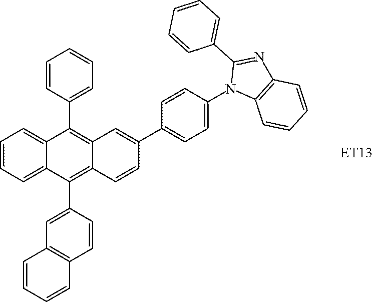 [SMILES: c1ccc(-c2c3ccccc3c(-c3ccc4ccccc4c3)c3ccc(-c4ccc(-n5c(-c6ccccc6)nc6ccccc65)cc4)cc23)cc1]

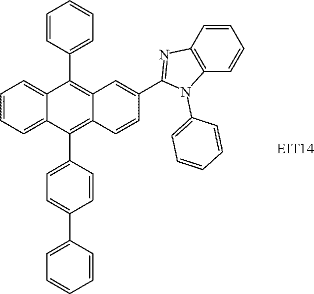 [SMILES: c1ccc(-c2ccc(-c3c4ccccc4c(-c4ccccc4)c4cc(-c5nc6ccccc6n5-c5ccccc5)ccc34)cc2)cc1]

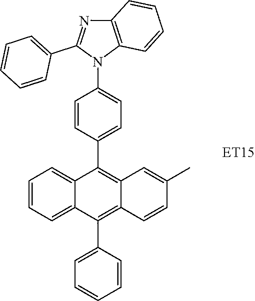 [SMILES: Cc1ccc2c(-c3ccccc3)c3ccccc3c(-c3ccc(-n4c(-c5ccccc5)nc5ccccc54)cc3)c2c1]

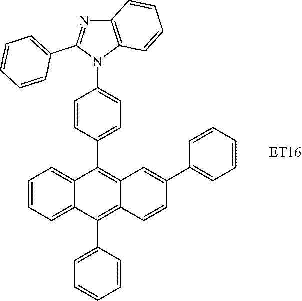 [SMILES: c1ccc(-c2ccc3c(-c4ccccc4)c4ccccc4c(-c4ccc(-n5c(-c6ccccc6)nc6ccccc65)cc4)c3c2)cc1]

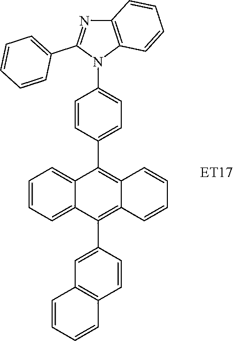 [SMILES: c1ccc(-c2nc3ccccc3n2-c2ccc(-c3c4ccccc4c(-c4ccc5ccccc5c4)c4ccccc34)cc2)cc1]

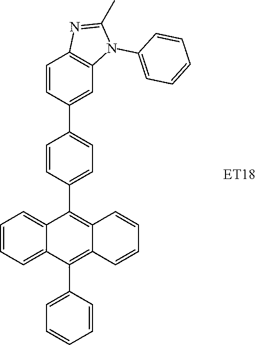 [SMILES: Cc1nc2ccc(-c3ccc(-c4c5ccccc5c(-c5ccccc5)c5ccccc45)cc3)cc2n1-c1ccccc1]

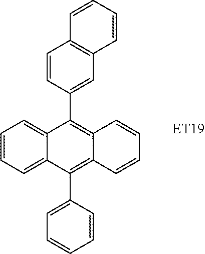 [SMILES: c1ccc(-c2c3ccccc3c(-c3ccc4ccccc4c3)c3ccccc23)cc1]

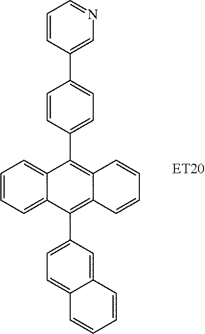 [SMILES: c1cncc(-c2ccc(-c3c4ccccc4c(-c4ccc5ccccc5c4)c4ccccc34)cc2)c1]

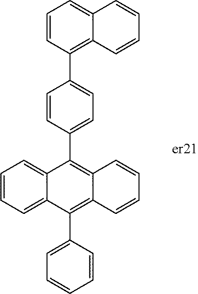 [SMILES: c1ccc(-c2c3ccccc3c(-c3ccc(-c4cccc5ccccc45)cc3)c3ccccc23)cc1]

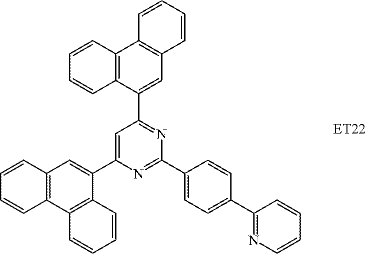 [SMILES: c1ccc(-c2ccc(-c3nc(-c4cc5ccccc5c5ccccc45)cc(-c4cc5ccccc5c5ccccc45)n3)cc2)nc1]

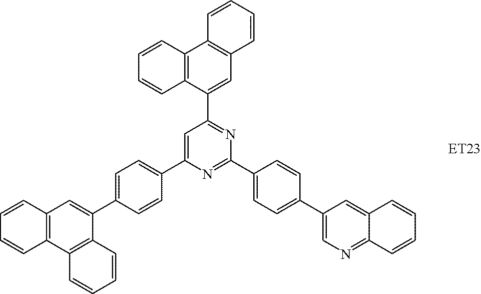 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1]

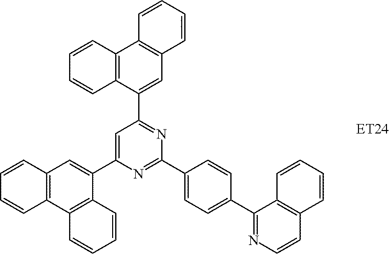 [SMILES: c1ccc2c(-c3ccc(-c4nc(-c5cc6ccccc6c6ccccc56)cc(-c5cc6ccccc6c6ccccc56)n4)cc3)nccc2c1]

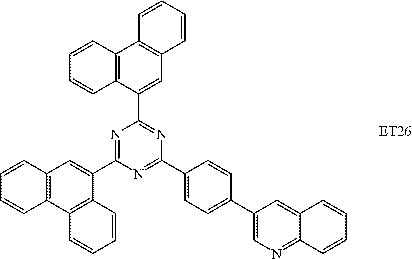 [SMILES: c1ccc2ncc(-c3ccc(-c4nc(-c5cc6ccccc6c6ccccc56)nc(-c5cc6ccccc6c6ccccc56)n4)cc3)cc2c1]

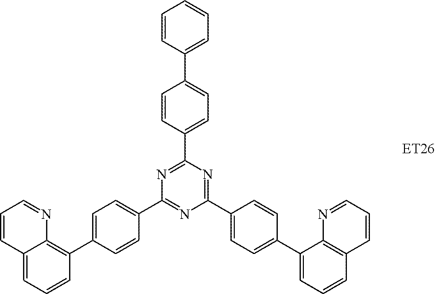 [SMILES: c1ccc(-c2ccc(-c3nc(-c4ccc(-c5cccc6cccnc56)cc4)nc(-c4ccc(-c5cccc6cccnc56)cc4)n3)cc2)cc1]

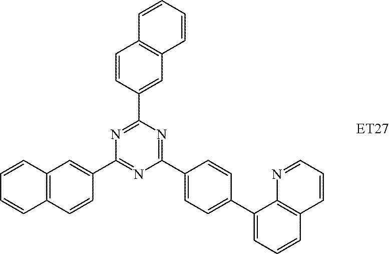 [SMILES: c1ccc2cc(-c3nc(-c4ccc(-c5cccc6cccnc56)cc4)nc(-c4ccc5ccccc5c4)n3)ccc2c1]

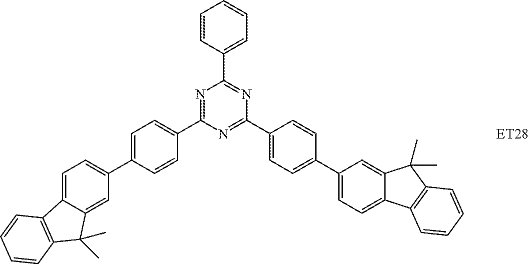 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

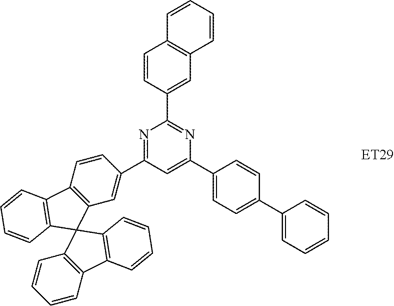 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

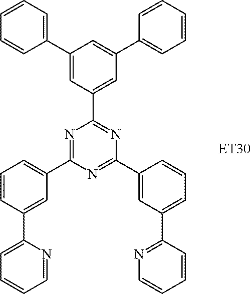 [SMILES: c1ccc(-c2cc(-c3ccccc3)cc(-c3nc(-c4cccc(-c5ccccn5)c4)nc(-c4cccc(-c5ccccn5)c4)n3)c2)cc1]

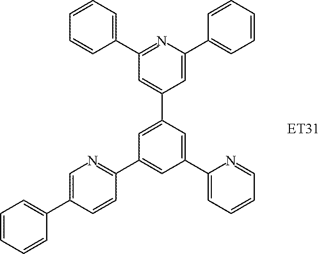 [SMILES: c1ccc(-c2ccc(-c3cc(-c4cc(-c5ccccc5)nc(-c5ccccc5)c4)cc(-c4ccccn4)c3)nc2)cc1]

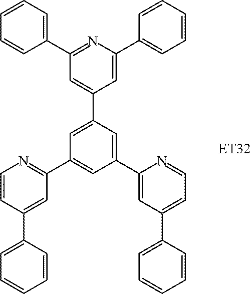 [SMILES: c1ccc(-c2ccnc(-c3cc(-c4cc(-c5ccccc5)nc(-c5ccccc5)c4)cc(-c4cc(-c5ccccc5)ccn4)c3)c2)cc1]

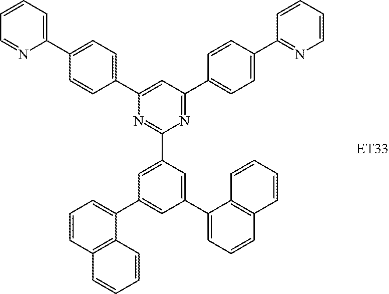 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

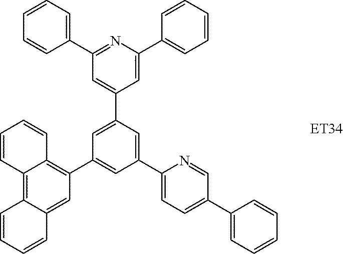 [SMILES: c1ccc(-c2ccc(-c3cc(-c4cc(-c5ccccc5)nc(-c5ccccc5)c4)cc(-c4cc5ccccc5c5ccccc45)c3)nc2)cc1]

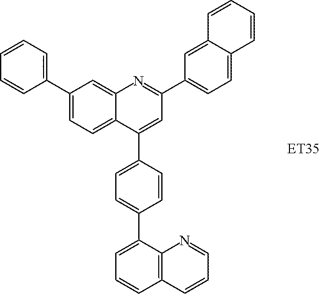 [SMILES: c1ccc(-c2ccc3c(-c4ccc(-c5cccc6cccnc56)cc4)cc(-c4ccc5ccccc5c4)nc3c2)cc1]

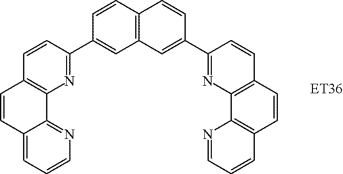 [SMILES: c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, Rbl, Cul and KI, a lanthanide metal such as Yb, or a co-depositing material of the metal halide and the lanthanide metal. For example, the electron transport region ETR may include KI:Yb, Rbl:Yb, LiF:Yb, etc., as the co-depositing material. In some embodiments, the electron transport region ETR may utilize a metal oxide such as Li₂O and BaO, or 8-hydroxy-lithium quinolate (Liq). However, an embodiment of the present disclosure is not limited thereto. The electron transport region ETR also may be formed utilizing a mixture material of an electron transport material and an insulating organo metal salt. The organo metal salt may be a material having an energy band gap of about 4 eV or more. For example, the organo metal salt may include, for example, one or more metal acetates, metal benzoates, metal acetoacetates, metal acetylacetonates, and/or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the aforementioned materials. However, an embodiment of the present disclosure is not limited thereto.

The electron transport region ETR may include the compounds of the electron transport region in at least one selected from among an electron injection layer EIL, an electron transport layer ETL, and a hole blocking layer HBL.

When the electron transport region ETR includes the electron transport layer ETL, the thickness of the electron transport layer ETL may be from about 100 Å to about 1.000 Å, for example, from about 150 Å to about 500 Å. When the thickness of the electron transport layer ETL satisfies the above-described range, satisfactory electron transport properties may be obtained without substantial increase of a driving voltage. When the electron transport region ETR includes the electron injection layer EIL, the thickness of the electron injection layer EIL may be from about 1 Å to about 100 Å, or from about 3 Å to about 90 Å. When the thickness of the electron injection layer EIL satisfies the above described ranges, satisfactory electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but an embodiment of the present disclosure is not limited thereto. For example, when the first electrode EL1 is an anode, the second cathode EL2 may be a cathode, and when the first electrode EL1 is a cathode, the second electrode EL2 may be an anode.

The second electrode EL2 may be a transmissive electrode, a transflective electrode or a reflective electrode. When the second electrode EL2 is the transmissive electrode, the second electrode EL2 may include a transparent metal oxide, for example, ITO, IZO, ZnO, ITZO, etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, one or more compounds thereof, or one or more mixtures thereof (for example, AgMg, AgYb, or MgAg). In some embodiments, the second electrode EL2 may have a multilayered structure including a reflective layer or a transflective layer formed utilizing the above-described materials and a transparent conductive layer formed utilizing ITO, IZO, ZnO, ITZO, etc. For example, the second electrode EL2 may include one or more of the aforementioned metal materials, combinations of two or more metal materials selected from the aforementioned metal materials, and/or oxides of the aforementioned metal materials.

In some embodiments, the second electrode EL2 may be connected with an auxiliary electrode. When the second electrode EL2 is connected with the auxiliary electrode, the resistance of the second electrode EL2 may decrease.

In some embodiments, on the second electrode EL2 in the light emitting element ED of an embodiment, a capping layer CPL may be further disposed. The capping layer CPL may include a multilayer or a single layer.

In an embodiment, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiNx, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., an epoxy resin, and/or acrylate such as methacrylate. In some embodiments, a capping layer CPL may include at least one selected from among Compounds P1 to P5, but an embodiment of the present disclosure is not limited thereto.

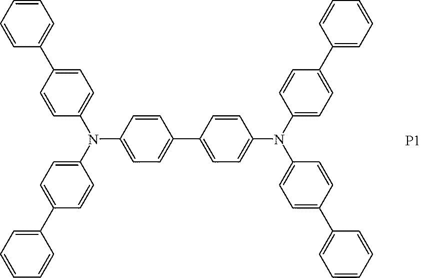 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

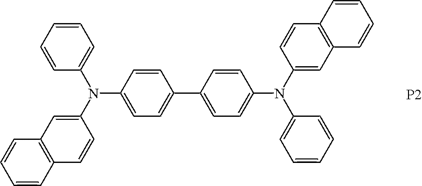 [SMILES: c1ccc(N(c2ccc(-c3ccc(N(c4ccccc4)c4ccc5ccccc5c4)cc3)cc2)c2ccc3ccccc3c2)cc1]

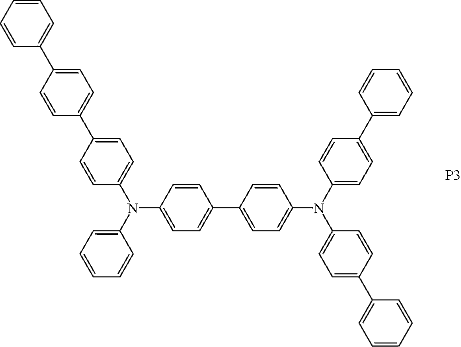 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

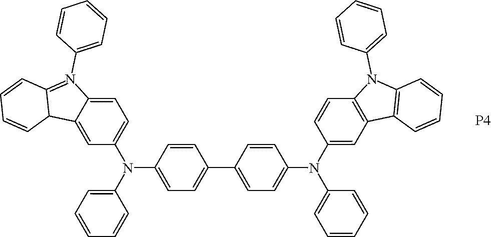

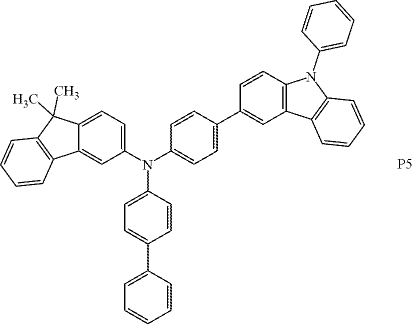 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL with respect to light in a wavelength range of about 550 nm to about 660 nm may be about 1.6 or more.

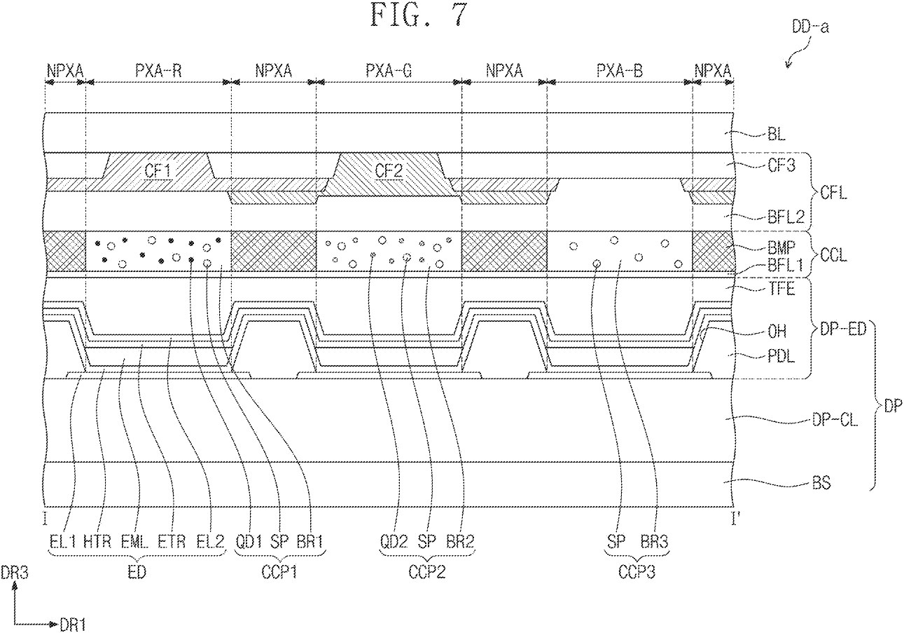

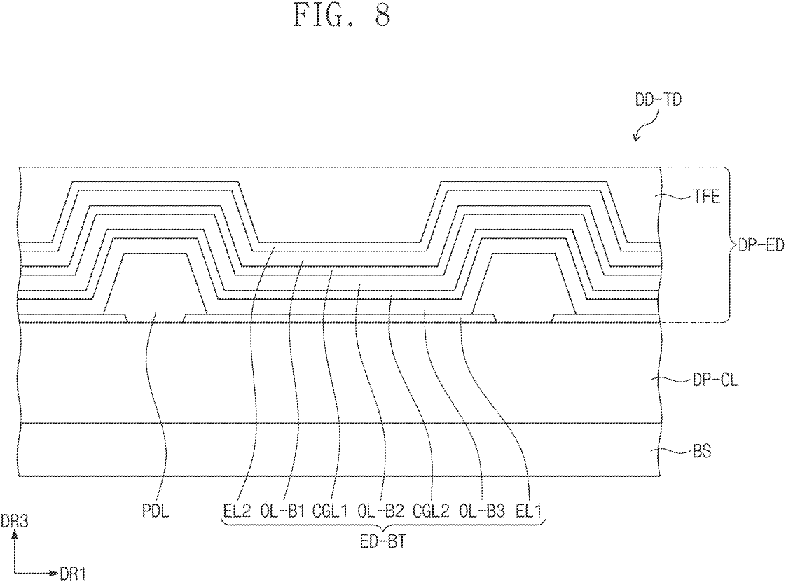

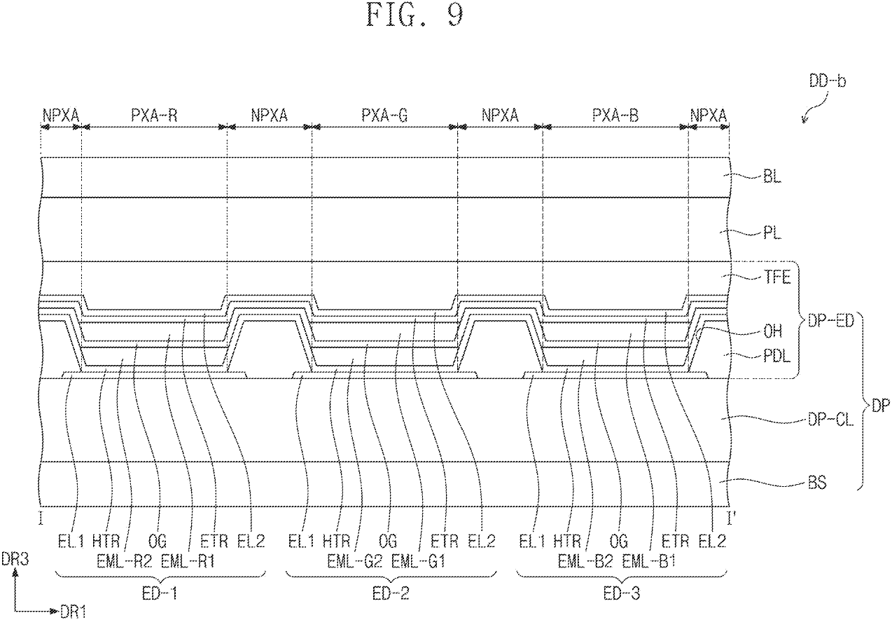

FIG. 7 and FIG. 8 are cross-sectional views on display apparatuses according to embodiments. In the explanation on the display apparatuses of embodiments, referring to FIG. 7 and FIG. 8, the overlapping parts with the explanation on FIG. 1 to FIG. 6 will not be explained again, and the different features will be explained chiefly.

Referring to FIG. 7, a display apparatus DD-a according to an embodiment may include a display panel DP including a display device layer DP-ED, a light controlling layer CCL disposed on the display panel DP, and a color filter layer CFL.

In an embodiment shown in FIG. 7, the display panel DP includes a base layer BS, a circuit layer DP-CL provided on the base layer BS and a display device layer DP-ED, and the display device layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In some embodiments, the same structures of the light emitting elements of FIG. 3 to FIG. 6 may be applied to the structure of the light emitting element ED shown in FIG. 7.

Referring to FIG. 7, the emission layer EML may be disposed in an opening part OH defined in a pixel definition layer PDL. For example, the emission layer EML divided by the pixel definition layer PDL and correspondingly provided to each of luminous areas PXA-R, PXA-G and PXA-B may be to emit light in substantially the same wavelength region. In the display apparatus DD-a of an embodiment, the emission layer EML may be to emit blue light. In some embodiments, different from the drawings, in an embodiment, the emission layer EML may be provided as a common layer for all luminous areas PXA-R, PXA-G and PXA-B.

The light controlling layer CCL may be disposed on the display panel DP. The light controlling layer CCL may include a light converter. The light converter may be a quantum dot or a phosphor. The light converter may transform the wavelength of light provided and then emit (e.g., emit light of a different color). For example, the light controlling layer CCL may be a layer including a quantum dot or a layer including a phosphor.

The light controlling layer CCL may include multiple light controlling parts CCP1, CCP2 and CCP3. The light controlling parts CCP1, CCP2 and CCP3 may be separated from one another.

Referring to FIG. 7, a partition pattern BMP may be disposed between the separated light controlling parts CCP1, CCP2 and CCP3, but an embodiment of the present disclosure is not limited thereto. In FIG. 7, the partition pattern BMP is shown not to be overlapped with the light controlling parts CCP1, CCP2 and CCP3, but in some embodiments, at least a portion of the edge of the light controlling parts CCP1, CCP2 and CCP3 may be overlapped with the partition pattern BMP.

The light controlling layer CCL may include a first light controlling part CCP1 including a first quantum dot QD1 converting a first color light provided from the light emitting element ED into a second color light, a second light controlling part CCP2 including a second quantum dot QD2 converting the first color light into a third color light, and a third light controlling part CCP3 transmitting the first color light.

In an embodiment, the first light controlling part CCP1 may provide red light which is the second color light, and the second light controlling part CCP2 may provide green light which is the third color light. The third color controlling part CCP3 may be to transmit and provide blue light which is the first color light provided from the light emitting element ED. For example, the first quantum dot QD1 may be a red quantum dot, and the second quantum dot QD2 may be a green quantum dot. For the quantum dots QD1 and QD2, the same contents as those described above may be applied.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include (e.g., may exclude) a quantum dot but may include the scatterer SP.

The scatterer SP may be an inorganic particle. For example, the scatterer SP may include at least one selected from among TiO₂, ZnO, Al₂O₃, SiO₂, and hollow silica. The scatterer SP may include at least one selected from among TiO₂, ZnO, Al₂O₃, SiO₂, and hollow silica, or may be a mixture of two or more materials selected from among TiO₂, ZnO, Al₂O₃, SiO₂, and hollow silica.

Each of the first light controlling part CCP1, the second light controlling part CCP2, and the third light controlling part CCP3 may include a corresponding one of the base resins BR1, BR2 and BR3, for dispersing the quantum dots QD1 and QD2 and the scatterer SP. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3. The base resins BR1, BR2 and BR3 are mediums in which the quantum dots QD1 and QD2 and the scatterer SP are dispersed, and may be composed of one or more suitable resin compositions which may be generally referred to as a binder. For example, the base resins BR1, BR2 and BR3 may be one or more acrylic resins, urethane-based resins, silicone-based resins, epoxy-based resins, etc. The base resins BR1, BR2 and BR3 may be transparent resins. In an embodiment, the first base resin BR1, the second base resin BR2 and the third base resin BR3 may be the same or different from each other.

The light controlling layer CCL may include a barrier layer BFL1. The barrier layer BFL1 may play the role of blocking the penetration of moisture and/or oxygen (hereinafter, will be referred to as “humidity/oxygen”). The barrier layer BFL1 may be disposed on the light controlling parts CCP1, CCP2 and CCP3 to block or reduce the exposure of the light controlling parts CCP1, CCP2 and CCP3 to humidity/oxygen. In some embodiments, the barrier layer BFL1 may cover the light controlling parts CCP1, CCP2 and CCP3. In some embodiments, the barrier layer BFL2 may be provided between a color filter layer CFL and the light controlling parts CCP1, CCP2 and CCP3.

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and/or a metal thin film for securing light transmittance. In some embodiments, the barrier layers BFL1 and BFL2 may further include an organic layer. The barrier layers BFL1 and BFL2 may be composed of a single layer of multiple layers.

In the display apparatus DD-a of an embodiment, the color filter layer CFL may be disposed on the light controlling layer CCL. For example, the color filter layer CFL may be disposed directly on the light controlling layer CCL. In this case, the barrier layer BFL2 may not be provided.

The color filter layer CFL may include a light blocking part BM and filters CF1, CF2 and CF3. The color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment and/or dye. The first filter CF1 may include a red pigment and/or dye, the second filter CF2 may include a green pigment and/or dye, and the third filter CF3 may include a blue pigment and/or dye. In some embodiments, the present disclosure is not limited thereto, and the third filter CF3 may not include (e.g., may exclude) the pigment and/or dye. The third filter CF3 may include a polymer photosensitive resin and not include a pigment or dye. The third filter CF3 may be transparent. The third filter CF3 may be formed utilizing a transparent photosensitive resin.

In some embodiments, in an embodiment, the first filter CF1 and the second filter CF2 may be yellow filters. The first filter CF1 and the second filter CF2 may be provided in one body without distinction.

The light blocking part BM may be a black matrix. The light blocking part BM may be formed by including an organic light blocking material and/or an inorganic light blocking material including a black pigment and/or black dye. The light blocking part BM may prevent or reduce light leakage phenomenon and divide the boundaries selected from among adjacent filters CF1, CF2 and CF3. In some embodiments, the light blocking part BM may be formed as a blue filter.

Each of the first to third filters CF1, CF2 and CF3 may be disposed corresponding to a respective red luminous area PXA-R, green luminous area PXA-G, and blue luminous area PXA-B.

On the color filter layer CFL, a base substrate BL may be disposed. The base substrate BL may be a member providing a base surface on which the color filter layer CFL, the light controlling layer CCL, etc. are disposed. The base substrate BL may be a glass substrate, a metal substrate, a plastic substrate, etc. However, an embodiment of the present disclosure is not limited thereto, and the base substrate BL may be an inorganic layer, an organic layer or a composite material layer. In some embodiments, different from the drawing, the base substrate BL may not be provided.

FIG. 8 is a cross-sectional view showing a portion of the display apparatus according to an embodiment. In FIG. 8, the cross-sectional view of a portion corresponding to the display panel DP in FIG. 7 is shown. In a display apparatus DD-TD of an embodiment, the light emitting element ED-BT may include multiple light emitting structures OL-B1, OL-B2 and OL-B3. The light emitting element ED-BT may include oppositely disposed first electrode EL1 and second electrode EL2, and the multiple light emitting structures OL-B1, OL-B2 and OL-B3 stacked in the stated order in a thickness direction and provided between the first electrode EL1 and the second electrode EL2. Each of the light emitting structures OL-B1, OL-B2 and OL-B3 may include an emission layer EML (FIG. 7), and a hole transport region HTR and an electron transport region ETR, disposed with the emission layer EML (FIG. 7) therebetween.

For example, the light emitting element ED-BT included in the display apparatus DD-TD of an embodiment may be a light emitting element of a tandem structure including multiple emission layers.

In an embodiment shown in FIG. 8, light emitted from the light emitting structures OL-B1, OL-B2 and OL-B3 may be all blue light. However, an embodiment of the present disclosure is not limited thereto, and the wavelength regions of light emitted from the light emitting structures OL-B1, OL-B2 and OL-B3 may be different from each other. For example, the light emitting element ED-BT including the multiple light emitting structures OL-B1, OL-B2 and OL-B3 emitting light in different wavelength regions may be to emit white light.

Between neighboring light emitting structures OL-B1, OL-B2 and OL-B3, charge generating layers CGL1 and CGL2 may be respectively disposed. The charge generating layers CGL1 and CGL2 may include a p-type or kind charge generating layer and/or an n-type or kind charge generating layer.

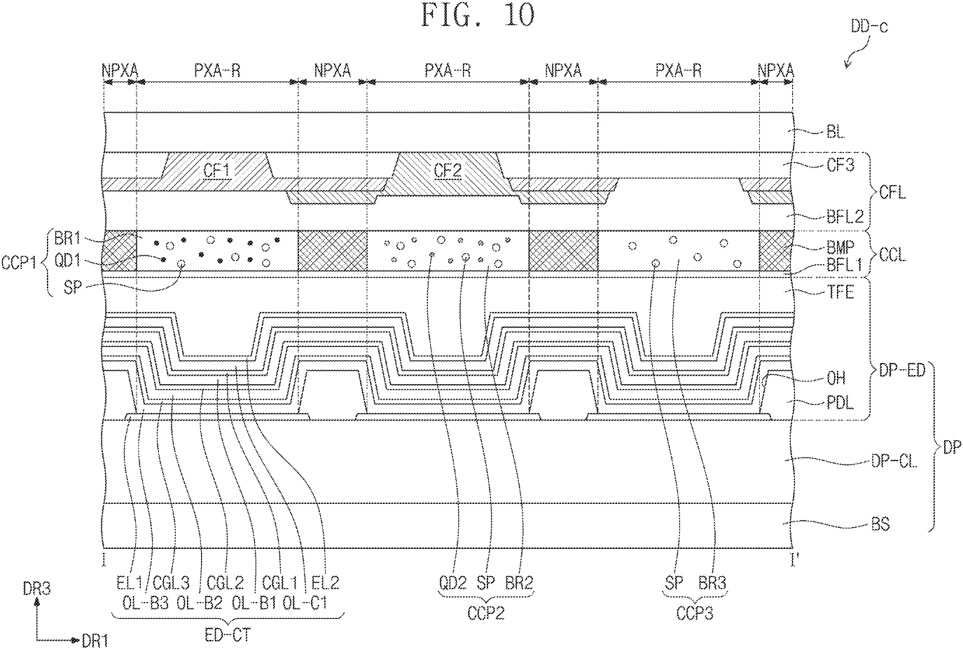

FIG. 9 is a cross-sectional view on a display apparatus according to an embodiment. Hereinafter, in the explanation on the display apparatus of an embodiment, referring to FIG. 9, overlapping parts with the explanation referring to FIG. 1 to FIG. 6 will not be explained again, and different features will be mainly explained.

Referring to FIG. 9, a display apparatus DD-b according to an embodiment may include light emitting elements ED-1, ED-2 and ED-3, each formed by stacking two emission layers. Compared to the display apparatus DD of an embodiment, shown in FIG. 2, an embodiment shown in FIG. 9 is different in that the first to third light emitting elements ED-1, ED-2 and ED-3 each include two emission layers stacked in a thickness direction. In the first to third light emitting elements ED-1, ED-2 and ED-3, the two emission layers may be to emit light in substantially the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. Between the first red emission layer EML-R1 and the second red emission layer EML-R2, between the first green emission layer EML-G1 and the second green emission layer EML-G2, and between the first blue emission layer EML-B1 and the second blue emission layer EML-B2, an emission auxiliary part OG may be disposed.

The emission auxiliary part OG may include a single layer or a multilayer. The emission auxiliary part OG may include a charge generating layer. For example, the emission auxiliary part OG may include an electron transport region, a charge generating layer, and a hole transport region stacked in the stated order. The emission auxiliary part OG may be provided as a common layer in all of the first to third light emitting elements ED-1, ED-2 and ED-3. However, an embodiment of the present disclosure is not limited thereto, and the emission auxiliary part OG may be patterned and provided in an opening part OH defined in a pixel definition layer PDL.

The first red emission layer EML-R1, the first green emission layer EML-G1 and the first blue emission layer EML-B1 may be disposed between the electron transport region ETR and the emission auxiliary part OG. The second red emission layer EML-R2, the second green emission layer EML-G2 and the second blue emission layer EML-B2 may be disposed between the emission auxiliary part OG and the hole transport region HTR.

For example, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, stacked in the stated order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, stacked in the stated order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in the stated order.

In some embodiments, an optical auxiliary layer PL may be disposed on a display device layer DP-ED. The optical auxiliary layer PL may include a polarization layer. The optical auxiliary layer PL may be disposed on a display panel DP and may control reflected light at the display panel DP by external light. Different from the drawings, the optical auxiliary layer PL may not be provided from the display apparatus according to an embodiment.

Different from FIG. 8 and FIG. 9, a display apparatus DD-c in FIG. 10 is shown to include four light emitting structures OL-B1, OL-B2, OL-B3 and OL-C1. A light emitting element ED-CT may include oppositely disposed first electrode EL1 and second electrode EL2, and first to fourth light emitting structures OL-B1, OL-B2, OL-B3 and OL-C1 stacked in the stated order in a thickness direction between the first electrode EL1 and the second electrode EL2. Between adjacent first to fourth light emitting structures OL-B1, OL-B2, OL-B3 and OL-C1, charge generating layers CGL1, CGL2 and CGL3 may be respectively disposed. From among the four light emitting structures, the first to third light emitting structures OL-B1, OL-B2 and OL-B3 emit blue light, and the fourth light emitting structure OL-C1 may be to emit green light. However, an embodiment of the present disclosure is not limited thereto, and the first to fourth light emitting structures OL-B1, OL-B2, OL-B3 and OL-C1 may be to emit light of different wavelengths.

Charge generating layers CGL1, CGL2 and CGL3 disposed among neighboring light emitting structures OL-B1, OL-B2, OL-B3 and OL-C1 may each include a p-type or kind charge generating layer and/or an n-type or kind charge generating layer.

Hereinafter, the polycyclic compound according to an embodiment and the light emitting element according to an embodiment of the present disclosure will be particularly explained referring to embodiments and comparative embodiments. In addition, the embodiments below are only described to assist the understanding of the present disclosure, and the scope of the present disclosure is not limited thereto.

### EXAMPLES

### 1. Synthesis of Polycyclic Compound

First, the synthetic method of the polycyclic compound according to an embodiment of the present disclosure will be explained in particular by referring to the synthetic methods of Compound 82, Compound 86, Compound 96, Compound 97 and Compound 99 in Compound Group 1. In addition, the synthetic methods of the polycyclic compounds explained hereinafter are only embodiments, and the synthetic method of the polycyclic compound according to an embodiment of the present disclosure is not limited to the embodiments below.

### Synthesis of Compound 82

Compound 82 according to an embodiment may be synthesized by, for example, the steps of Reaction 1-1 to Reaction 1-6.

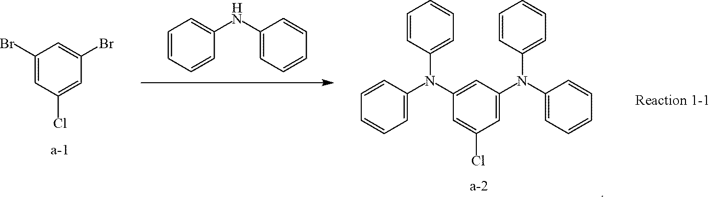

Under an argon (Ar) atmosphere, to a three-neck round-bottom flask, a-1 (50.0 g, 185 mmol), diphenylamine (62.6 g, 370 mmol), Pd(dba)₂ (5.32 g, 9.25 mmol), 2-dicyclohexylphosphino-2′,6′-dimethoxybiphenyl (7.59 g, 18.5 mmol), t-BuONa (39.1 g, 407 mmol) and 500 mL of toluene were added and stirred at about 80° C. for about 5 hours. After cooling to room temperature, 500 mL of water was added, liquid layers were separated, and an organic layer was extracted. The organic layer thus obtained was separated by column chromatography to obtain a-2 (65.5 g, yield 79.2%).

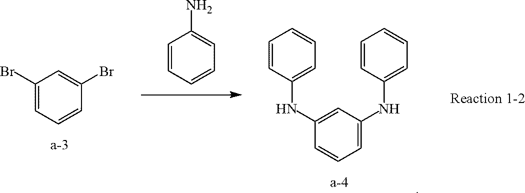

Under an argon (Ar) atmosphere, to a three-neck round-bottom flask, a-3 (50.0 g, 212 mmol), aniline (39.5 g, 424 mmol), Pd(dba)₂ (3.66 g, 6.36 mmol), 2-dicyclohexylphosphino-2′,6′-dimethoxybiphenyl (5.22 g, 12.7 mmol), t-BuONa (23.4 g, 244 mmol) and 500 mL of toluene were added and stirred at about 70° C. for about 3 hours. After cooling to room temperature, 500 mL of water was added, liquid layers were separated, and an organic layer was extracted. The organic layer thus obtained was separated by column chromatography to obtain a-4 (49.2 g, yield 89.2%).

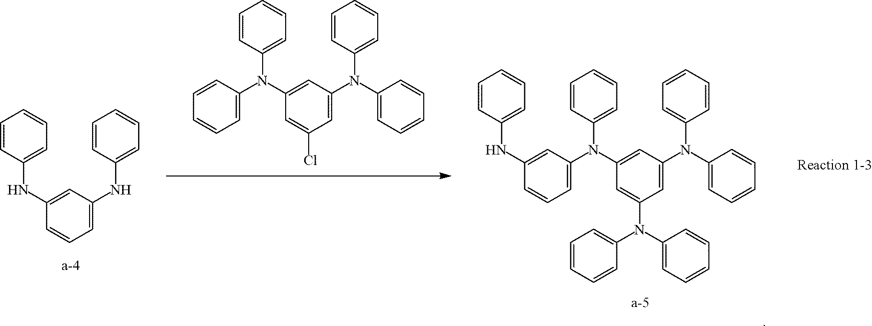

Under an argon (Ar) atmosphere, to a three-neck round-bottom flask, a-4 (17.5 g, 67.1 mmol), a-2 (15.0 g, 33.6 mmol), Pd(dba)₂(0.58 g, 1.01 mmol), 2-dicyclohexylphosphino-2′,6′-dimethoxybiphenyl (0.83 g, 2.01 mmol), t-BuONa (3.55 g, 36.9 mmol) and 200 mL of toluene were added and stirred at about 70° C. for about 5 hours. After cooling to room temperature, 200 mL of water was added, liquid layers were separated, and an organic layer was extracted. The organic layer thus obtained was separated by column chromatography to obtain a-5 (12.6 g, yield 56.2%).

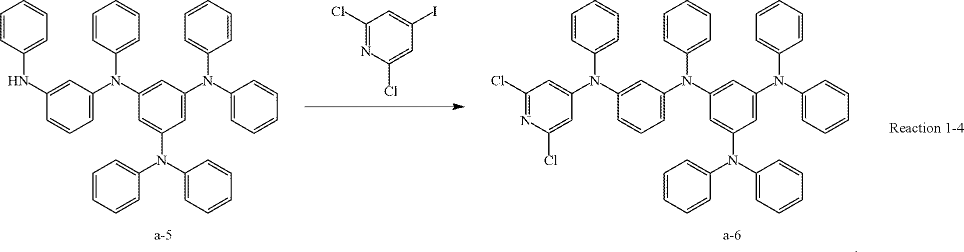

Under an argon (Ar) atmosphere, to a three-neck round-bottom flask, a-5 (12.0 g, 17.9 mmol), 2,6-dichloro-4-iodopyridine (9.80 g, 35.8 mmol), Pd(dba)₂ (0.31 g, 0.54 mmol), 2-dicyclohexylphosphino-2′,6′-dimethoxybiphenyl (0.44 g, 1.07 mmol), t-BuONa (4.13 g, 42.9 mmol) and 150 mL of toluene were added and stirred at about 50° C. for about 5 hours. After cooling to room temperature, 100 mL of water was added, liquid layers were separated, and an organic layer was extracted. The organic layer thus obtained was separated by column chromatography to obtain a-6 (10.2 g, yield 69.8%).

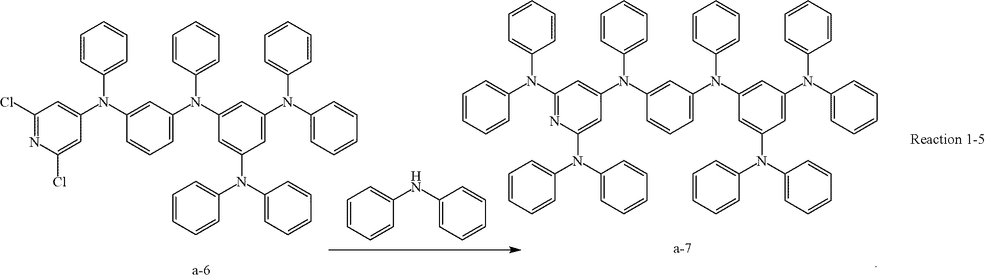

Under an argon (Ar) atmosphere, to a three-neck round-bottom flask, a-6 (10.0 g, 12.2 mmol), diphenylamine (4.25 g, 25.1 mmol), Pd(dba)₂ (0.35 g, 0.61 mmol), 2-dicyclohexylphosphino-2′,6′-dimethoxybiphenyl (0.50 g, 1.22 mmol), t-BuONa (2.59 g, 2.20 mmol) and 100 mL of toluene were added and stirred at about 80° C. for about 3 hours. After cooling to room temperature, 100 mL of water was added, liquid layers were separated, and an organic layer was extracted. The organic layer thus obtained was separated by column chromatography to obtain a-7 (10.5 g, yield 79.2%).

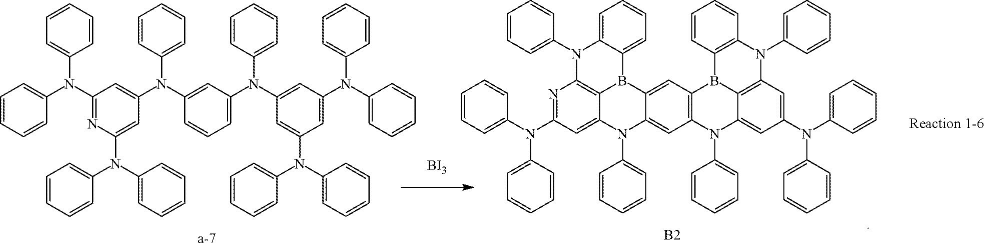

Under an argon (Ar) atmosphere, to a three-neck round-bottom flask, a-7 (10.0 g, 9.24 mmol), boron triiodide (28.9 g, 73.9 mmol) and 100 mL of o-dichlorobenzene were added and stirred at about 100° C. for about 3 hours. After cooling to room temperature, N,N-diisopropylethylamine (38.2 g, 296 mmol) was added, and stirring was performed at room temperature for about 1 hour. 100 mL of water was added thereto, liquid layers were separated, and an organic layer was extracted. The organic layer thus obtained was separated by column chromatography to obtain Compound 82 (1.1 g, yield 10.8%).

Compound 82 was purified through sublimation (430° C., 2×10⁻⁵ Pa), and results of the mass measurement are as follows.

FAB-MS m/z = 1098(M⁺+1)

### Synthesis of Compound 86

Compound 86 according to an embodiment may be synthesized by, for example, the steps of Reaction 2-1 to Reaction 2-6.

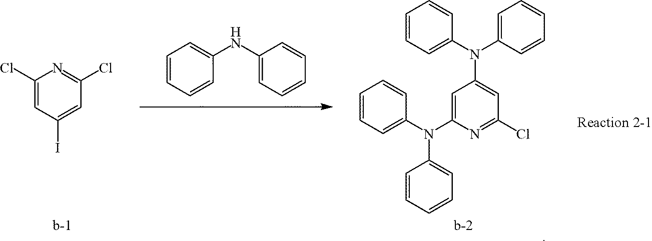

Under an argon (Ar) atmosphere, to a three-neck round-bottom flask, b-1 (25.0 g, 91.3 mmol), diphenylamine (30.9 g, 183 mmol), Pd(dba)₂(2.62 g, 4.56 mmol), 2-dicyclohexylphosphino-2′,6′-dimethoxybiphenyl (3.75 g, 9.13 mmol), t-BuONa (18.4 g, 192 mmol) and 600 mL of toluene were added and stirred at about 50° C. for about 3 hours and at about 60° C. for about 4 hours. After cooling to room temperature, 300 mL of water was added, liquid layers were separated, and an organic layer was extracted. The organic layer was separated by column chromatography to obtain b-2 (17.3 g, yield 42.3%).

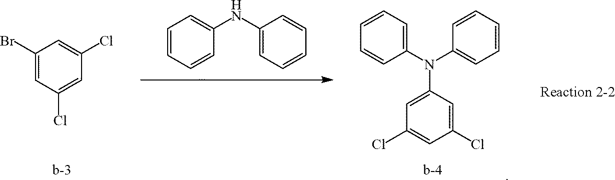

Under an argon (Ar) atmosphere, to a three-neck round-bottom flask, b-3 (50.0 g, 221 mmol), diphenylamine (37.5 g, 370 mmol), Pd(dba)₂ (3.82 g, 6.64 mmol), 2-dicyclohexylphosphino-2′,6′-dimethoxybiphenyl (5.45 g, 13.3 mmol), t-BuONa (24.5 g, 255 mmol) and 400 mL of toluene were added and stirred at about 80° C. for about 5 hours. After cooling to room temperature, 400 mL of water was added, liquid layers were separated, and an organic layer was extracted. The organic layer thus obtained was separated by column chromatography to obtain b-4 (58.2 g, yield 83.7%).

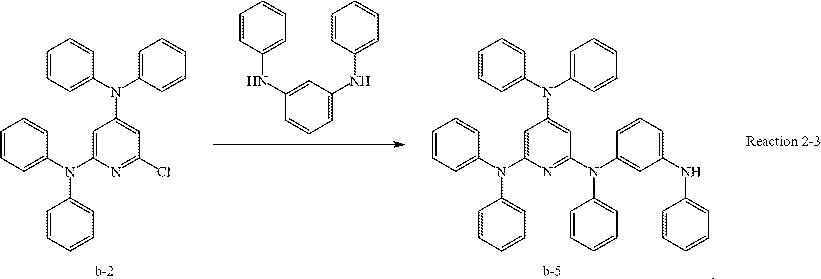

Under an argon (Ar) atmosphere, to a three-neck round-bottom flask, b-2 (15.0 g, 33.5 mmol), a-4 (17.4 g, 67.0 mmol), Pd(dba)₂(0.58 g, 1.00 mmol), 2-dicyclohexylphosphino-2′,6′-dimethoxybiphenyl (0.83 g, 2.01 mmol), t-BuONa (4.18 g, 43.5 mmol) and 300 mL of toluene were added and stirred at about 60° C. for about 3 hours. After cooling to room temperature, 200 mL of water was added, liquid layers were separated, and an organic layer was extracted. The organic layer thus obtained was separated by column chromatography to obtain b-5 (10.4 g, yield 46.2%).

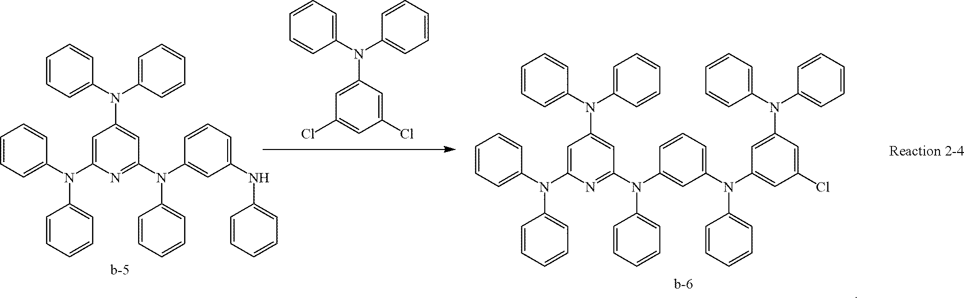

Under an argon (Ar) atmosphere, to a three-neck round-bottom flask, b-5 (10.0 g, 14.9 mmol), b-4 (14.0 g, 44.7 mmol), Pd(dba)₂ (0.26 g, 0.45 mmol), 2-dicyclohexylphosphino-2′,6′-dimethoxybiphenyl (0.37 g, 0.89 mmol), t-BuONa (1.72 g, 17.9 mmol) and 100 mL of toluene were added and stirred at about 80° C. for about 5 hours. After cooling to room temperature, 100 mL of water was added, liquid layers were separated, and an organic layer was extracted. The organic layer thus obtained was separated by column chromatography to obtain b-6 (10.7 g, yield 75.5%).

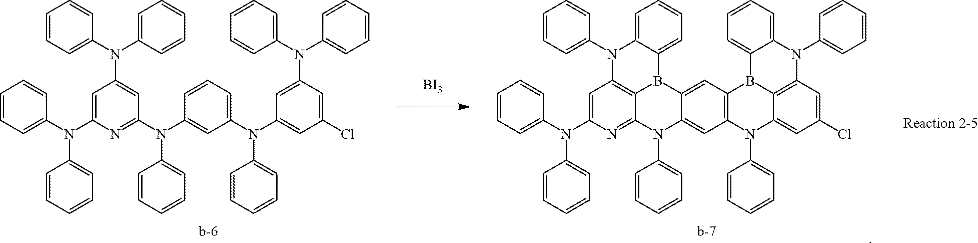

Under an argon (Ar) atmosphere, to a three-neck round-bottom flask, b-6 (10.0 g, 10.5 mmol), boron triiodide (33.0 g, 84.3 mmol) and 100 mL of o-dichlorobenzene were added and stirred at about 100° C. for about 3 hours. After cooling to room temperature, N,N-diisopropylethylamine (43.6 g, 337 mmol) was added, and stirring was performed at room temperature for about 1 hour. 100 mL of water was added, liquid layers were separated, and an organic layer was extracted. The organic layer thus obtained was separated by column chromatography to obtain b-7 (0.58 g, yield 5.7%).

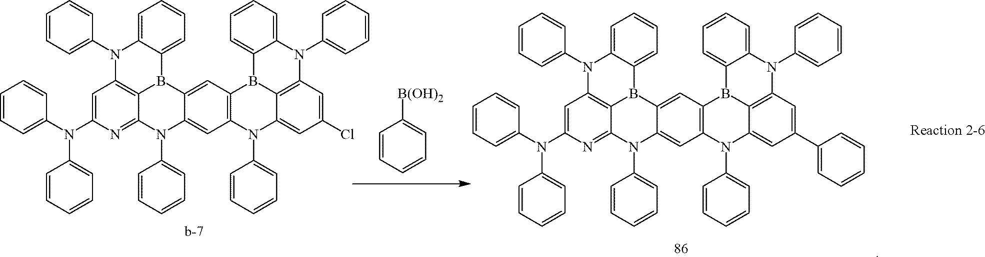

Under an argon (Ar) atmosphere, to a three-neck round-bottom flask, b-7 (0.58 g, 0.60 mmol), phenylboronic acid (0.088 g, 0.72 mmol), Pd(OAc)₂ (0.004 g, 0.02 mmol), 2-dicyclohexylphosphino-2′,6′-dimethoxybiphenyl (0.015 g, 0.04 mmol), tripotassium phosphate (0.15 g, 0.72 mmol), 10 mL of water, 10 mL of ethanol, and 50 mL of toluene were added and stirred at about 80° C. for about 5 hours. After cooling to room temperature, 50 mL of water was added, liquid layers were separated, and an organic layer was extracted. The organic layer thus obtained was separated by column chromatography to obtain Compound 86 (0.38 g, yield 62.8%).

Compound 86 was purified through sublimation (410° C., 1×10⁻⁵ Pa), and results of the mass measurement are as follows.

FAB-MS m/z = 1007(M⁺+1)

### Synthesis of Compound 96

Compound 96 according to an embodiment may be synthesized by, for example, the steps of Reaction 3-1 to Reaction 3-8.

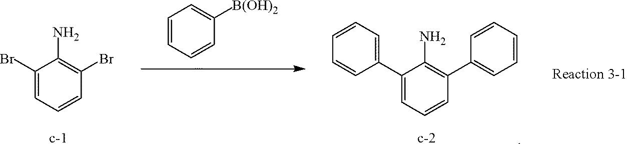

Under an argon (Ar) atmosphere, to a three-neck round-bottom flask, c-1 (100 g, 399 mmol), phenylboronic acid (117 g, 956 mmol), Pd(PPh₃)₄ (13.8 g, 12.0 mmol), potassium carbonate (198 g, 1.43 mol) and 800 mL of ethanol were added and refluxed for about 5 hours. After cooling to room temperature, 500 mL of toluene and 200 mL of water were added, liquid layers were separated, and an organic layer was extracted. The organic layer was separated by column chromatography to obtain c-2 (82.3 g, yield 84.2%).

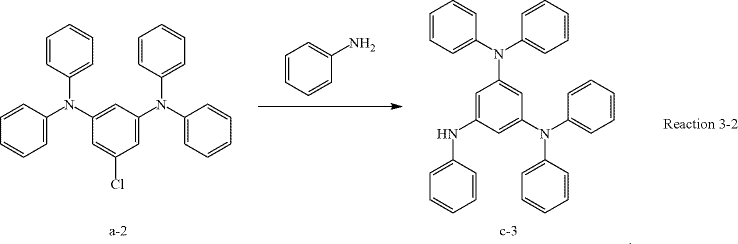

Under an argon (Ar) atmosphere, to a three-neck round-bottom flask, a-2 (25.0 g, 55.9 mmol), aniline (5.21 g, 55.9 mmol), Pd(dba)₂ (0.965 g, 1.68 mmol), 2-dicyclohexylphosphino-2′,6′-dimethoxybiphenyl (1.38 g, 3.36 mmol), t-BuONa (6.45 g, 67.1 mmol) and 500 mL of toluene were added and stirred at about 80° C. for about 5 hours. After cooling to room temperature, 300 mL of water was added, liquid layers were separated, and an organic layer was extracted. The organic layer thus obtained was separated by column chromatography to obtain c-3 (25.3 g, yield 89.8%).

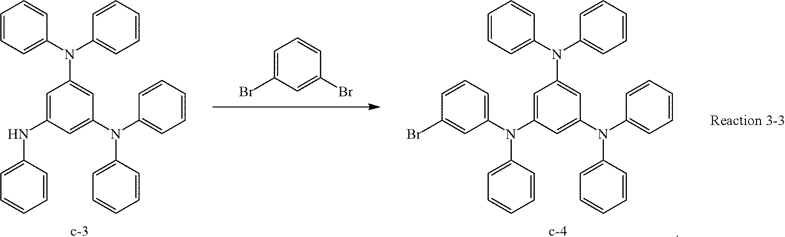

Under an argon (Ar) atmosphere, to a three-neck round-bottom flask, c-3 (15.0 g, 29.8 mmol), 1,3-dibromobenzene (35.1 g, 149 mmol), Pd(dba)₂ (0.51 g, 0.89 mmol), 2-dicyclohexylphosphino-2′,6′-dimethoxybiphenyl (0.73 g, 1.79 mmol), t-BuONa (3.44 g, 35.7 mmol) and 200 mL of toluene were added and stirred at about 80° C. for about 5 hours. After cooling to room temperature, 200 mL of water was added, liquid layers were separated, and an organic layer was extracted. The organic layer thus obtained was separated by column chromatography to obtain c-4 (13.7 g, yield 69.8%).

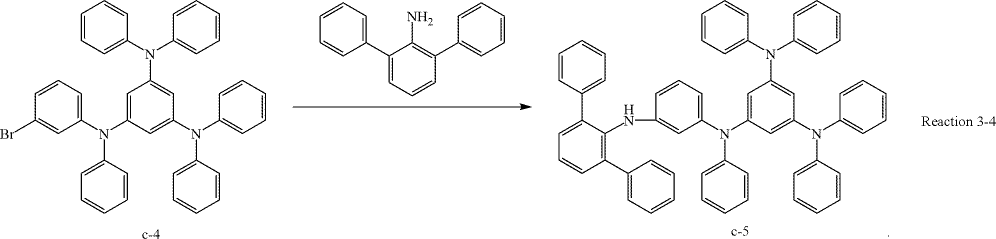

Under an argon (Ar) atmosphere, to a three-neck round-bottom flask, c-4 (13.5 g, 20.5 mmol), c-2 (5.03 g, 20.5 mmol), Pd(dba)₂ (0.35 g, 0.61 mmol), 2-dicyclohexylphosphino-2′,6′-dimethoxybiphenyl (0.50 g, 1.23 mmol), t-BuONa (2.36 g, 24.6 mmol) and 200 mL of toluene were added and stirred at about 80° C. for about 5 hours. After cooling to room temperature, 200 mL of water was added, liquid layers were separated, and an organic layer was extracted. The organic layer thus obtained was separated by column chromatography to obtain c-5 (14.6 g, yield 86.5%).

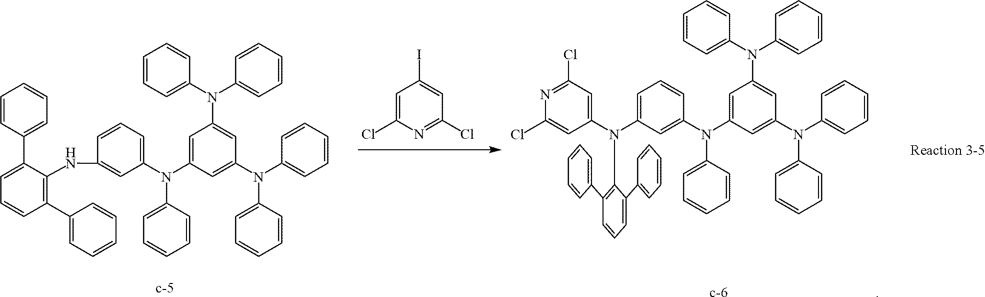

Under an argon (Ar) atmosphere, to a three-neck round-bottom flask, c-5 (12.0 g, 14.6 mmol), 2,6-dichloro-4-iodopyridine (12.0 g, 43.7 mmol), copper(I) iodide (2.78 g, 14.6 mmol), potassium carbonate (6.05 g, 43.7 mmol) and 30 mL of NMP were added and stirred at about 180° C. for about 24 hours. After cooling to room temperature, 200 mL of toluene was added, and filtering was performed. To the filtrate, 200 mL of water was added, liquid layers were separated, and an organic layer was extracted. The organic layer thus obtained was separated by column chromatography to obtain c-6 (11.2 g, yield 79.3%).

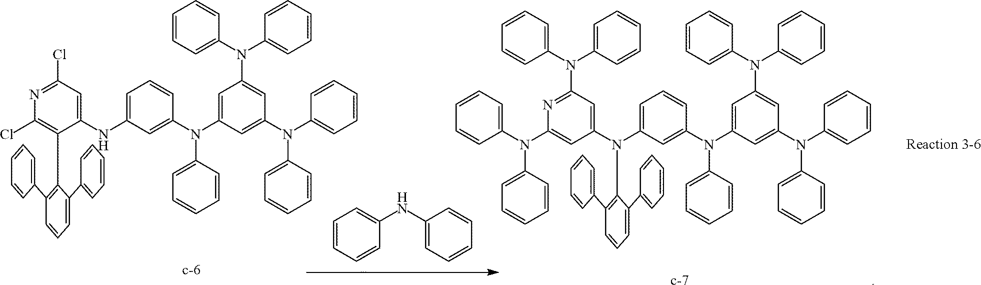

Under an argon (Ar) atmosphere, to a three-neck round-bottom flask, c-6 (10.0 g, 10.3 mmol), diphenylamine (3.49 g, 20.6 mmol), Pd(dba)₂ (0.30 g, 0.52 mmol), 2-dicyclohexylphosphino-2′,6′-dimethoxybiphenyl (0.42 g, 1.03 mmol), t-BuONa (2.18 g, 22.7 mmol) and 100 mL of toluene were added and stirred at about 70° C. for about 3 hours. After cooling to room temperature, 100 mL of water was added, liquid layers were separated, and an organic layer was extracted. The organic layer thus obtained was separated by column chromatography to obtain c-7 (10.5 g, yield 82.4%).

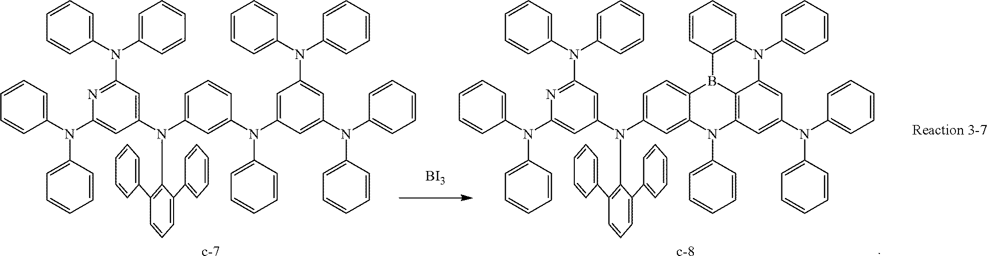

Under an argon (Ar) atmosphere, to a three-neck round-bottom flask, c-7 (10.0 g, 8.10 mmol), boron triiodide (6.34 g, 16.2 mmol) and 80 mL of o-dichlorobenzene were added and stirred at about 100° C. for about 3 hours. After cooling to room temperature, N,N-diisopropylethylamine (8.37 g, 64.8 mmol) was added, and stirring was performed at room temperature for about 1 hour. 80 mL of water was added, liquid layers were separated, and an organic layer was extracted. The organic layer thus obtained was separated by column chromatography to obtain c-8 (5.30 g, yield 53.7%).

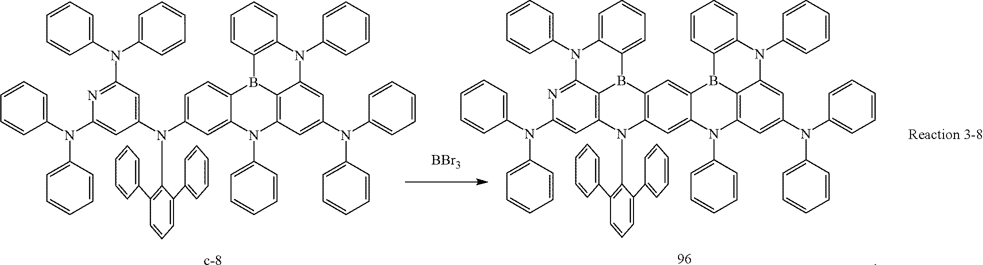

Under an argon (Ar) atmosphere, to a three-neck round-bottom flask, c-8 (5.00 g, 4.02 mmol), boron triiodide (5.04 g, 20.1 mmol) and 40 mL of o-dichlorobenzene were added and stirred at about 180° C. for about 3 hours. After cooling to room temperature, N,N-diisopropylethylamine (10.4 g, 80.5 mmol) was added, and stirring was performed at room temperature for about 1 hour. 40 mL of water was added, liquid layers were separated, and an organic layer was extracted. The organic layer thus obtained was separated by column chromatography to obtain Compound 96 (0.76 g, yield 15.1%).

Compound 96 was purified through sublimation (390° C., 1×10⁻⁵ Pa), and results of the mass measurement are as follows.

$$\text{FAB-MS m/z = 1250} \left({\text{M}}^{+} + 1\right)$$

### Synthesis of Compound 97

Compound 97 according to an embodiment may be synthesized by, for example, the steps of Reaction 4-1 to Reaction 4-6.

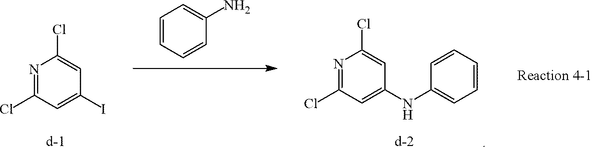

Under an argon (Ar) atmosphere, to a three-neck round-bottom flask, d-1 (29.4 g, 107 mmol), aniline (10.0 g, 107 mmol), copper(I) iodide (20.4 g, 107 mmol), potassium carbonate (29.7 g, 215 mmol) and 10 mL of NMP were added and stirred at about 180° C. for about 24 hours. After cooling to room temperature, 100 mL of toluene was added, and filtering was performed. To the filtrate, 100 mL of water was added, liquid layers were separated, and an organic layer was extracted. The organic layer was separated by column chromatography to obtain d-2 (16.2 g, yield 63.5%).

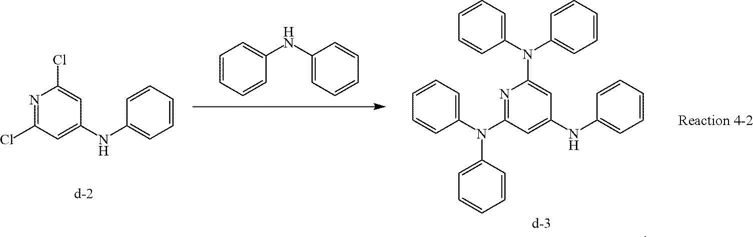

Under an argon (Ar) atmosphere, to a three-neck round-bottom flask, d-2 (10.0 g, 41.8 mmol), diphenylamine (14.2 g, 83.6 mmol), Pd(dba)₂(1.20 g, 2.09 mmol), 2-dicyclohexylphosphino-2′,6′-dimethoxybiphenyl (1.72 g, 4.18 mmol), t-BuONa (8.84 g, 92.0 mmol) and 200 mL of toluene were added and stirred at about 70° C. for about 3 hours. After cooling to room temperature, 100 mL of water was added, liquid layers were separated, and an organic layer was extracted. The organic layer thus obtained was separated by column chromatography to obtain d-3 (16.2 g, yield 76.8%).

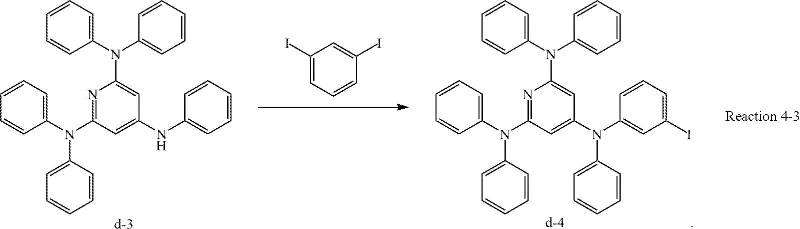

Under an argon (Ar) atmosphere, to a three-neck round-bottom flask, d-3 (15.0 g, 29.7 mmol), 1,3-diiodobenzene (29.4 g, 89.2 mmol), Pd(dba)₂ (0.51 g, 0.89 mmol), 2-dicyclohexylphosphino-2′,6′-dimethoxybiphenyl (0.73 g, 1.78 mmol), t-BuONa (3.14 g, 32.7 mmol) and 150 mL of toluene were added and stirred at about 70° C. for about 3 hours. After cooling to room temperature, 100 mL of water was added, liquid layers were separated, and an organic layer was extracted. The organic layer thus obtained was separated by column chromatography to obtain d-4 (15.5 g, yield 73.8%).

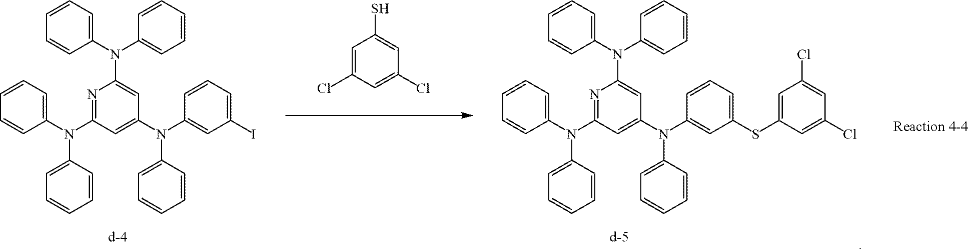

Under an argon (Ar) atmosphere, to a three-neck round-bottom flask, d-4 (15.0 g, 21.2 mmol), 3,5-dichlorobenzenethiol (3.80 g, 21.2 mmol), copper(I) iodide (4.04 g, 21.2 mmol), potassium carbonate (5.87 g, 42.5 mmol) and 30 mL of NMP were added and stirred at about 120° C. for about 5 hours. After cooling to room temperature, 150 mL of toluene was added, and filtering was performed. To the filtrate, 150 mL of water was added, liquid layers were separated, and an organic layer was extracted. The organic layer thus obtained was separated by column chromatography to obtain d-5 (10.4 g, yield 64.7%).

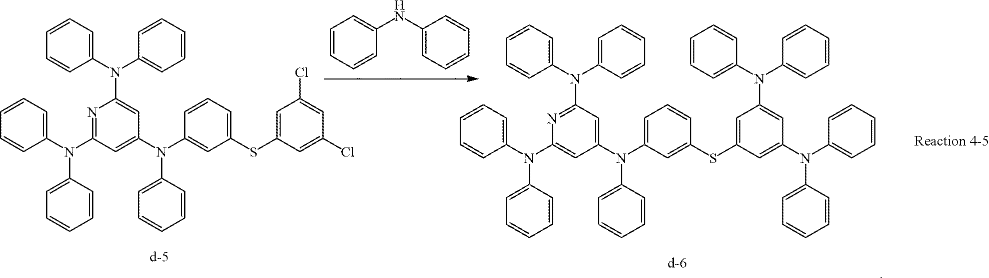

Under an argon (Ar) atmosphere, to a three-neck round-bottom flask, d-5 (10.0 g, 13.2 mmol), diphenylamine (4.47 g, 26.4 mmol), Pd(dba)₂ (0.38 g, 0.66 mmol), 2-dicyclohexylphosphino-2′,6′-dimethoxybiphenyl (0.54 g, 1.32 mmol), t-BuONa (2.79 g, 29.0 mmol) and 100 mL of toluene were added and stirred at about 80° C. for about 5 hours. After cooling to room temperature, 100 mL of water was added, liquid layers were separated, and an organic layer was extracted. The organic layer thus obtained was separated by column chromatography to obtain d-6 (9.66 g, yield 71.5%).

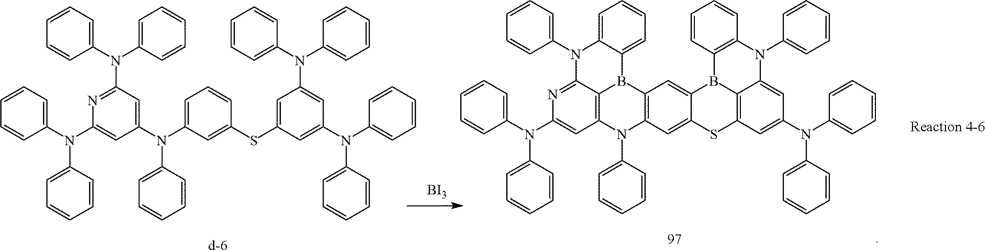

Under an argon (Ar) atmosphere, to a three-neck round-bottom flask, d-6 (9.00 g, 8.79 mmol), boron triiodide (27.5 g, 70.4 mmol) and 90 mL of o-dichlorobenzene were added and stirred at about 100° C. for about 3 hours. After cooling to room temperature, N,N-diisopropylethylamine (36.4 g, 281 mmol) was added, and stirring was performed at room temperature for about 1 hour. 100 mL of water was added, liquid layers were separated, and an organic layer was extracted. The organic layer thus obtained was separated by column chromatography to obtain Compound 97 (1.23 g, yield 13.5%).

Compound 97 was purified through sublimation (420° C., 2×10⁻⁵ Pa), and results of the mass measurement are as follows.

$$\text{FAB-MS m/z = 1039} \left({\text{M}}^{+} + 1\right)$$

### Synthesis of Compound 98

Compound 98 according to an embodiment may be synthesized by, for example, the steps of Reaction 5-1 to Reaction 5-6.

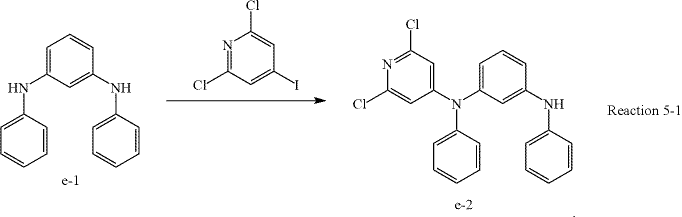

Under an argon (Ar) atmosphere, to a three-neck round-bottom flask, e-1 (71.3 g, 274 mmol), 2,6-dichloro-4-iodopyridine (25.0 g, 91.3 mmol), copper(I) iodide (17.4 g, 91.3 mmol), potassium carbonate (63.1 g, 456 mmol) and 100 mL of NMP were added and stirred at about 180° C. for about 24 hours. After cooling to room temperature, 100 mL of toluene was added, and filtering was performed. To the filtrate, 100 mL of water was added, liquid layers were separated, and an organic layer was extracted. The organic layer was separated by column chromatography to obtain e-2 (24.2 g, yield 65.3%).

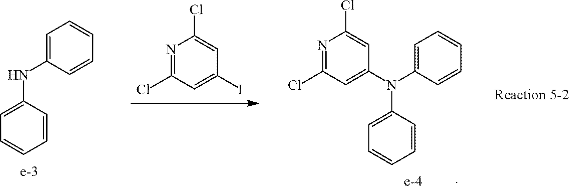

Under an argon (Ar) atmosphere, to a three-neck round-bottom flask, e-3 (24.7 g, 146 mmol), 2,6-dichloro-4-iodopyridine (40.0 g, 146 mmol), copper(I) iodide (27.8 g, 146 mmol), potassium carbonate (40.4 g, 292 mmol) and 100 mL of NMP were added and stirred at about 180° C. for about 24 hours. After cooling to room temperature, 1000 mL of toluene was added, and filtering was performed. To the filtrate, 1000 mL of water was added, liquid layers were separated, and an organic layer was extracted. The organic layer was separated by column chromatography to obtain e-4 (33.5 g, yield 72.8%).

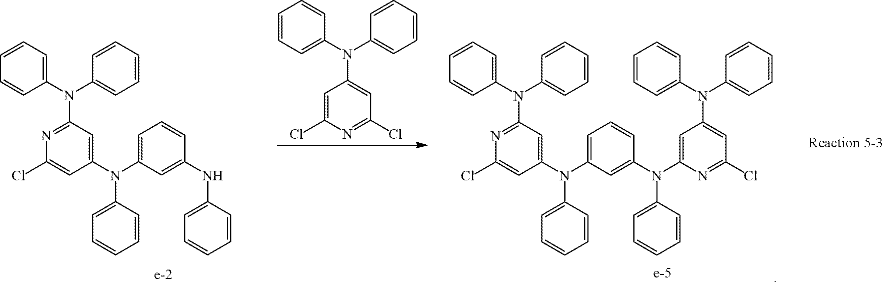

Under an argon (Ar) atmosphere, to a three-neck round-bottom flask, e-2 (20.0 g, 37.1 mmol), e-4 (29.2 g, 92.8 mmol), Pd(dba)₂ (0.64 g, 1.11 mmol), 2-dicyclohexylphosphino-2′,6′-dimethoxybiphenyl (0.91 g, 2.23 mmol), t-BuONa (4.28 g, 44.5 mmol) and 150 mL of toluene were added and stirred at about 60° C. for about 5 hours. After cooling to room temperature, 100 mL of water was added, liquid layers were separated, and an organic layer was extracted. The organic layer thus obtained was separated by column chromatography to obtain e-5 (15.1 g, yield 49.8%).

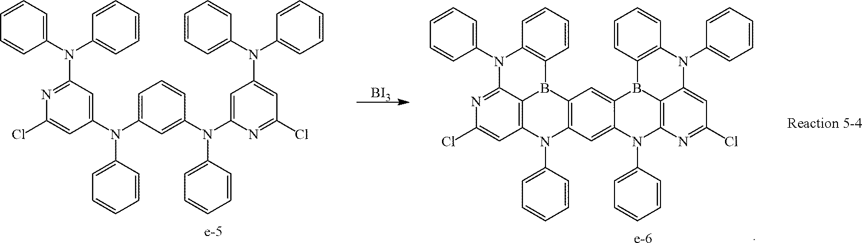

Under an argon (Ar) atmosphere, to a three-neck round-bottom flask, e-5 (14.0 g, 17.1 mmol), boron triiodide (80.4 g, 205 mmol) and 140 mL of o-dichlorobenzene were added and stirred at about 100° C. for about 3 hours. After cooling to room temperature, N,N-diisopropylethylamine (106 g, 882 mmol) was added, and stirring was performed at room temperature for about 1 hour. 100 mL of water was added, liquid layers were separated, and an organic layer was extracted. The organic layer thus obtained was separated by column chromatography to obtain e-6 (1.15 g, yield 8.1%)

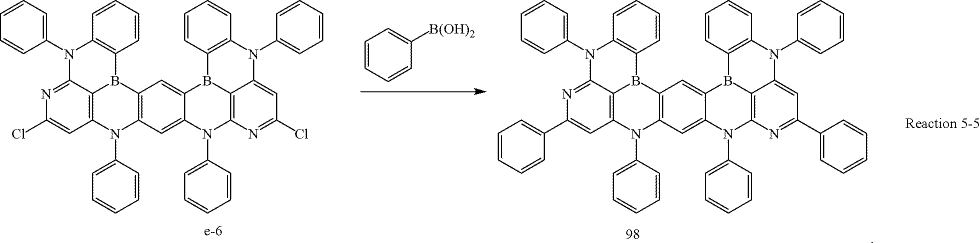

Under an argon (Ar) atmosphere, to a three-neck round-bottom flask, e-6 (1.10 g, 1.32 mmol), phenylboronic acid (0.225 g, 1.85 mmol), Pd(OAc)₂ (0.009 g, 0.04 mmol), 2-dicyclohexylphosphino-2′,6′-dimethoxybiphenyl (0.033 g, 0.08 mmol), tripotassium phosphate (0.392 g, 1.85 mmol), 10 mL of water, 10 mL of ethanol and 50 mL of toluene were added and stirred at about 90° C. for about 5 hours. After cooling to room temperature, 50 mL of water was added, liquid layers were separated, and an organic layer was extracted. The organic layer thus obtained was separated by column chromatography to obtain Compound 98 (0.86 g, yield 71.1%).

Compound 98 was purified through sublimation (390° C., 3×10⁻⁵ Pa), and mass evaluation was performed.

FAB-MS m/z=917(M⁺+1)

### Synthesis of Compound 99

Compound 99 according to an embodiment may be synthesized by, for example, the steps of Reaction 6-1 and Reaction 6-2.

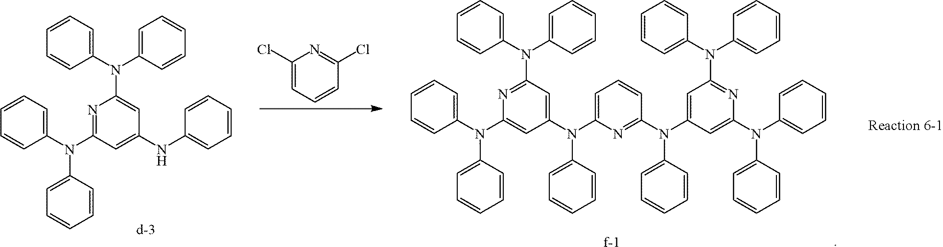

Under an argon (Ar) atmosphere, to a three-neck round-bottom flask, d-3 (34.1 g, 67.6 mmol), 2,6-dichloropyridine (5.0 g, 33.8 mmol), Pd(dba)₂ (0.583 g, 1.01 mmol), 2-dicyclohexylphosphino-2′,6′-dimethoxybiphenyl (0.832 g, 2.03 mmol), t-BuONa (3.57 g, 37.2 mmol) and 200 mL of toluene were added and stirred at about 60° C. for about 5 hours. After cooling to room temperature, 100 mL of water was added, liquid layers were separated, and an organic layer was extracted. The organic layer was separated by column chromatography to obtain f-1 (31.3 g, yield 85.4%).

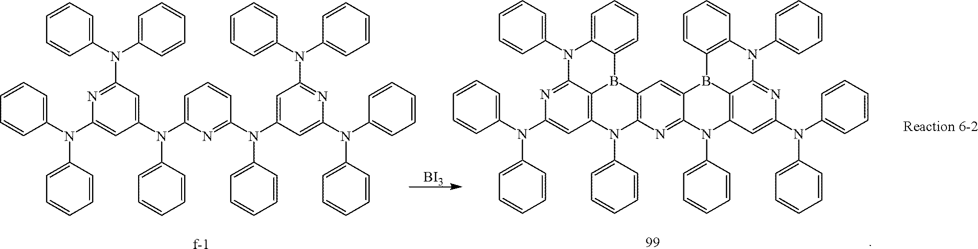

Under an argon (Ar) atmosphere, to a three-neck round-bottom flask, f-1 (30.0 g, 27.7 mmol), boron triiodide (217 g, 553 mmol) and 300 mL of o-dichlorobenzene were added and stirred at about 100° C. for about 3 hours. After cooling to room temperature, N,N-diisopropylethylamine (114 g, 153 mmol) was added, and stirring was performed at room temperature for about 1 hour. 300 mL of water was added, liquid layers were separated, and an organic layer was extracted. The organic layer thus obtained was separated by column chromatography to obtain Compound 99 (0.92 g, yield 3.0%).

Compound 99 was purified through sublimation (430° C., 2×10⁻⁵ Pa), and mass evaluation was performed with the following result.

$$\text{FAB-MS m/z = 1100} \left({\text{M}}^{+} + 1\right)$$

### 2. Manufacture and Evaluation of Light Emitting Element

Light emitting elements of embodiments, including polycyclic compounds of embodiments were manufactured by methods below. Light emitting elements of Examples 1 to 6 were manufactured utilizing the polycyclic compounds of Compounds 82, 86, 96, 97, 98 and 99 as light emitting dopants of respective emission layers.

Light emitting elements of Comparative Examples 1 to 3 were manufactured utilizing Comparative Compounds X1 to X3 as light emitting dopant materials of respective emission layers.

Comparative Compounds utilized for the manufacture of the elements are shown below.

### Comparative Compounds

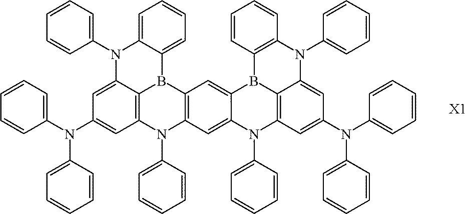 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1]

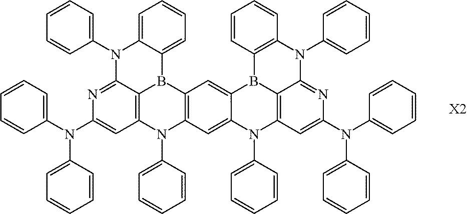 [SMILES: c1ccc(N(c2ccccc2)c2cc3c4c(n2)N(c2ccccc2)c2ccccc2B4c2cc4c(cc2N3c2ccccc2)N(c2ccccc2)c2cc(N(c3ccccc3)c3ccccc3)nc3c2B4c2ccccc2N3c2ccccc2)cc1]

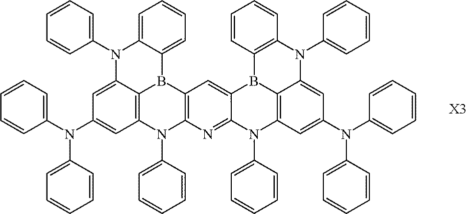 [SMILES: c1ccc(N(c2ccccc2)c2cc3c4c(c2)N(c2ccccc2)c2nc5c(cc2B4c2ccccc2N3c2ccccc2)B2c3ccccc3N(c3ccccc3)c3cc(N(c4ccccc4)c4ccccc4)cc(c32)N5c2ccccc2)cc1]

### Other Compounds Utilized for the Manufacture of Light Emitting Elements

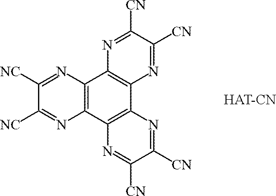

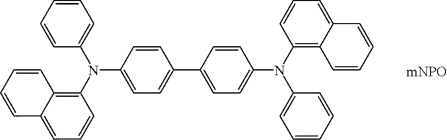 [SMILES: c1ccc(N(c2ccc(-c3ccc(N(c4ccccc4)c4cccc5ccccc45)cc3)cc2)c2cccc3ccccc23)cc1]

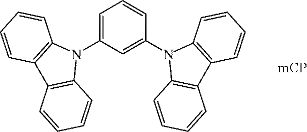 [SMILES: c1cc(-n2c3ccccc3c3ccccc32)cc(-n2c3ccccc3c3ccccc32)c1]

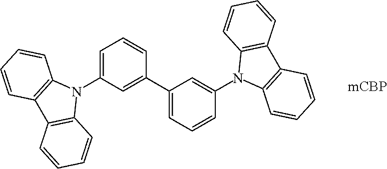 [SMILES: c1cc(-c2cccc(-n3c4ccccc4c4ccccc43)c2)cc(-n2c3ccccc3c3ccccc32)c1]

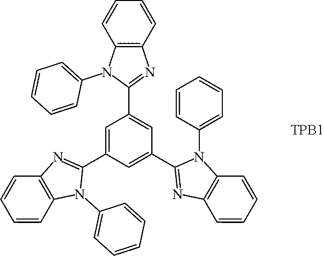 [SMILES: c1ccc(-n2c(-c3cc(-c4nc5ccccc5n4-c4ccccc4)cc(-c4nc5ccccc5n4-c4ccccc4)c3)nc3ccccc32)cc1]

A glass substrate on which ITO of 15 Ω/cm² (1000 Å) was patterned was cut into a size of 50 mm x 50 mm × 0.7 mm, washed (e.g., cleaned) by ultrasonic waves utilizing isopropyl alcohol and pure water for about 5 minutes each, and cleaned by exposing to ultraviolet rays for about 30 minutes and exposing to ozone.

Then, HAT-CN was deposited to a thickness of about 100 Å, α-NPD was deposited to a thickness of about 800 Å, and mCP was deposited to a thickness of about 50 Å to form a hole transport region. Then, on the hole transport region, a dopant and a host were co-deposited in a ratio (e.g., weight amount) of about 1:99 to form an emission layer with a thickness of about 200 Å. The dopant utilized was the compounds of Examples 1 to 3 or Comparative Example 1, and the host was mCBP.

Then, on the emission layer, TPBI was deposited to a thickness of about 300 Å, and LiF was deposited to a thickness of about 5 Å to form an electron transport region. After that, on the electron transport region, Al was deposited to form a second electrode of a thickness of about 1000 Å to manufacture a light emitting element.

### Evaluation of Properties of Light Emitting Elements

Table 1 shows the evaluation results of the light emitting elements of Example 1 to Example 6, and Comparative Example 1 to Comparative Example 3. In Table 1, the maximum external quantum efficiency (EQEₘₐₓ) at 1000 cd/m², and maximum emission wavelength (λmax) are compared and shown.

The maximum external quantum efficiency was calculated by calculation of internal quantum efficiency x charge balance x out coupling efficiency.

TABLE 1

| Element manufacturing example | Dopant | EQEₘₐₓ | λmax |
|---|---|---|---|
| | | % | (nm) |
| Example 1 | Compound 82 | 18.8 | 459 |
| Example 2 | Compound 86 | 16.5 | 453 |
| Example 3 | Compound 96 | 19.0 | 459 |
| Example 4 | Compound 97 | 18.0 | 456 |
| Example 5 | Compound 98 | 17.4 | 455 |
| Example 6 | Compound 99 | 18.5 | 462 |
| Comparative Example 1 | X1 | 16.0 | 470 |
| Comparative Example 2 | X2 | 17.4 | 442 |
| Comparative Example 3 | X3 | 16.6 | 484 |

Referring to the results of Table 1, it could be confirmed that the light emitting elements of Examples 1 to 6 each showed greater maximum external quantum efficiency when compared to the light emitting elements of Comparative Example 1 to Comparative Example 3, and each showed the maximum emission wavelength of about 450 nm to less than about 470 nm.

For example, it could be confirmed that the Examples each showed the maximum external quantum efficiency of about 16.5% or more and the maximum emission wavelength of about 450 nm to less than about 470 nm. In contrast, it could be confirmed that the light emitting element of Comparative Example 1 showed the maximum external quantum efficiency of less than about 16.5%, the light emitting element of Comparative Example 2 showed the maximum emission wavelength of less than about 450 nm, and the light emitting element of Comparative Example 3 showed the maximum emission wavelength of greater than about 470 nm.

As described above, it could be confirmed that the light emitting elements including the polycyclic compounds of the Examples showed higher emission efficiency properties and at the same time, had emission wavelengths of about 450 nm to less than about 470 nm.

The light emitting element according to an embodiment includes the polycyclic compound of an embodiment in an emission layer, and may be to emit light having an emission wavelength of about 450 nm to less than about 470 nm and at the same time, may show high emission efficiency properties.

The polycyclic compound (i.e., the first compound) of an embodiment includes a pyridinic nitrogen atom, and has the maximum emission wavelength of about 450 nm to less than about 470 nm, thereby improving the emission efficiency of the light emitting element.

The light emitting element of an embodiment includes the polycyclic compound of an embodiment and may be to emit blue light and show high emission efficiency properties.

The polycyclic compound (i.e., the first compound) of an embodiment emits blue light and may improve the emission efficiency of a light emitting element.

The use of “may” when describing embodiments of the present disclosure refers to “one or more embodiments of the present disclosure”. As used herein, the term “and/or” includes any and all combinations of one or more of the associated listed items. Throughout the disclosure, the expression, such as “at least one of a, b or c”, “at least one selected from a, b, and c”, “at least one selected from the group consisting of a, b, and c”, etc., indicates only a, only b, only c, both (e.g., simultaneously) a and b, both (e.g., simultaneously) a and c, both (e.g., simultaneously) b and c, all of a, b, and c, or variation(s) thereof.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic apparatus, the display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but various changes and modifications can be made by one ordinary skilled in the art within the spirit and scope of the present disclosure as hereinafter claimed, and equivalents thereof.

What is claimed is:

1. A light emitting element, comprising:
a first electrode;
a second electrode on the first electrode; and
an emission layer between the first electrode and the second electrode, and comprising a first compound represented by Formula 1, and at least one selected from among a second compound to a fourth compound,
wherein the first compound to the fourth compound are different from each other: 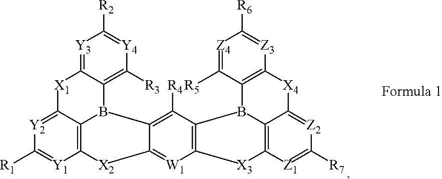
in Formula 1,
R₁ to R₇ are each independently a hydrogen atom, a deuterium atom, a substituted or unsubstituted oxy group, a substituted or unsubstituted thio group, a substituted or unsubstituted amino group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or combined with an adjacent group to form a ring,
X₁ to X₄ are each independently CRₐR_{b}, or NR_{c},
a case where X₁ to X₄ are all CRₐR_{b} is excluded,
at least one selected from among Y₁ to Y₄, Z₁ to Z₄, and W₁ is N, and the remainder of Y₁ to Y₄, Z₁ to Z₄, and W₁ are each independently CR_{d},
when W₁ is CR_{d}, a case where Y₁ and Z₁ are N at the same time, a case where Y₂ and Z₂ are N at the same time, a case where Y₃ and Z₃ are N at the same time, and a case where Y₄ and Z₄ are N at the same time are excluded, and
Rₐ to R_{d} are each independently a hydrogen atom, a deuterium atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or combined with an adjacent group to form a ring.

2. The light emitting element of claim 1, wherein the first compound represented by Formula 1 is represented by Formula 2-1 or Formula 2-2: 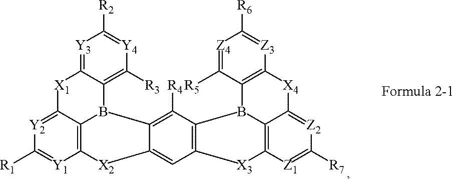 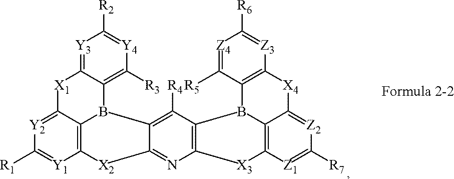
in Formula 2-1 and Formula 2-2, X₁ to X_{4,} Y₁ to Y₄, Z₁ to Z₄, and R₁ to R₇ are the same as defined in Formula 1.

3. The light emitting element of claim 2, wherein 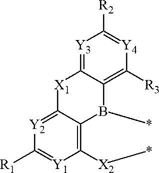
and 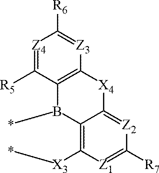
in Formula 2-1 are different from each other.

4. The light emitting element of claim 1, wherein X₁ and X₄ in Formula 1 are different from each other.

5. The light emitting element of claim 4, wherein the first compound represented by Formula 1 is represented by Formula 3: 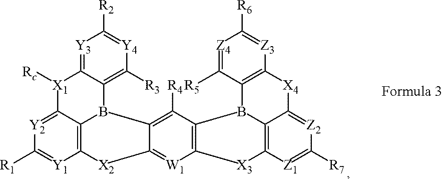
in Formula 3, W₁, X₂ to X_{4,} Y₁ to Y₄, Z₁ to Z₄, R₁ to R₇, and R_{c} are the same as defined in Formula 1.

6. The light emitting element of claim 1, wherein X₂ and X₃ in Formula 1 are different from each other.

7. The light emitting element of claim 6, wherein Formula 1 is represented by Formula 4: 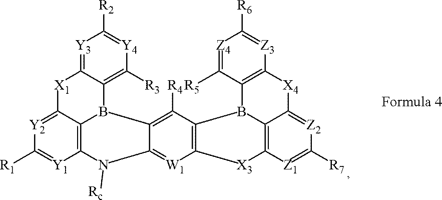
in Formula 4, W₁, X₁, X₂, X_{4,} Y₁ to Y₄, Z₁ to Z₄, R₁ to R₇, and R_{c} are the same as defined in Formula 1.

8. The light emitting element of claim 1, wherein the emission layer is to emit blue light.

9. The light emitting element of claim 1, wherein the first compound is to emit thermally activated delayed fluorescence.

10. The light emitting element of claim 1, wherein the emission layer comprises the second compound and the third compound, and
the second compound is represented by any one selected from among HT-1 to HT-4: 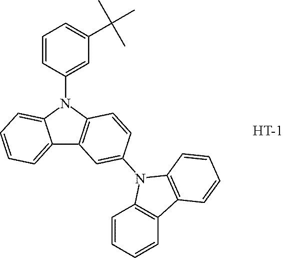 [SMILES: CC(C)(C)c1cccc(-n2c3ccccc3c3cc(-n4c5ccccc5c5ccccc54)ccc32)c1] 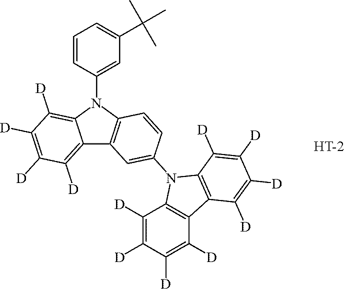 [SMILES: [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1] 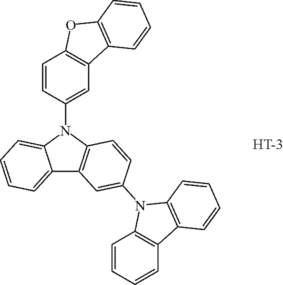 [SMILES: c1ccc2c(c1)oc1ccc(-n3c4ccccc4c4cc(-n5c6ccccc6c6ccccc65)ccc43)cc12] 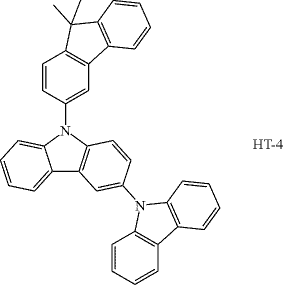 [SMILES: CC1(C)c2ccccc2-c2cc(-n3c4ccccc4c4cc(-n5c6ccccc6c6ccccc65)ccc43)ccc21]
.

11. The light emitting element of claim 10, wherein the third compound is represented by any one selected from among ET-1 to ET-3: 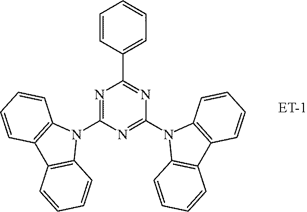 [SMILES: c1ccc(-c2nc(-n3c4ccccc4c4ccccc43)nc(-n3c4ccccc4c4ccccc43)n2)cc1] 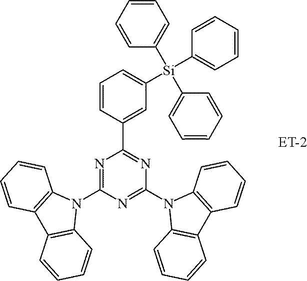 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1] 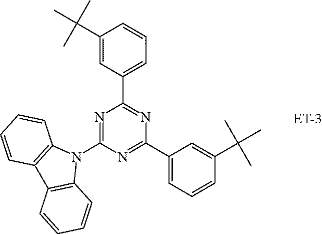 [SMILES: CC(C)(C)c1cccc(-c2nc(-c3cccc(C(C)(C)C)c3)nc(-n3c4ccccc4c4ccccc43)n2)c1]
.

12. The light emitting element of claim 11, wherein the emission layer further comprises the fourth compound, and the fourth compound is represented by Formula M-b: 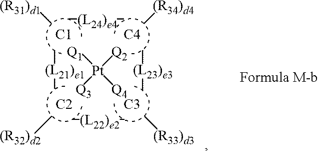
in Formula M-b,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
L₂₁ to L₂₄ are each independently a direct linkage, 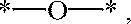 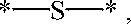 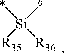 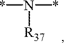 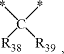 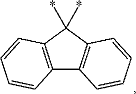
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
e1 to e4 are each independently 0 or 1,
R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or combined with an adjacent group to form a ring, and
d1 to d4 are each independently an integer of 0 to 4.

13. The light emitting element of claim 12, wherein the first compound is a light emitting dopant, the second compound is a hole transport host, the third compound is an electron transport host, and the fourth compound is an auxiliary dopant.

14. The light emitting element of claim 1, wherein the first compound is represented by any one selected from among compounds represented in Compound Group 1:
Compound Group 1 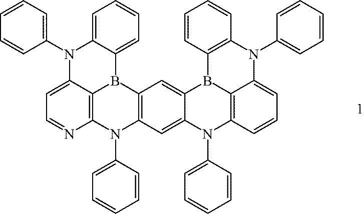 [SMILES: c1ccc(N2c3ccccc3B3c4cc5c(cc4N(c4ccccc4)c4cccc2c43)N(c2ccccc2)c2nccc3c2B5c2ccccc2N3c2ccccc2)cc1] 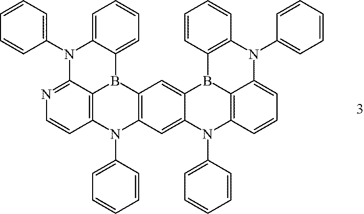 [SMILES: c1ccc(N2c3ccccc3B3c4cc5c(cc4N(c4ccccc4)c4cccc2c43)N(c2ccccc2)c2ccnc3c2B5c2ccccc2N3c2ccccc2)cc1] 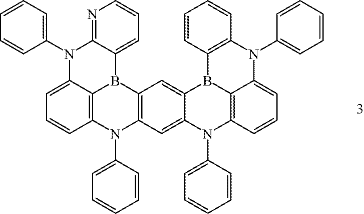 [SMILES: c1ccc(N2c3ccccc3B3c4cc5c(cc4N(c4ccccc4)c4cccc2c43)N(c2ccccc2)c2cccc3c2B5c2cccnc2N3c2ccccc2)cc1] 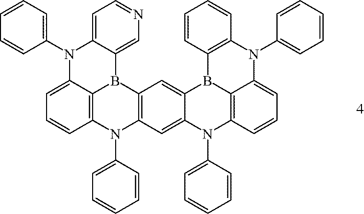 [SMILES: c1ccc(N2c3ccccc3B3c4cc5c(cc4N(c4ccccc4)c4cccc2c43)N(c2ccccc2)c2cccc3c2B5c2cnccc2N3c2ccccc2)cc1] 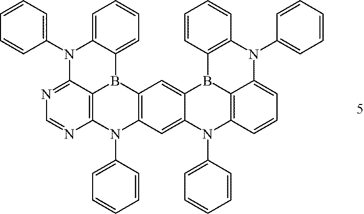 [SMILES: c1ccc(N2c3ccccc3B3c4cc5c(cc4N(c4ccccc4)c4cccc2c43)N(c2ccccc2)c2ncnc3c2B5c2ccccc2N3c2ccccc2)cc1] 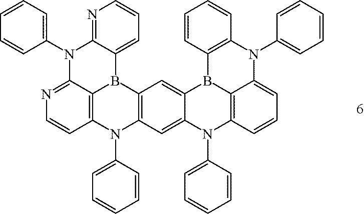 [SMILES: c1ccc(N2c3ccccc3B3c4cc5c(cc4N(c4ccccc4)c4cccc2c43)N(c2ccccc2)c2ccnc3c2B5c2cccnc2N3c2ccccc2)cc1] 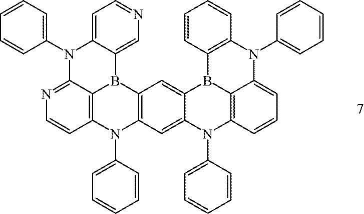 [SMILES: c1ccc(N2c3ccccc3B3c4cc5c(cc4N(c4ccccc4)c4cccc2c43)N(c2ccccc2)c2ccnc3c2B5c2cnccc2N3c2ccccc2)cc1] 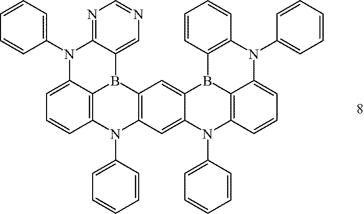 [SMILES: c1ccc(N2c3ccccc3B3c4cc5c(cc4N(c4ccccc4)c4cccc2c43)N(c2ccccc2)c2cccc3c2B5c2cncnc2N3c2ccccc2)cc1] 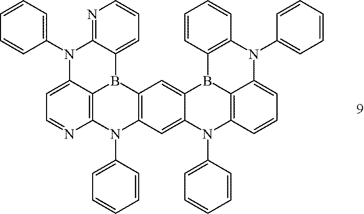 [SMILES: c1ccc(N2c3ccccc3B3c4cc5c(cc4N(c4ccccc4)c4cccc2c43)N(c2ccccc2)c2nccc3c2B5c2cccnc2N3c2ccccc2)cc1] 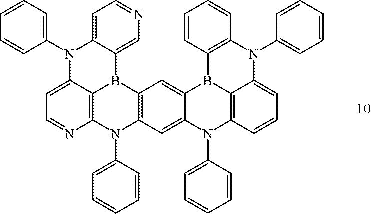 [SMILES: c1ccc(N2c3ccccc3B3c4cc5c(cc4N(c4ccccc4)c4cccc2c43)N(c2ccccc2)c2nccc3c2B5c2cnccc2N3c2ccccc2)cc1] 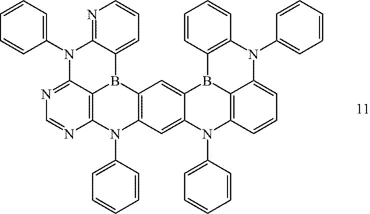 [SMILES: c1ccc(N2c3ccccc3B3c4cc5c(cc4N(c4ccccc4)c4cccc2c43)N(c2ccccc2)c2ncnc3c2B5c2cccnc2N3c2ccccc2)cc1] 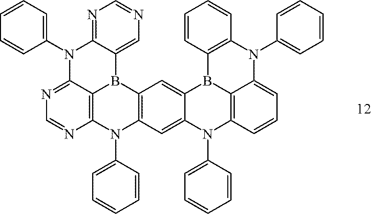 [SMILES: c1ccc(N2c3ccccc3B3c4cc5c(cc4N(c4ccccc4)c4cccc2c43)N(c2ccccc2)c2ncnc3c2B5c2cncnc2N3c2ccccc2)cc1] 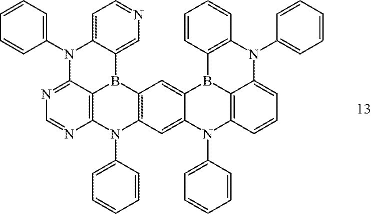 [SMILES: c1ccc(N2c3ccccc3B3c4cc5c(cc4N(c4ccccc4)c4cccc2c43)N(c2ccccc2)c2ncnc3c2B5c2cnccc2N3c2ccccc2)cc1] 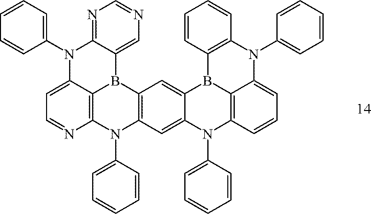 [SMILES: c1ccc(N2c3ccccc3B3c4cc5c(cc4N(c4ccccc4)c4cccc2c43)N(c2ccccc2)c2nccc3c2B5c2cncnc2N3c2ccccc2)cc1] 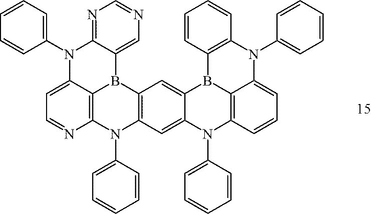 [SMILES: c1ccc(N2c3ccccc3B3c4cc5c(cc4N(c4ccccc4)c4cccc2c43)N(c2ccccc2)c2nccc3c2B5c2cncnc2N3c2ccccc2)cc1] 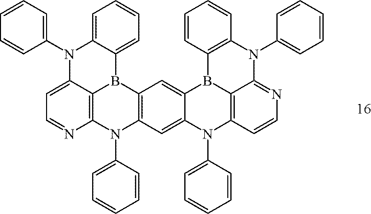 [SMILES: c1ccc(N2c3cc4c(cc3B3c5ccccc5N(c5ccccc5)c5nccc2c53)B2c3ccccc3N(c3ccccc3)c3ccnc(c32)N4c2ccccc2)cc1] 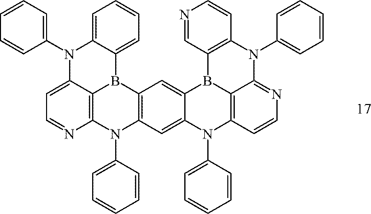 [SMILES: c1ccc(N2c3cc4c(cc3B3c5cnccc5N(c5ccccc5)c5nccc2c53)B2c3ccccc3N(c3ccccc3)c3ccnc(c32)N4c2ccccc2)cc1] 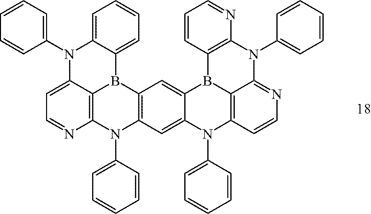 [SMILES: c1ccc(N2c3ccccc3B3c4cc5c(cc4N(c4ccccc4)c4nccc2c43)N(c2ccccc2)c2ccnc3c2B5c2cccnc2N3c2ccccc2)cc1] 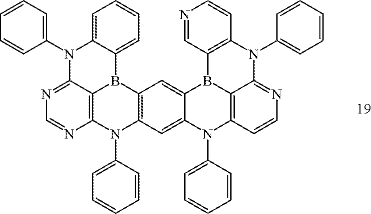 [SMILES: c1ccc(N2c3cc4c(cc3B3c5cnccc5N(c5ccccc5)c5nccc2c53)B2c3ccccc3N(c3ccccc3)c3ncnc(c32)N4c2ccccc2)cc1] 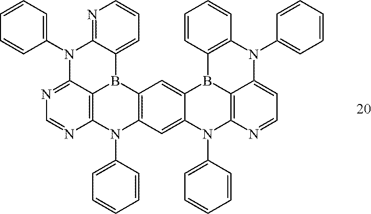 [SMILES: c1ccc(N2c3ccccc3B3c4cc5c(cc4N(c4ccccc4)c4nccc2c43)N(c2ccccc2)c2ncnc3c2B5c2cccnc2N3c2ccccc2)cc1] 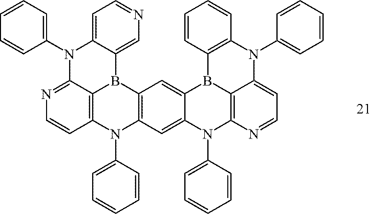 [SMILES: c1ccc(N2c3cc4c(cc3B3c5cnccc5N(c5ccccc5)c5nccc2c53)B2c3ccccc3N(c3ccccc3)c3ccnc(c32)N4c2ccccc2)cc1] 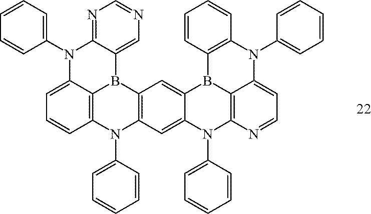 [SMILES: c1ccc(N2c3cc4c(cc3B3c5cncnc5N(c5ccccc5)c5cccc2c53)B2c3ccccc3N(c3ccccc3)c3ccnc(c32)N4c2ccccc2)cc1] 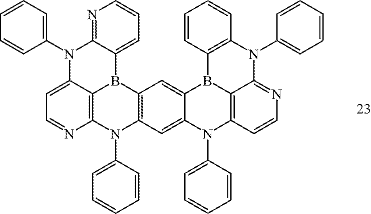 [SMILES: c1ccc(N2c3cc4c(cc3B3c5ccccc5N(c5ccccc5)c5nccc2c53)B2c3cccnc3N(c3ccccc3)c3ccnc(c32)N4c2ccccc2)cc1] 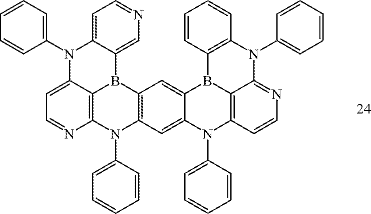 [SMILES: c1ccc(N2c3cc4c(cc3B3c5ccccc5N(c5ccccc5)c5nccc2c53)B2c3cnccc3N(c3ccccc3)c3ccnc(c32)N4c2ccccc2)cc1] 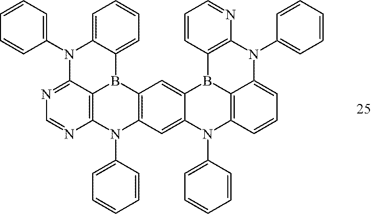 [SMILES: c1ccc(N2c3cc4c(cc3B3c5cccnc5N(c5ccccc5)c5cccc2c53)B2c3ccccc3N(c3ccccc3)c3ncnc(c32)N4c2ccccc2)cc1] 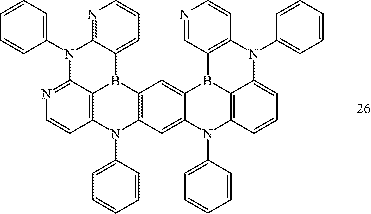 [SMILES: c1ccc(N2c3ccncc3B3c4cc5c(cc4N(c4ccccc4)c4cccc2c43)N(c2ccccc2)c2ccnc3c2B5c2cccnc2N3c2ccccc2)cc1] 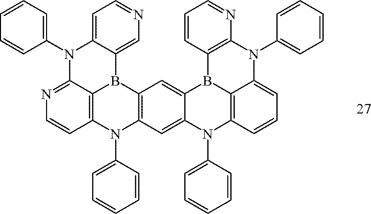 [SMILES: c1ccc(N2c3cc4c(cc3B3c5cccnc5N(c5ccccc5)c5cccc2c53)B2c3cnccc3N(c3ccccc3)c3nccc(c32)N4c2ccccc2)cc1] 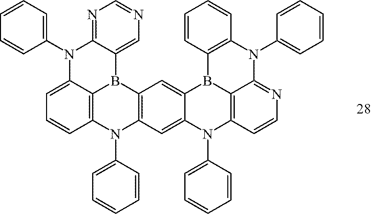 [SMILES: c1ccc(N2c3cc4c(cc3B3c5cncnc5N(c5ccccc5)c5cccc2c53)B2c3ccccc3N(c3ccccc3)c3nccc(c32)N4c2ccccc2)cc1] 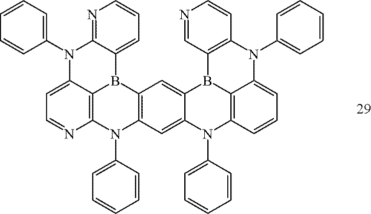 [SMILES: c1ccc(N2c3ccncc3B3c4cc5c(cc4N(c4ccccc4)c4cccc2c43)N(c2ccccc2)c2nccc3c2B5c2cccnc2N3c2ccccc2)cc1] 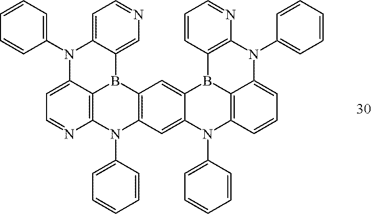 [SMILES: c1ccc(N2c3cc4c(cc3B3c5cccnc5N(c5ccccc5)c5cccc2c53)B2c3cnccc3N(c3ccccc3)c3ccnc(c32)N4c2ccccc2)cc1] 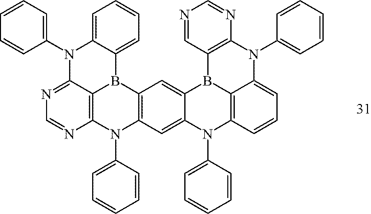 [SMILES: c1ccc(N2c3cc4c(cc3B3c5cncnc5N(c5ccccc5)c5cccc2c53)B2c3ccccc3N(c3ccccc3)c3ncnc(c32)N4c2ccccc2)cc1] 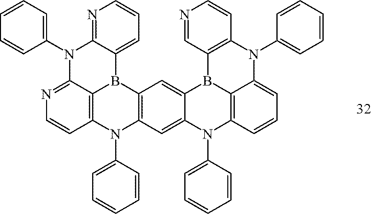 [SMILES: c1ccc(N2c3ccncc3B3c4cc5c(cc4N(c4ccccc4)c4cccc2c43)N(c2ccccc2)c2ccnc3c2B5c2cccnc2N3c2ccccc2)cc1] 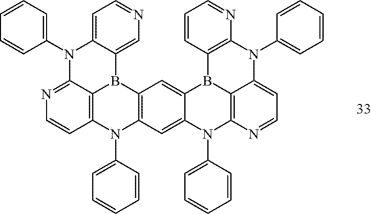 [SMILES: c1ccc(N2c3cc4c(cc3B3c5cnccc5N(c5ccccc5)c5nccc2c53)B2c3cccnc3N(c3ccccc3)c3ccnc(c32)N4c2ccccc2)cc1] 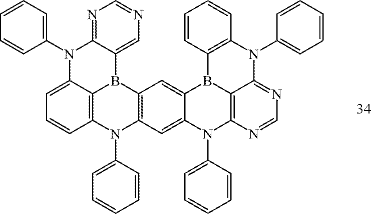 [SMILES: c1ccc(N2c3cc4c(cc3B3c5cncnc5N(c5ccccc5)c5cccc2c53)B2c3ccccc3N(c3ccccc3)c3ncnc(c32)N4c2ccccc2)cc1] 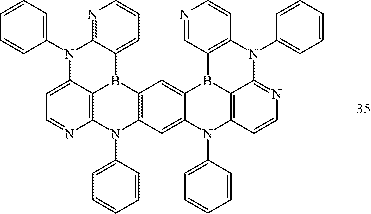 [SMILES: c1ccc(N2c3cc4c(cc3B3c5cnccc5N(c5ccccc5)c5nccc2c53)B2c3cccnc3N(c3ccccc3)c3ccnc(c32)N4c2ccccc2)cc1] 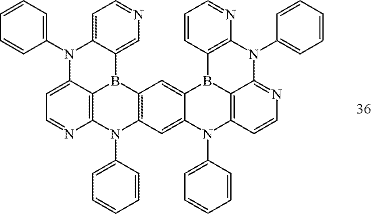 [SMILES: c1ccc(N2c3ccncc3B3c4cc5c(cc4N(c4ccccc4)c4nccc2c43)N(c2ccccc2)c2ccnc3c2B5c2cccnc2N3c2ccccc2)cc1] 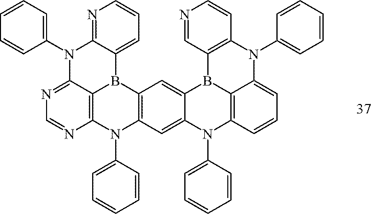 [SMILES: c1ccc(N2c3ccncc3B3c4cc5c(cc4N(c4ccccc4)c4cccc2c43)N(c2ccccc2)c2ncnc3c2B5c2cccnc2N3c2ccccc2)cc1] 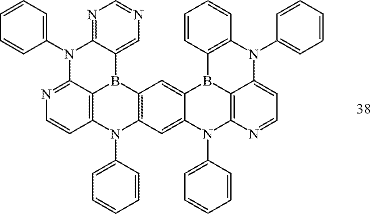 [SMILES: c1ccc(N2c3ccccc3B3c4cc5c(cc4N(c4ccccc4)c4nccc2c43)N(c2ccccc2)c2ccnc3c2B5c2cncnc2N3c2ccccc2)cc1] 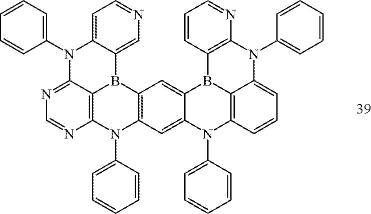 [SMILES: c1ccc(N2c3cc4c(cc3B3c5cccnc5N(c5ccccc5)c5cccc2c53)B2c3cnccc3N(c3ccccc3)c3ncnc(c32)N4c2ccccc2)cc1] 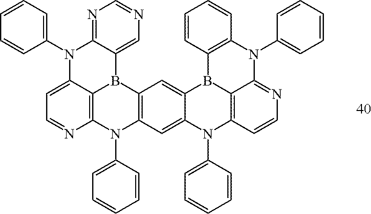 [SMILES: c1ccc(N2c3cc4c(cc3B3c5ccccc5N(c5ccccc5)c5nccc2c53)B2c3cncnc3N(c3ccccc3)c3ccnc(c32)N4c2ccccc2)cc1] 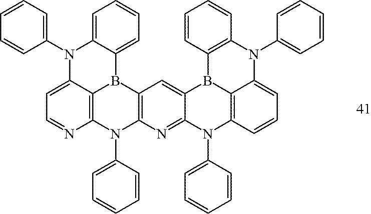 [SMILES: c1ccc(N2c3ccccc3B3c4cc5c(nc4N(c4ccccc4)c4cccc2c43)N(c2ccccc2)c2nccc3c2B5c2ccccc2N3c2ccccc2)cc1] 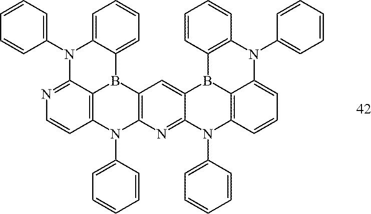 [SMILES: c1ccc(N2c3ccccc3B3c4cc5c(nc4N(c4ccccc4)c4cccc2c43)N(c2ccccc2)c2ccnc3c2B5c2ccccc2N3c2ccccc2)cc1] 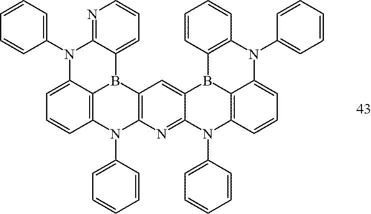 [SMILES: c1ccc(N2c3ccccc3B3c4cc5c(nc4N(c4ccccc4)c4cccc2c43)N(c2ccccc2)c2cccc3c2B5c2cccnc2N3c2ccccc2)cc1] 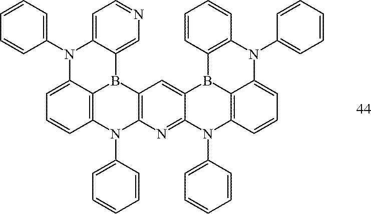 [SMILES: c1ccc(N2c3ccccc3B3c4cc5c(nc4N(c4ccccc4)c4cccc2c43)N(c2ccccc2)c2cccc3c2B5c2cnccc2N3c2ccccc2)cc1] 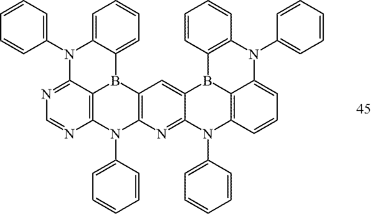 [SMILES: c1ccc(N2c3ccccc3B3c4cc5c(nc4N(c4ccccc4)c4cccc2c43)N(c2ccccc2)c2ncnc3c2B5c2ccccc2N3c2ccccc2)cc1] 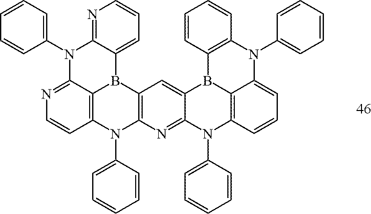 [SMILES: c1ccc(N2c3ccccc3B3c4cc5c(nc4N(c4ccccc4)c4cccc2c43)N(c2ccccc2)c2ccnc3c2B5c2cccnc2N3c2ccccc2)cc1] 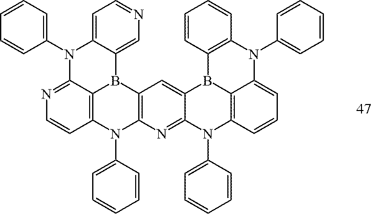 [SMILES: c1ccc(N2c3ccccc3B3c4cc5c(nc4N(c4ccccc4)c4cccc2c43)N(c2ccccc2)c2ccnc3c2B5c2cnccc2N3c2ccccc2)cc1] 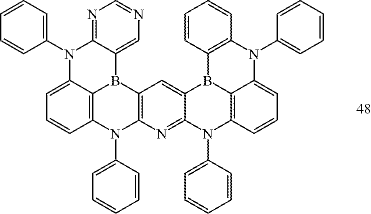 [SMILES: c1ccc(N2c3ccccc3B3c4cc5c(nc4N(c4ccccc4)c4cccc2c43)N(c2ccccc2)c2cccc3c2B5c2cncnc2N3c2ccccc2)cc1] 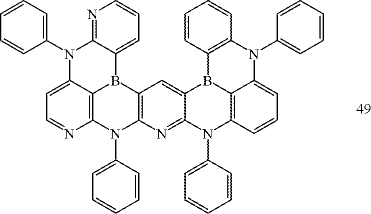 [SMILES: c1ccc(N2c3ccccc3B3c4cc5c(nc4N(c4ccccc4)c4cccc2c43)N(c2ccccc2)c2nccc3c2B5c2cccnc2N3c2ccccc2)cc1] 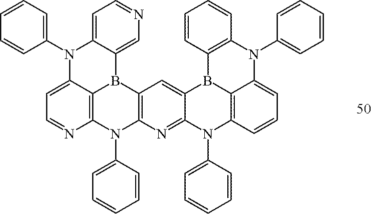 [SMILES: c1ccc(N2c3ccccc3B3c4cc5c(nc4N(c4ccccc4)c4cccc2c43)N(c2ccccc2)c2nccc3c2B5c2cnccc2N3c2ccccc2)cc1] 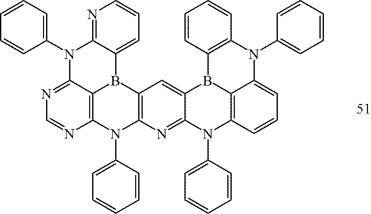 [SMILES: c1ccc(N2c3ccccc3B3c4cc5c(nc4N(c4ccccc4)c4cccc2c43)N(c2ccccc2)c2ncnc3c2B5c2cccnc2N3c2ccccc2)cc1] 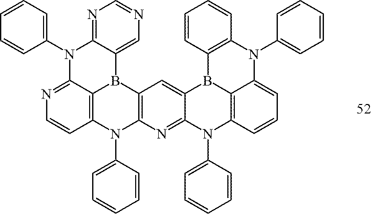 [SMILES: c1ccc(N2c3ccccc3B3c4cc5c(nc4N(c4ccccc4)c4cccc2c43)N(c2ccccc2)c2ccnc3c2B5c2cncnc2N3c2ccccc2)cc1] 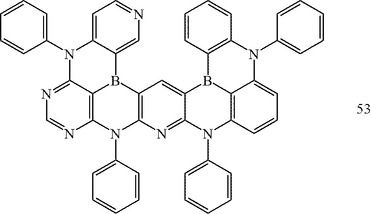 [SMILES: c1ccc(N2c3ccccc3B3c4cc5c(nc4N(c4ccccc4)c4cccc2c43)N(c2ccccc2)c2ncnc3c2B5c2cnccc2N3c2ccccc2)cc1] 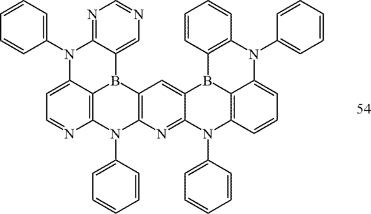 [SMILES: c1ccc(N2c3ccccc3B3c4cc5c(nc4N(c4ccccc4)c4cccc2c43)N(c2ccccc2)c2nccc3c2B5c2cncnc2N3c2ccccc2)cc1] 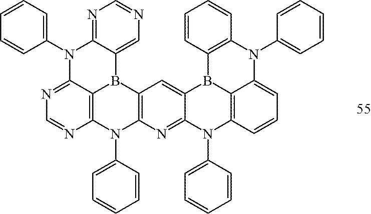 [SMILES: c1ccc(N2c3ccccc3B3c4cc5c(nc4N(c4ccccc4)c4cccc2c43)N(c2ccccc2)c2ncnc3c2B5c2cncnc2N3c2ccccc2)cc1] 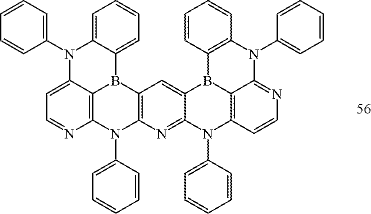 [SMILES: c1ccc(N2c3ccccc3B3c4cc5c(nc4N(c4ccccc4)c4nccc2c43)N(c2ccccc2)c2ccnc3c2B5c2ccccc2N3c2ccccc2)cc1] 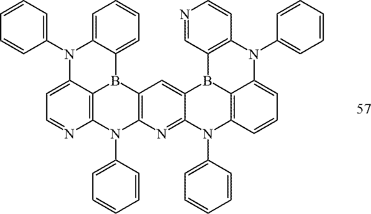 [SMILES: c1ccc(N2c3ccncc3B3c4cc5c(nc4N(c4ccccc4)c4cccc2c43)N(c2ccccc2)c2nccc3c2B5c2ccccc2N3c2ccccc2)cc1] 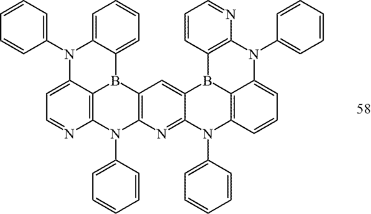 [SMILES: c1ccc(N2c3ccccc3B3c4cc5c(nc4N(c4ccccc4)c4nccc2c43)N(c2ccccc2)c2cccc3c2B5c2cccnc2N3c2ccccc2)cc1] 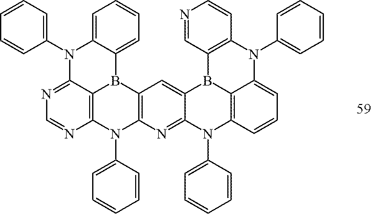 [SMILES: c1ccc(N2c3ccncc3B3c4cc5c(nc4N(c4ccccc4)c4cccc2c43)N(c2ccccc2)c2ncnc3c2B5c2ccccc2N3c2ccccc2)cc1] 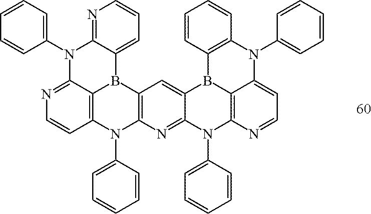 [SMILES: c1ccc(N2c3ccccc3B3c4cc5c(nc4N(c4ccccc4)c4nccc2c43)N(c2ccccc2)c2ccnc3c2B5c2cccnc2N3c2ccccc2)cc1] 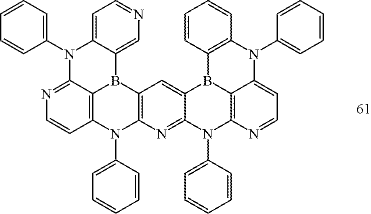 [SMILES: c1ccc(N2c3ccccc3B3c4cc5c(nc4N(c4ccccc4)c4nccc2c43)N(c2ccccc2)c2ccnc3c2B5c2cnccc2N3c2ccccc2)cc1] 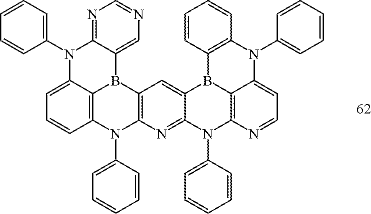 [SMILES: c1ccc(N2c3ccccc3B3c4cc5c(nc4N(c4ccccc4)c4nccc2c43)N(c2ccccc2)c2cccc3c2B5c2cncnc2N3c2ccccc2)cc1] 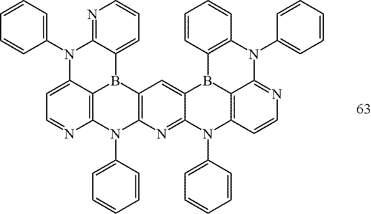 [SMILES: c1ccc(N2c3ccnc4c3B(c3ccccc3N4c3ccccc3)c3cc4c(nc32)N(c2ccccc2)c2nccc3c2B4c2cccnc2N3c2ccccc2)cc1] 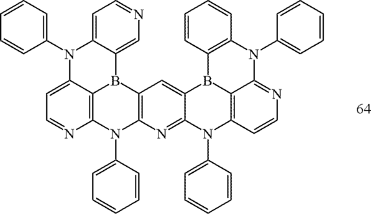 [SMILES: c1ccc(N2c3ccncc3B3c4cc5c(nc4N(c4ccccc4)c4nccc2c43)N(c2ccccc2)c2ccnc3c2B5c2ccccc2N3c2ccccc2)cc1] 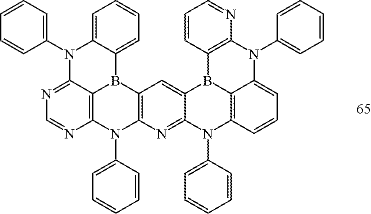 [SMILES: c1ccc(N2c3cccc4c3B(c3cccnc32)c2cc3c(nc2N4c2ccccc2)N(c2ccccc2)c2ncnc4c2B3c2ccccc2N4c2ccccc2)cc1] 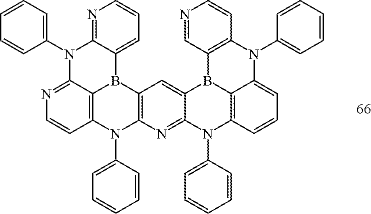 [SMILES: c1ccc(N2c3ccncc3B3c4cc5c(nc4N(c4ccccc4)c4cccc2c43)N(c2ccccc2)c2ccnc3c2B5c2cccnc2N3c2ccccc2)cc1] 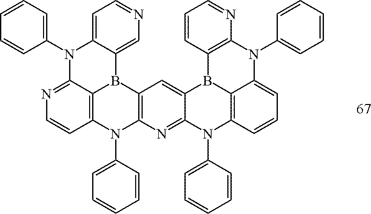 [SMILES: c1ccc(N2c3cccc4c3B(c3cccnc32)c2cc3c(nc2N4c2ccccc2)N(c2ccccc2)c2ccnc4c2B3c2cnccc2N4c2ccccc2)cc1] 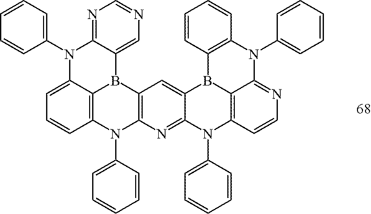 [SMILES: c1ccc(N2c3cccc4c3B(c3cncnc32)c2cc3c(nc2N4c2ccccc2)N(c2ccccc2)c2ccnc4c2B3c2ccccc2N4c2ccccc2)cc1] 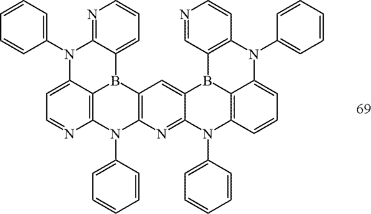 [SMILES: c1ccc(N2c3ccncc3B3c4cc5c(nc4N(c4ccccc4)c4cccc2c43)N(c2ccccc2)c2nccc3c2B5c2cccnc2N3c2ccccc2)cc1] 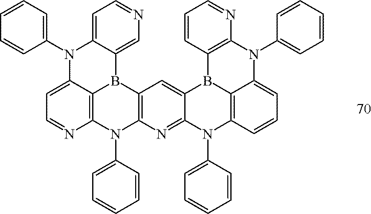 [SMILES: c1ccc(N2c3ccncc3B3c4cc5c(nc4N(c4ccccc4)c4nccc2c43)N(c2ccccc2)c2cccc3c2B5c2cccnc2N3c2ccccc2)cc1] 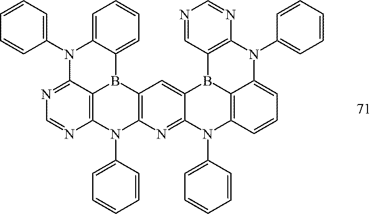 [SMILES: c1ccc(N2c3cccc4c3B(c3cncnc32)c2cc3c(nc2N4c2ccccc2)N(c2ccccc2)c2ncnc4c2B3c2ccccc2N4c2ccccc2)cc1] 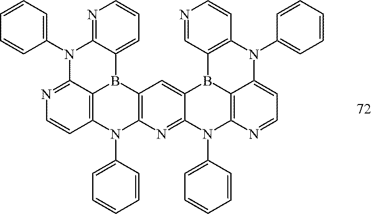 [SMILES: c1ccc(N2c3ccncc3B3c4cc5c(nc4N(c4ccccc4)c4nccc2c43)N(c2ccccc2)c2ccnc3c2B5c2cccnc2N3c2ccccc2)cc1] 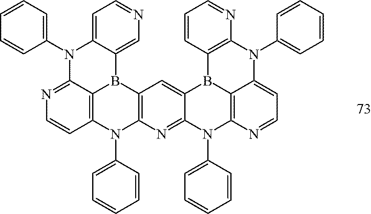 [SMILES: c1ccc(N2c3ccnc4c3B(c3cnccc3N4c3ccccc3)c3cc4c(nc32)N(c2ccccc2)c2nccc3c2B4c2cccnc2N3c2ccccc2)cc1] 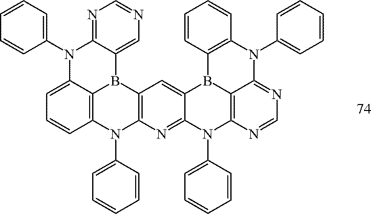 [SMILES: c1ccc(N2c3cccc4c3B(c3cncnc32)c2cc3c(nc2N4c2ccccc2)N(c2ccccc2)c2ncnc4c2B3c2ccccc2N4c2ccccc2)cc1] 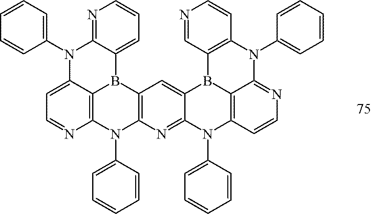 [SMILES: c1ccc(N2c3ccnc4c3B(c3cnccc3N4c3ccccc3)c3cc4c(nc32)N(c2ccccc2)c2nccc3c2B4c2cccnc2N3c2ccccc2)cc1] 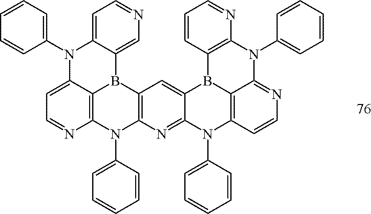 [SMILES: c1ccc(N2c3ccncc3B3c4cc5c(nc4N(c4ccccc4)c4nccc2c43)N(c2ccccc2)c2ccnc3c2B5c2cccnc2N3c2ccccc2)cc1] 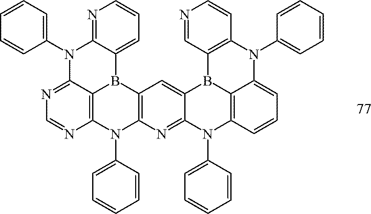 [SMILES: c1ccc(N2c3ccncc3B3c4cc5c(nc4N(c4ccccc4)c4cccc2c43)N(c2ccccc2)c2ncnc3c2B5c2cccnc2N3c2ccccc2)cc1] 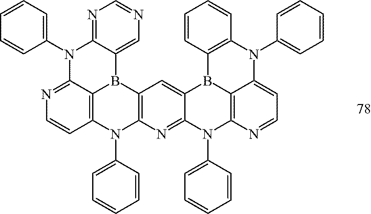 [SMILES: c1ccc(N2c3ccccc3B3c4cc5c(nc4N(c4ccccc4)c4nccc2c43)N(c2ccccc2)c2ccnc3c2B5c2cncnc2N3c2ccccc2)cc1] 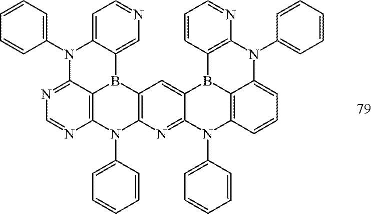 [SMILES: c1ccc(N2c3cccc4c3B(c3cccnc32)c2cc3c(nc2N4c2ccccc2)N(c2ccccc2)c2ncnc4c2B3c2cnccc2N4c2ccccc2)cc1] 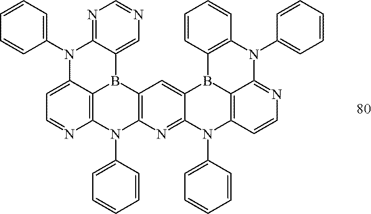 [SMILES: c1ccc(N2c3ccnc4c3B(c3ccccc3N4c3ccccc3)c3cc4c(nc32)N(c2ccccc2)c2nccc3c2B4c2cncnc2N3c2ccccc2)cc1] 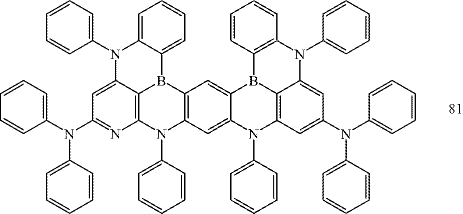 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)nc(c32)N5c2ccccc2)cc1] 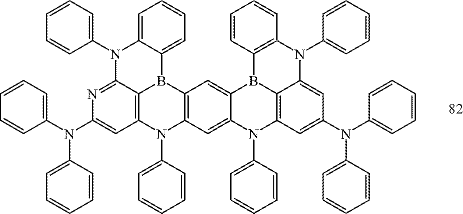 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3nc(N(c4ccccc4)c4ccccc4)cc(c32)N5c2ccccc2)cc1] 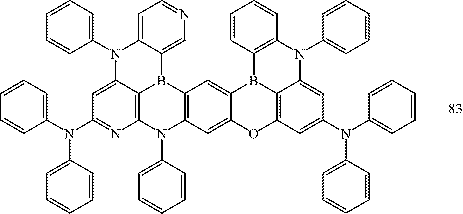 [SMILES: c1ccc(N(c2ccccc2)c2cc3c4c(c2)N(c2ccccc2)c2ccccc2B4c2cc4c(cc2O3)N(c2ccccc2)c2nc(N(c3ccccc3)c3ccccc3)cc3c2B4c2cnccc2N3c2ccccc2)cc1] 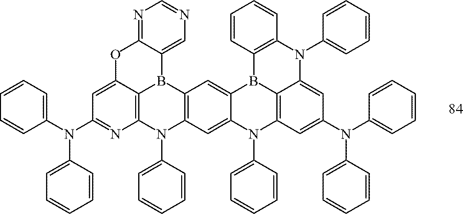 [SMILES: c1ccc(N(c2ccccc2)c2cc3c4c(c2)N(c2ccccc2)c2cc5c(cc2B4c2ccccc2N3c2ccccc2)B2c3cncnc3Oc3cc(N(c4ccccc4)c4ccccc4)nc(c32)N5c2ccccc2)cc1] 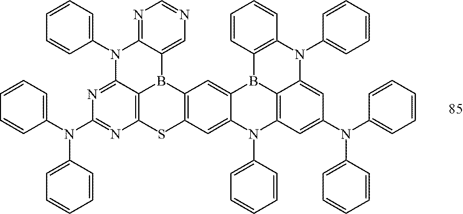 [SMILES: c1ccc(N(c2ccccc2)c2cc3c4c(c2)N(c2ccccc2)c2cc5c(cc2B4c2ccccc2N3c2ccccc2)B2c3cncnc3N(c3ccccc3)c3nc(N(c4ccccc4)c4ccccc4)nc(c32)S5)cc1] 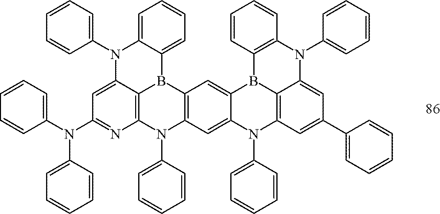 [SMILES: c1ccc(-c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)nc(c32)N5c2ccccc2)cc1] 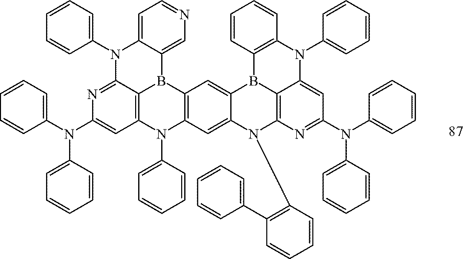 [SMILES: c1ccc(-c2ccccc2N2c3cc4c(cc3B3c5ccccc5N(c5ccccc5)c5cc(N(c6ccccc6)c6ccccc6)nc2c53)B2c3cnccc3N(c3ccccc3)c3nc(N(c5ccccc5)c5ccccc5)cc(c32)N4c2ccccc2)cc1] 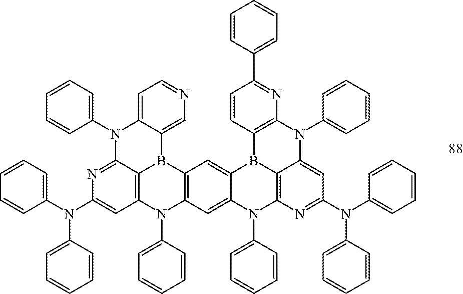 [SMILES: c1ccc(-c2ccc3c(n2)N(c2ccccc2)c2cc(N(c4ccccc4)c4ccccc4)nc4c2B3c2cc3c(cc2N4c2ccccc2)N(c2ccccc2)c2cc(N(c4ccccc4)c4ccccc4)nc4c2B3c2cnccc2N4c2ccccc2)cc1] 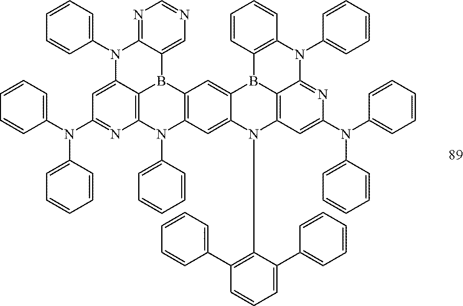 [SMILES: c1ccc(-c2cccc(-c3ccccc3)c2N2c3cc4c(cc3B3c5ccccc5N(c5ccccc5)c5nc(N(c6ccccc6)c6ccccc6)cc2c53)B2c3cncnc3N(c3ccccc3)c3cc(N(c5ccccc5)c5ccccc5)nc(c32)N4c2ccccc2)cc1] 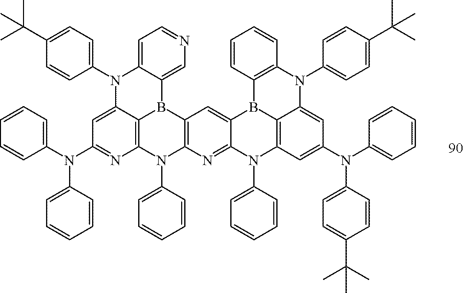 [SMILES: CC(C)(C)c1ccc(N(c2ccccc2)c2cc3c4c(c2)N(c2ccccc2)c2nc5c(cc2B4c2ccccc2N3c2ccc(C(C)(C)C)cc2)B2c3cnccc3N(c3ccc(C(C)(C)C)cc3)c3cc(N(c4ccccc4)c4ccccc4)nc(c32)N5c2ccccc2)cc1] 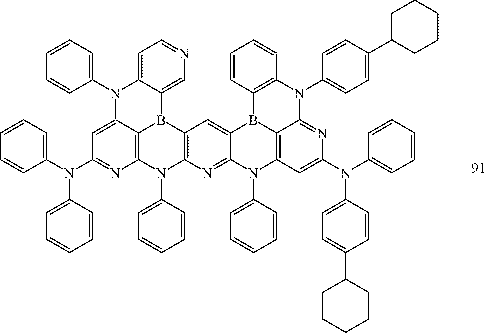 [SMILES: c1ccc(N(c2ccc(C3CCCCC3)cc2)c2cc3c4c(n2)N(c2ccc(C5CCCCC5)cc2)c2ccccc2B4c2cc4c(nc2N3c2ccccc2)N(c2ccccc2)c2nc(N(c3ccccc3)c3ccccc3)cc3c2B4c2cnccc2N3c2ccccc2)cc1] 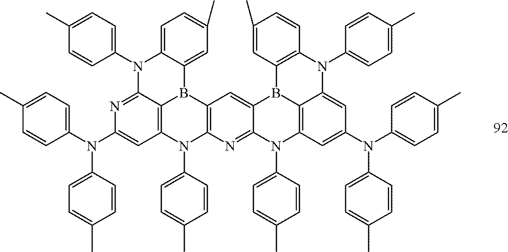 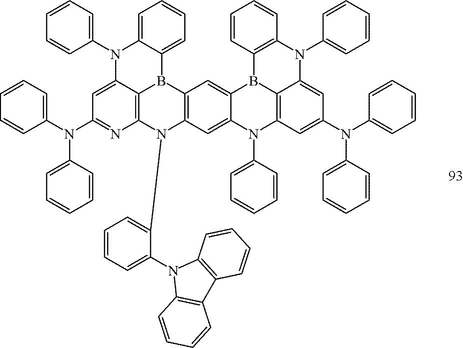 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)nc(c32)N5c2ccccc2-n2c3ccccc3c3ccccc32)cc1] 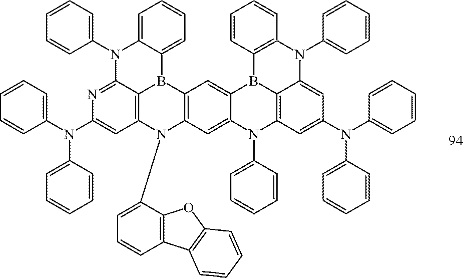 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3nc(N(c4ccccc4)c4ccccc4)cc(c32)N5c2cccc3c2oc2ccccc23)cc1] 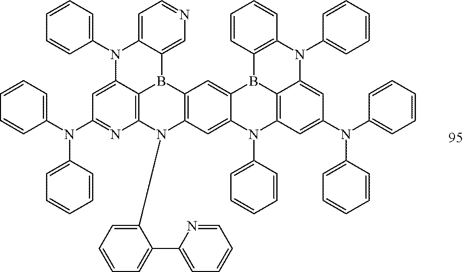 [SMILES: c1ccc(N(c2ccccc2)c2cc3c4c(c2)N(c2ccccc2)c2cc5c(cc2B4c2ccccc2N3c2ccccc2)B2c3cnccc3N(c3ccccc3)c3cc(N(c4ccccc4)c4ccccc4)nc(c32)N5c2ccccc2-c2ccccn2)cc1] 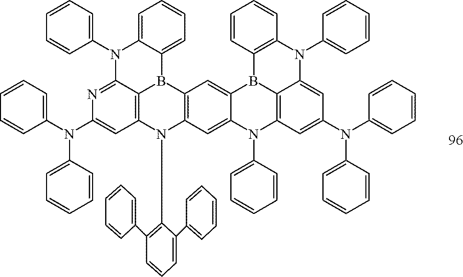 [SMILES: c1ccc(-c2cccc(-c3ccccc3)c2N2c3cc4c(cc3B3c5ccccc5N(c5ccccc5)c5nc(N(c6ccccc6)c6ccccc6)cc2c53)B2c3ccccc3N(c3ccccc3)c3cc(N(c5ccccc5)c5ccccc5)cc(c32)N4c2ccccc2)cc1] 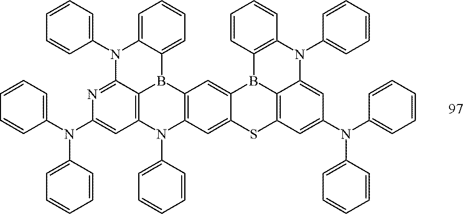 [SMILES: c1ccc(N(c2ccccc2)c2cc3c4c(c2)N(c2ccccc2)c2ccccc2B4c2cc4c(cc2S3)N(c2ccccc2)c2cc(N(c3ccccc3)c3ccccc3)nc3c2B4c2ccccc2N3c2ccccc2)cc1] 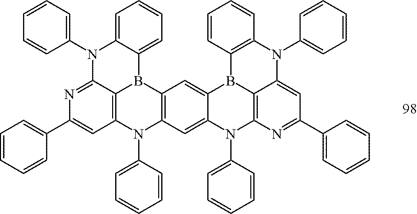 [SMILES: c1ccc(-c2cc3c4c(n2)N(c2ccccc2)c2ccccc2B4c2cc4c(cc2N3c2ccccc2)N(c2ccccc2)c2nc(-c3ccccc3)cc3c2B4c2ccccc2N3c2ccccc2)cc1] 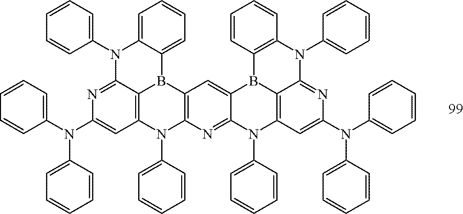 [SMILES: c1ccc(N(c2ccccc2)c2cc3c4c(n2)N(c2ccccc2)c2ccccc2B4c2cc4c(nc2N3c2ccccc2)N(c2ccccc2)c2cc(N(c3ccccc3)c3ccccc3)nc3c2B4c2ccccc2N3c2ccccc2)cc1] 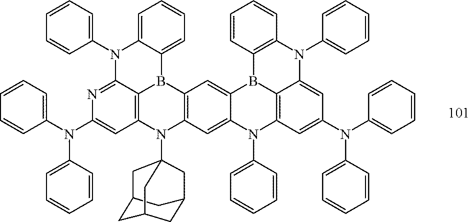 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3nc(N(c4ccccc4)c4ccccc4)cc(c32)N5C23CC4CC(CC(C4)C2)C3)cc1] 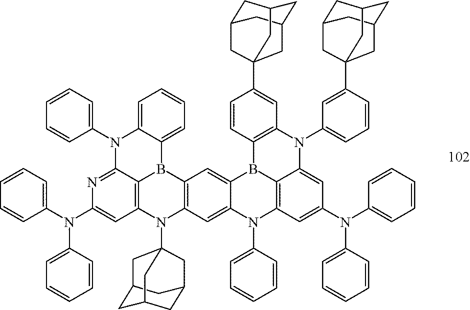 [SMILES: c1ccc(N(c2ccccc2)c2cc3c4c(c2)N(c2ccccc2)c2cc5c(cc2B4c2ccc(C46CC7CC(CC(C7)C4)C6)cc2N3c2cccc(C34CC6CC(CC(C6)C3)C4)c2)B2c3ccccc3N(c3ccccc3)c3nc(N(c4ccccc4)c4ccccc4)cc(c32)N5C23CC4CC(CC(C4)C2)C3)cc1] 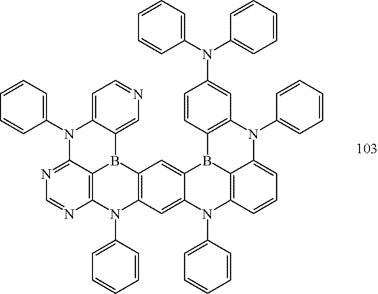 [SMILES: c1ccc(N(c2ccccc2)c2ccc3c(c2)N(c2ccccc2)c2cccc4c2B3c2cc3c(cc2N4c2ccccc2)N(c2ccccc2)c2ncnc4c2B3c2cnccc2N4c2ccccc2)cc1] 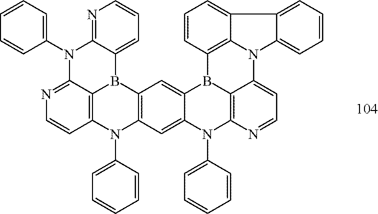 [SMILES: c1ccc(N2c3cc4c(cc3B3c5cccnc5N(c5ccccc5)c5nccc2c53)B2c3c(ccnc3N4c3ccccc3)-n3c4ccccc4c4cccc2c43)cc1] 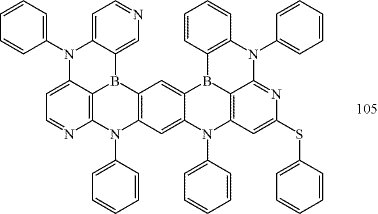 [SMILES: c1ccc(Sc2cc3c4c(n2)N(c2ccccc2)c2ccccc2B4c2cc4c(cc2N3c2ccccc2)N(c2ccccc2)c2nccc3c2B4c2cnccc2N3c2ccccc2)cc1] 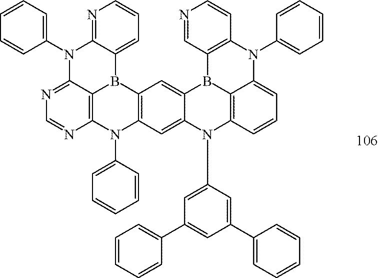 [SMILES: c1ccc(-c2cc(-c3ccccc3)cc(N3c4cc5c(cc4B4c6cnccc6N(c6ccccc6)c6cccc3c64)B3c4cccnc4N(c4ccccc4)c4ncnc(c43)N5c3ccccc3)c2)cc1] 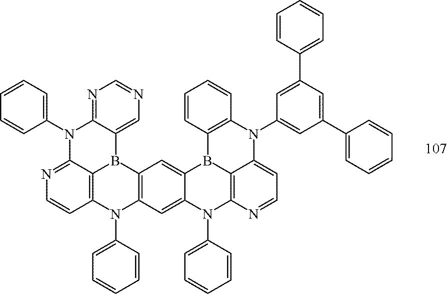 [SMILES: c1ccc(-c2cc(-c3ccccc3)cc(N3c4ccccc4B4c5cc6c(cc5N(c5ccccc5)c5nccc3c54)N(c3ccccc3)c3ccnc4c3B6c3cncnc3N4c3ccccc3)c2)cc1] 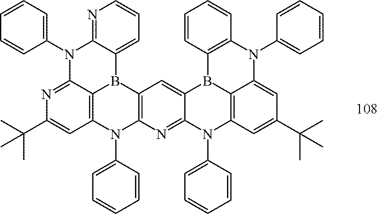 [SMILES: CC(C)(C)c1cc2c3c(c1)N(c1ccccc1)c1nc4c(cc1B3c1ccccc1N2c1ccccc1)B1c2cccnc2N(c2ccccc2)c2nc(C(C)(C)C)cc(c21)N4c1ccccc1] 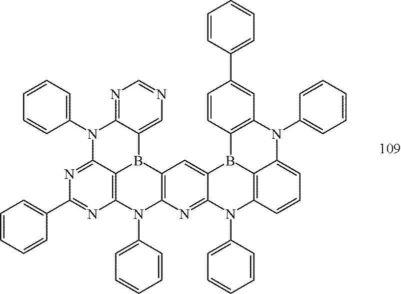 [SMILES: c1ccc(-c2ccc3c(c2)N(c2ccccc2)c2cccc4c2B3c2cc3c(nc2N4c2ccccc2)N(c2ccccc2)c2nc(-c4ccccc4)nc4c2B3c2cncnc2N4c2ccccc2)cc1] 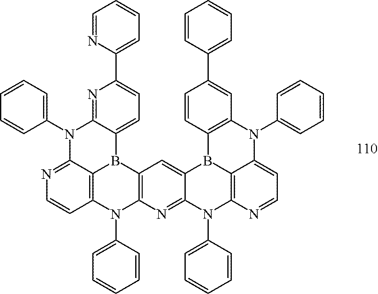 [SMILES: c1ccc(-c2ccc3c(c2)N(c2ccccc2)c2ccnc4c2B3c2cc3c(nc2N4c2ccccc2)N(c2ccccc2)c2ccnc4c2B3c2ccc(-c3ccccn3)nc2N4c2ccccc2)cc1] 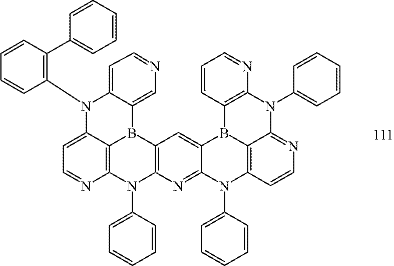 [SMILES: c1ccc(-c2ccccc2N2c3ccncc3B3c4cc5c(nc4N(c4ccccc4)c4nccc2c43)N(c2ccccc2)c2ccnc3c2B5c2cccnc2N3c2ccccc2)cc1] 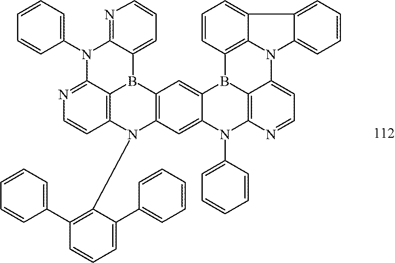 [SMILES: c1ccc(-c2cccc(-c3ccccc3)c2N2c3cc4c(cc3B3c5cccnc5N(c5ccccc5)c5nccc2c53)B2c3c(ccnc3N4c3ccccc3)-n3c4ccccc4c4cccc2c43)cc1] 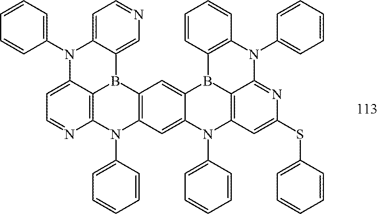 [SMILES: c1ccc(Sc2cc3c4c(n2)N(c2ccccc2)c2ccccc2B4c2cc4c(cc2N3c2ccccc2)N(c2ccccc2)c2nccc3c2B4c2cnccc2N3c2ccccc2)cc1] 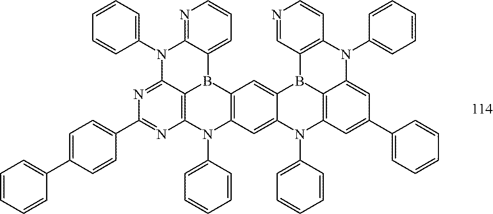 [SMILES: c1ccc(-c2ccc(-c3nc4c5c(n3)N(c3ccccc3)c3ncccc3B5c3cc5c(cc3N4c3ccccc3)N(c3ccccc3)c3cc(-c4ccccc4)cc4c3B5c3cnccc3N4c3ccccc3)cc2)cc1] 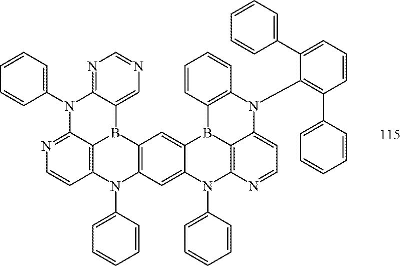 [SMILES: c1ccc(-c2cccc(-c3ccccc3)c2N2c3ccccc3B3c4cc5c(cc4N(c4ccccc4)c4nccc2c43)N(c2ccccc2)c2ccnc3c2B5c2cncnc2N3c2ccccc2)cc1] 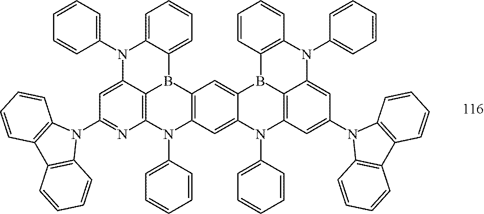 [SMILES: c1ccc(N2c3ccccc3B3c4cc5c(cc4N(c4ccccc4)c4cc(-n6c7ccccc7c7ccccc76)cc2c43)N(c2ccccc2)c2nc(-n3c4ccccc4c4ccccc43)cc3c2B5c2ccccc2N3c2ccccc2)cc1] 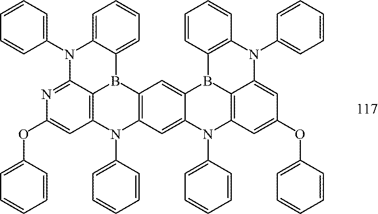 [SMILES: c1ccc(Oc2cc3c4c(c2)N(c2ccccc2)c2cc5c(cc2B4c2ccccc2N3c2ccccc2)B2c3ccccc3N(c3ccccc3)c3nc(Oc4ccccc4)cc(c32)N5c2ccccc2)cc1] 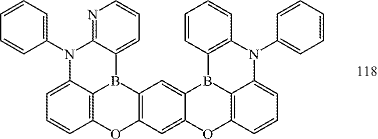 [SMILES: c1ccc(N2c3ccccc3B3c4cc5c(cc4Oc4cccc2c43)Oc2cccc3c2B5c2cccnc2N3c2ccccc2)cc1] 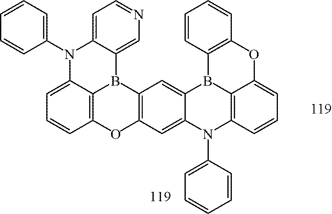 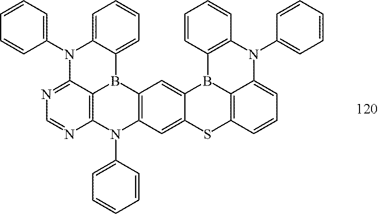 [SMILES: c1ccc(N2c3ccccc3B3c4cc5c(cc4Sc4cccc2c43)N(c2ccccc2)c2ncnc3c2B5c2ccccc2N3c2ccccc2)cc1] 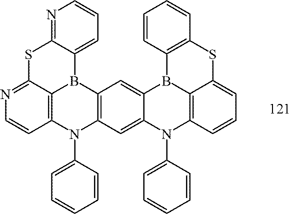 [SMILES: c1ccc(N2c3cc4c(cc3B3c5ccccc5Sc5cccc2c53)B2c3cccnc3Sc3nccc(c32)N4c2ccccc2)cc1] 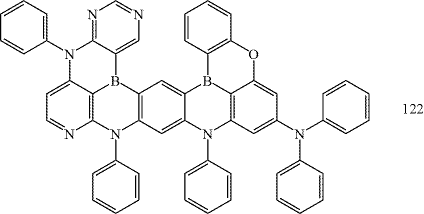 [SMILES: c1ccc(N(c2ccccc2)c2cc3c4c(c2)N(c2ccccc2)c2cc5c(cc2B4c2ccccc2O3)B2c3cncnc3N(c3ccccc3)c3ccnc(c32)N5c2ccccc2)cc1] 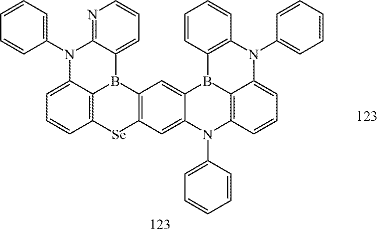 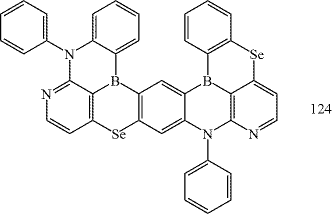 [SMILES: c1ccc(N2c3ccccc3B3c4cc5c(cc4[Se]c4ccnc2c43)N(c2ccccc2)c2nccc3c2B5c2ccccc2[Se]3)cc1] 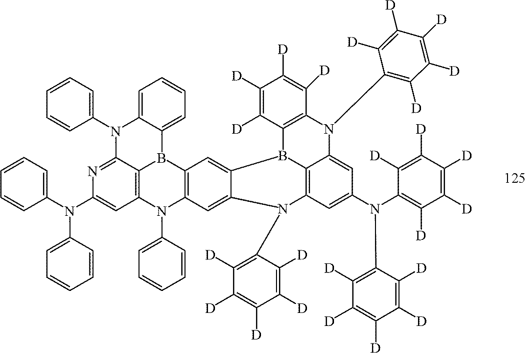 [SMILES: [2H]c1c([2H])c([2H])c(CN2c3cc4c(cc3B3c5c2cc(N(c2c([2H])c([2H])c([2H])c([2H])c2[2H])c2c([2H])c([2H])c([2H])c([2H])c2[2H])cc5N(c2c([2H])c([2H])c([2H])c([2H])c2[2H])c2c([2H])c([2H])c([2H])c([2H])c23)B2c3ccccc3N(c3ccccc3)c3nc(N(c5ccccc5)c5ccccc5)cc(c32)N4c2ccccc2)c([2H])c1[2H]] 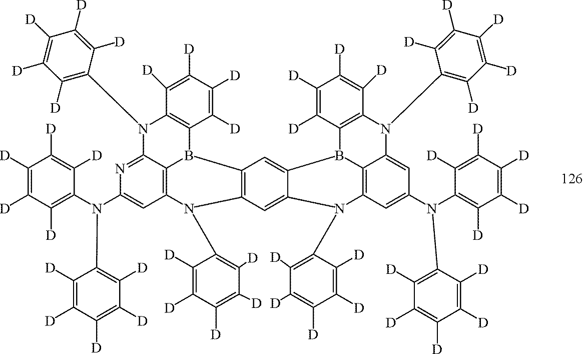 [SMILES: [2H]c1c([2H])c([2H])c(CN2c3cc4c(cc3B3c5c2cc(N(c2c([2H])c([2H])c([2H])c([2H])c2[2H])c2c([2H])c([2H])c([2H])c([2H])c2[2H])cc5N(c2c([2H])c([2H])c([2H])c([2H])c2[2H])c2c([2H])c([2H])c([2H])c([2H])c23)B2c3c(cc(N(c5c([2H])c([2H])c([2H])c([2H])c5[2H])c5c([2H])c([2H])c([2H])c([2H])c5[2H])nc3N(c3c([2H])c([2H])c([2H])c([2H])c3[2H])c3c([2H])c([2H])c([2H])c([2H])c32)N4Cc2c([2H])c([2H])c([2H])c([2H])c2[2H])c([2H])c1[2H]]
.

15. A polycyclic compound represented by Formula 1: 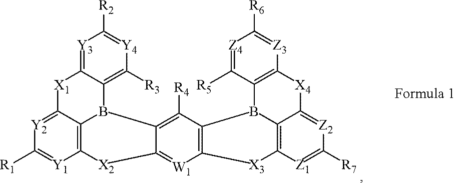
in Formula 1,
R₁ to R₇ are each independently a hydrogen atom, a deuterium atom, a substituted or unsubstituted oxy group, a substituted or unsubstituted thio group, a substituted or unsubstituted amino group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or combined with an adjacent group to form a ring,
X₁ to X₄ are each independently CRₐR_{b}, or NR_{c},
a case where X₁ to X₄ are all CRₐR_{b} is excluded,
at least one selected from among Y₁ to Y₄, Z₁ to Z₄, and W₁ is N, and the remainder of Y₁ to Y₄, Z₁ to Z₄, and W₁ are each independently CR_{d},
when W₁ is CR_{d}, a case where Y₁ and Z₁ are N at the same time, a case where Y₂ and Z₂ are N at the same time, a case where Y₃ and Z₃ are N at the same time, and a case where Y₄ and Z₄ are N at the same time are excluded, and
Rₐ to R_{d} are each independently a hydrogen atom, a deuterium atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or combined with an adjacent group to form a ring.

16. The polycyclic compound of claim 15, wherein the polycyclic compound represented by Formula 1 is represented by Formula 2-1 or Formula 2-2: 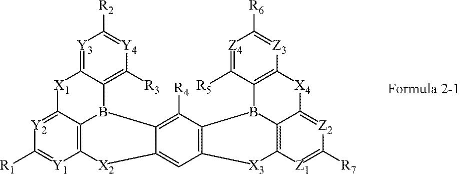 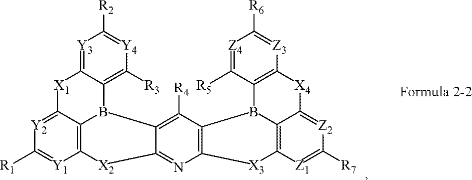
in Formula 2-1 and Formula 2-2, X₁ to X_{4,} Y₁ to Y₄, Z₁ to Z₄, and R₁ to R₇ are the same as defined in Formula 1.

17. The polycyclic compound of claim 15, wherein 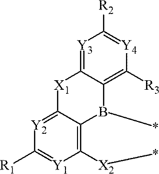
and 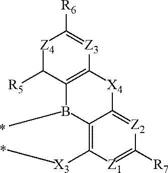
in Formula 2-1 are different from each other.

18. The polycyclic compound of claim 15, wherein the polycyclic compound represented by Formula 1 is represented by Formula 3: 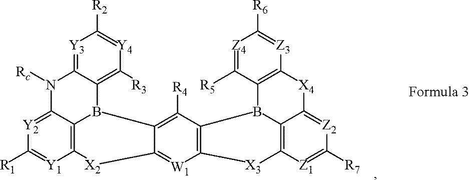
in Formula 3, W₁, X₂ to X₄, Y₁ to Y₄, Z₁ to Z₄, R₁ to R₇, and R_{c} are the same as defined in Formula 1.

19. The polycyclic compound of claim 15, wherein the polycyclic compound represented by Formula 1 is represented by Formula 4: 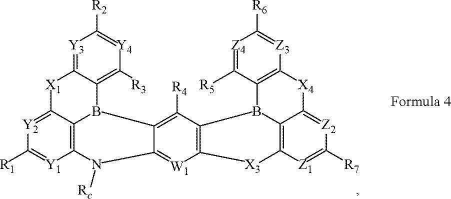
in Formula 4, W₁, X₁, X₂, X_{4,} Y₁ to Y₄, Z₁ to Z₄, R₁ to R₇, and R_{c} are the same as defined in Formula 1.

20. The polycyclic compound of claim 15, wherein the polycyclic compound represented by Formula 1 is represented by any one selected from among compounds represented in Compound Group 1:
Compound Group 1 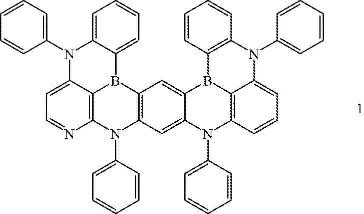 [SMILES: c1ccc(N2c3ccccc3B3c4cc5c(cc4N(c4ccccc4)c4cccc2c43)N(c2ccccc2)c2nccc3c2B5c2ccccc2N3c2ccccc2)cc1] 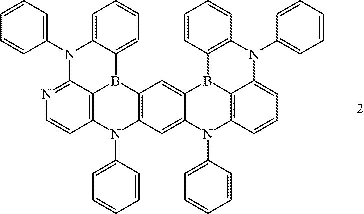 [SMILES: c1ccc(N2c3ccccc3B3c4cc5c(cc4N(c4ccccc4)c4cccc2c43)N(c2ccccc2)c2ccnc3c2B5c2ccccc2N3c2ccccc2)cc1] 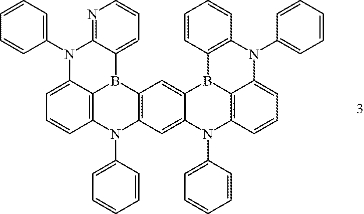 [SMILES: c1ccc(N2c3ccccc3B3c4cc5c(cc4N(c4ccccc4)c4cccc2c43)N(c2ccccc2)c2cccc3c2B5c2cccnc2N3c2ccccc2)cc1] 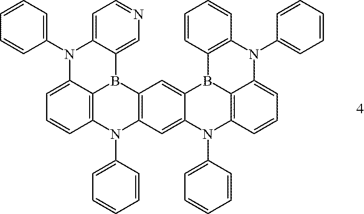 [SMILES: c1ccc(N2c3ccccc3B3c4cc5c(cc4N(c4ccccc4)c4cccc2c43)N(c2ccccc2)c2cccc3c2B5c2cnccc2N3c2ccccc2)cc1] 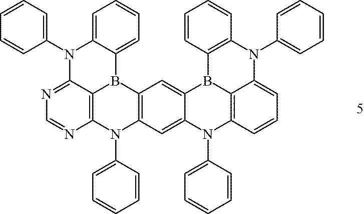 [SMILES: c1ccc(N2c3ccccc3B3c4cc5c(cc4N(c4ccccc4)c4cccc2c43)N(c2ccccc2)c2ncnc3c2B5c2ccccc2N3c2ccccc2)cc1] 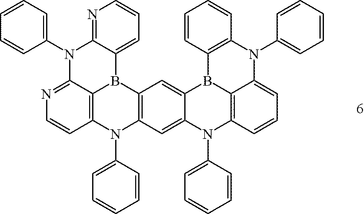 [SMILES: c1ccc(N2c3ccccc3B3c4cc5c(cc4N(c4ccccc4)c4cccc2c43)N(c2ccccc2)c2ccnc3c2B5c2cccnc2N3c2ccccc2)cc1] 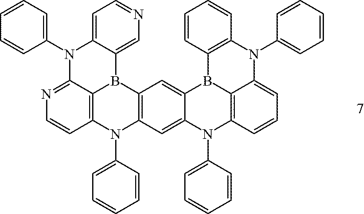 [SMILES: c1ccc(N2c3ccccc3B3c4cc5c(cc4N(c4ccccc4)c4cccc2c43)N(c2ccccc2)c2ccnc3c2B5c2cnccc2N3c2ccccc2)cc1] 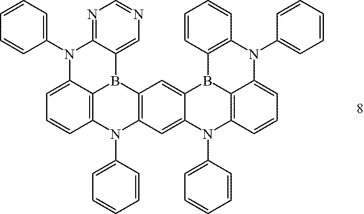 [SMILES: c1ccc(N2c3ccccc3B3c4cc5c(cc4N(c4ccccc4)c4cccc2c43)N(c2ccccc2)c2cccc3c2B5c2cncnc2N3c2ccccc2)cc1] 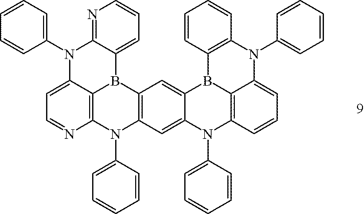 [SMILES: c1ccc(N2c3ccccc3B3c4cc5c(cc4N(c4ccccc4)c4cccc2c43)N(c2ccccc2)c2nccc3c2B5c2cccnc2N3c2ccccc2)cc1] 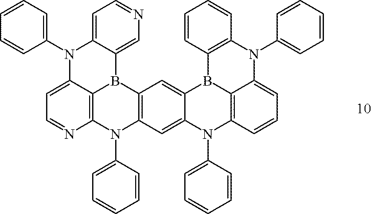 [SMILES: c1ccc(N2c3ccccc3B3c4cc5c(cc4N(c4ccccc4)c4cccc2c43)N(c2ccccc2)c2nccc3c2B5c2cnccc2N3c2ccccc2)cc1] 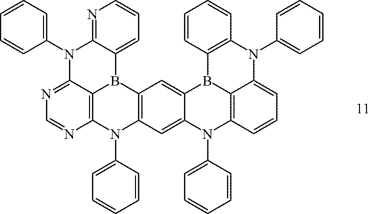 [SMILES: c1ccc(N2c3ccccc3B3c4cc5c(cc4N(c4ccccc4)c4cccc2c43)N(c2ccccc2)c2ncnc3c2B5c2cccnc2N3c2ccccc2)cc1] 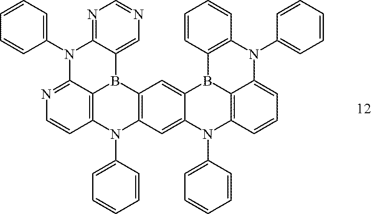 [SMILES: c1ccc(N2c3ccccc3B3c4cc5c(cc4N(c4ccccc4)c4cccc2c43)N(c2ccccc2)c2ccnc3c2B5c2cncnc2N3c2ccccc2)cc1] 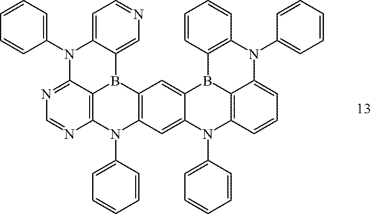 [SMILES: c1ccc(N2c3ccccc3B3c4cc5c(cc4N(c4ccccc4)c4cccc2c43)N(c2ccccc2)c2ncnc3c2B5c2cnccc2N3c2ccccc2)cc1] 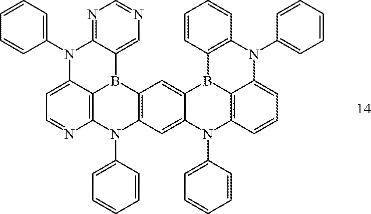 [SMILES: c1ccc(N2c3ccccc3B3c4cc5c(cc4N(c4ccccc4)c4cccc2c43)N(c2ccccc2)c2nccc3c2B5c2cncnc2N3c2ccccc2)cc1] 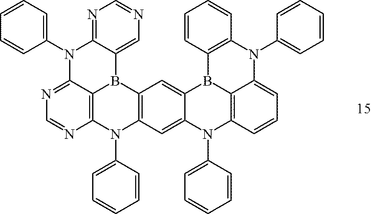 [SMILES: c1ccc(N2c3ccccc3B3c4cc5c(cc4N(c4ccccc4)c4cccc2c43)N(c2ccccc2)c2ncnc3c2B5c2cncnc2N3c2ccccc2)cc1] 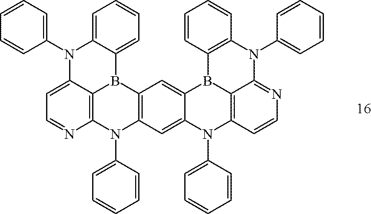 [SMILES: c1ccc(N2c3cc4c(cc3B3c5ccccc5N(c5ccccc5)c5nccc2c53)B2c3ccccc3N(c3ccccc3)c3ccnc(c32)N4c2ccccc2)cc1] 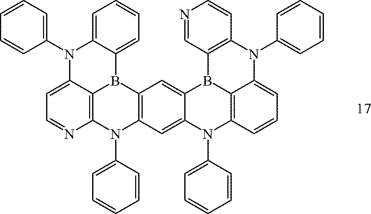 [SMILES: c1ccc(N2c3ccncc3B3c4cc5c(cc4N(c4ccccc4)c4cccc2c43)N(c2ccccc2)c2nccc3c2B5c2ccccc2N3c2ccccc2)cc1] 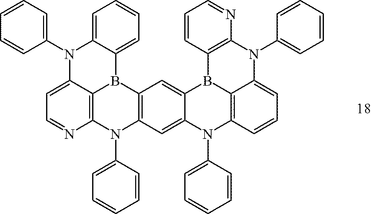 [SMILES: c1ccc(N2c3cc4c(cc3B3c5cccnc5N(c5ccccc5)c5cccc2c53)B2c3ccccc3N(c3ccccc3)c3ccnc(c32)N4c2ccccc2)cc1] 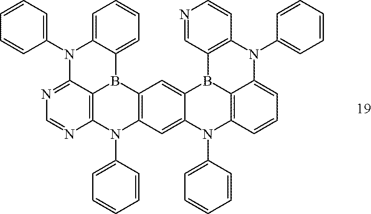 [SMILES: c1ccc(N2c3ccncc3B3c4cc5c(cc4N(c4ccccc4)c4cccc2c43)N(c2ccccc2)c2ncnc3c2B5c2ccccc2N3c2ccccc2)cc1] 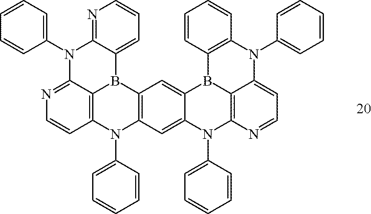 [SMILES: c1ccc(N2c3ccccc3B3c4cc5c(cc4N(c4ccccc4)c4nccc2c43)N(c2ccccc2)c2ccnc3c2B5c2cccnc2N3c2ccccc2)cc1] 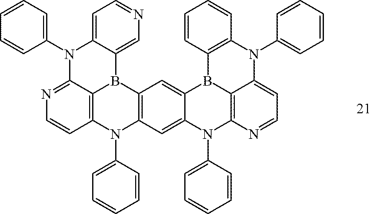 [SMILES: c1ccc(N2c3cc4c(cc3B3c5cnccc5N(c5ccccc5)c5nccc2c53)B2c3ccccc3N(c3ccccc3)c3ccnc(c32)N4c2ccccc2)cc1] 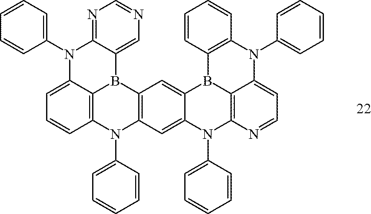 [SMILES: c1ccc(N2c3cc4c(cc3B3c5cncnc5N(c5ccccc5)c5cccc2c53)B2c3ccccc3N(c3ccccc3)c3ccnc(c32)N4c2ccccc2)cc1] 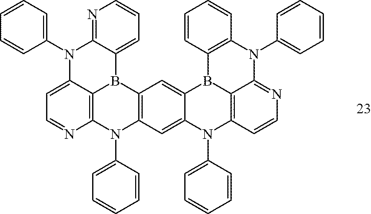 [SMILES: c1ccc(N2c3cc4c(cc3B3c5ccccc5N(c5ccccc5)c5nccc2c53)B2c3cccnc3N(c3ccccc3)c3ccnc(c32)N4c2ccccc2)cc1] 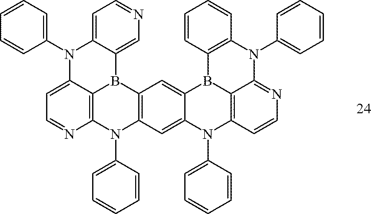 [SMILES: c1ccc(N2c3cc4c(cc3B3c5ccccc5N(c5ccccc5)c5nccc2c53)B2c3cnccc3N(c3ccccc3)c3ccnc(c32)N4c2ccccc2)cc1] 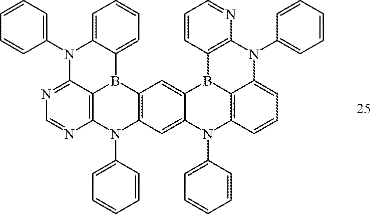 [SMILES: c1ccc(N2c3cc4c(cc3B3c5cccnc5N(c5ccccc5)c5cccc2c53)B2c3ccccc3N(c3ccccc3)c3ncnc(c32)N4c2ccccc2)cc1] 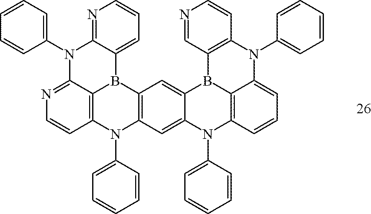 [SMILES: c1ccc(N2c3ccncc3B3c4cc5c(cc4N(c4ccccc4)c4cccc2c43)N(c2ccccc2)c2ccnc3c2B5c2cccnc2N3c2ccccc2)cc1] 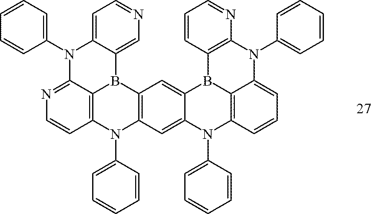 [SMILES: c1ccc(N2c3cc4c(cc3B3c5cccnc5N(c5ccccc5)c5cccc2c53)B2c3cnccc3N(c3ccccc3)c3nccc(c32)N4c2ccccc2)cc1] 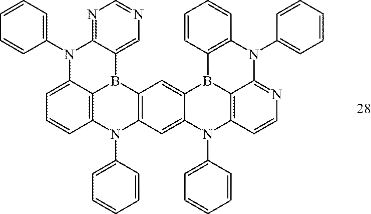 [SMILES: c1ccc(N2c3cc4c(cc3B3c5cncnc5N(c5ccccc5)c5cccc2c53)B2c3ccccc3N(c3ccccc3)c3nccc(c32)N4c2ccccc2)cc1] 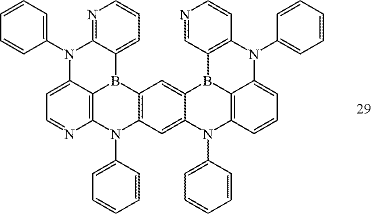 [SMILES: c1ccc(N2c3ccncc3B3c4cc5c(cc4N(c4ccccc4)c4cccc2c43)N(c2ccccc2)c2nccc3c2B5c2cccnc2N3c2ccccc2)cc1] 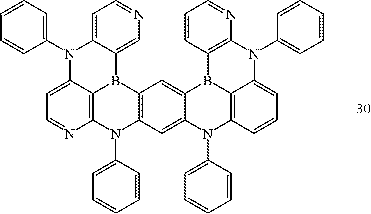 [SMILES: c1ccc(N2c3cc4c(cc3B3c5cccnc5N(c5ccccc5)c5cccc2c53)B2c3cnccc3N(c3ccccc3)c3ccnc(c32)N4c2ccccc2)cc1] 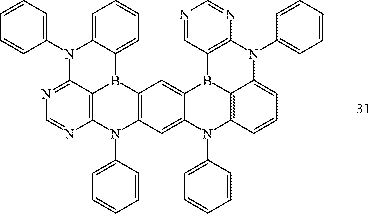 [SMILES: c1ccc(N2c3cc4c(cc3B3c5cncnc5N(c5ccccc5)c5cccc2c53)B2c3ccccc3N(c3ccccc3)c3ncnc(c32)N4c2ccccc2)cc1] 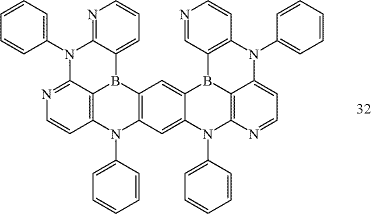 [SMILES: c1ccc(N2c3ccncc3B3c4cc5c(cc4N(c4ccccc4)c4nccc2c43)N(c2ccccc2)c2ccnc3c2B5c2cccnc2N3c2ccccc2)cc1] 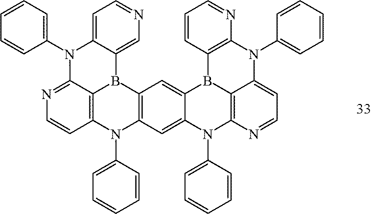 [SMILES: c1ccc(N2c3cc4c(cc3B3c5cnccc5N(c5ccccc5)c5nccc2c53)B2c3cccnc3N(c3ccccc3)c3ccnc(c32)N4c2ccccc2)cc1] 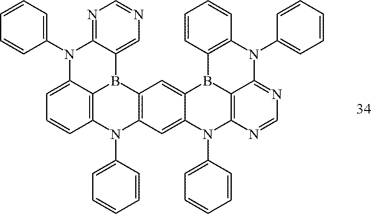 [SMILES: c1ccc(N2c3cc4c(cc3B3c5cncnc5N(c5ccccc5)c5cccc2c53)B2c3ccccc3N(c3ccccc3)c3ncnc(c32)N4c2ccccc2)cc1] 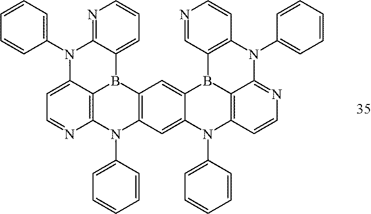 [SMILES: c1ccc(N2c3cc4c(cc3B3c5cnccc5N(c5ccccc5)c5nccc2c53)B2c3cccnc3N(c3ccccc3)c3ccnc(c32)N4c2ccccc2)cc1] 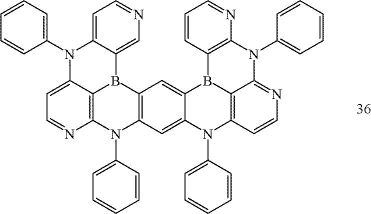 [SMILES: c1ccc(N2c3ccncc3B3c4cc5c(cc4N(c4ccccc4)c4nccc2c43)N(c2ccccc2)c2ccnc3c2B5c2cccnc2N3c2ccccc2)cc1] 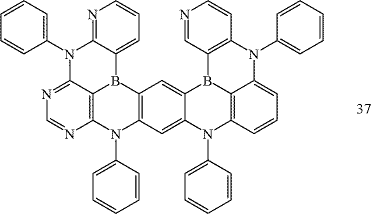 [SMILES: c1ccc(N2c3ccncc3B3c4cc5c(cc4N(c4ccccc4)c4cccc2c43)N(c2ccccc2)c2ncnc3c2B5c2cccnc2N3c2ccccc2)cc1] 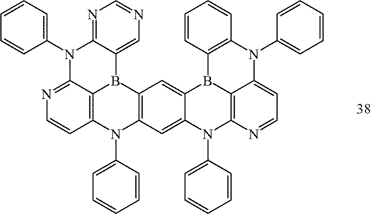 [SMILES: c1ccc(N2c3ccccc3B3c4cc5c(cc4N(c4ccccc4)c4nccc2c43)N(c2ccccc2)c2ccnc3c2B5c2cncnc2N3c2ccccc2)cc1] 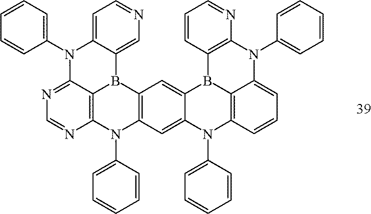 [SMILES: c1ccc(N2c3cc4c(cc3B3c5cccnc5N(c5ccccc5)c5cccc2c53)B2c3cnccc3N(c3ccccc3)c3ncnc(c32)N4c2ccccc2)cc1] 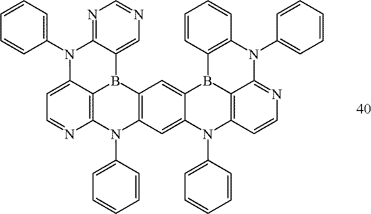 [SMILES: c1ccc(N2c3cc4c(cc3B3c5ccccc5N(c5ccccc5)c5nccc2c53)B2c3cncnc3N(c3ccccc3)c3ccnc(c32)N4c2ccccc2)cc1] 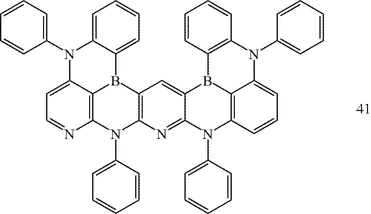 [SMILES: c1ccc(N2c3ccccc3B3c4cc5c(nc4N(c4ccccc4)c4cccc2c43)N(c2ccccc2)c2nccc3c2B5c2ccccc2N3c2ccccc2)cc1] 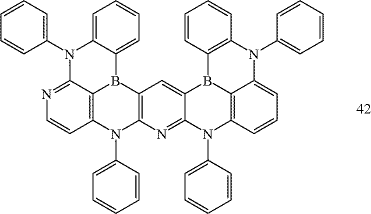 [SMILES: c1ccc(N2c3ccccc3B3c4cc5c(nc4N(c4ccccc4)c4cccc2c43)N(c2ccccc2)c2ccnc3c2B5c2ccccc2N3c2ccccc2)cc1] 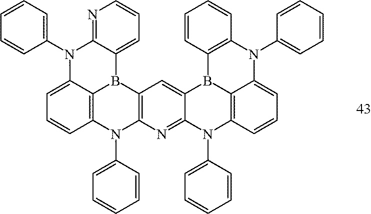 [SMILES: c1ccc(N2c3ccccc3B3c4cc5c(nc4N(c4ccccc4)c4cccc2c43)N(c2ccccc2)c2cccc3c2B5c2cccnc2N3c2ccccc2)cc1] 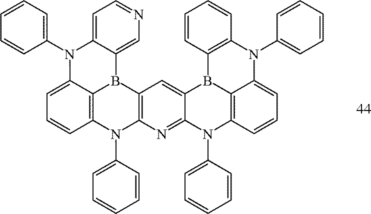 [SMILES: c1ccc(N2c3ccccc3B3c4cc5c(nc4N(c4ccccc4)c4cccc2c43)N(c2ccccc2)c2cccc3c2B5c2cnccc2N3c2ccccc2)cc1] 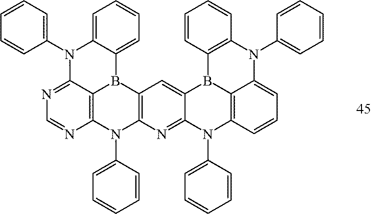 [SMILES: c1ccc(N2c3ccccc3B3c4cc5c(nc4N(c4ccccc4)c4cccc2c43)N(c2ccccc2)c2ncnc3c2B5c2ccccc2N3c2ccccc2)cc1] 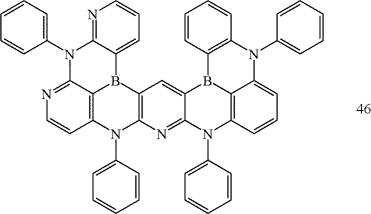 [SMILES: c1ccc(N2c3ccccc3B3c4cc5c(nc4N(c4ccccc4)c4cccc2c43)N(c2ccccc2)c2ccnc3c2B5c2cccnc2N3c2ccccc2)cc1] 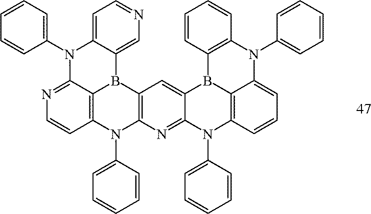 [SMILES: c1ccc(N2c3ccccc3B3c4cc5c(nc4N(c4ccccc4)c4cccc2c43)N(c2ccccc2)c2ccnc3c2B5c2cnccc2N3c2ccccc2)cc1] 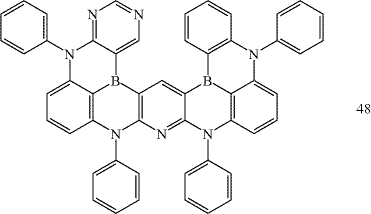 [SMILES: c1ccc(N2c3ccccc3B3c4cc5c(nc4N(c4ccccc4)c4cccc2c43)N(c2ccccc2)c2cccc3c2B5c2cncnc2N3c2ccccc2)cc1] 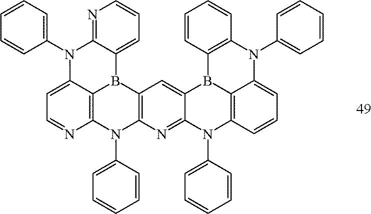 [SMILES: c1ccc(N2c3ccccc3B3c4cc5c(nc4N(c4ccccc4)c4cccc2c43)N(c2ccccc2)c2nccc3c2B5c2cccnc2N3c2ccccc2)cc1] 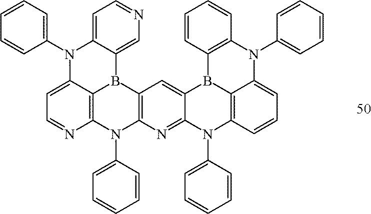 [SMILES: c1ccc(N2c3ccccc3B3c4cc5c(nc4N(c4ccccc4)c4cccc2c43)N(c2ccccc2)c2nccc3c2B5c2cnccc2N3c2ccccc2)cc1] 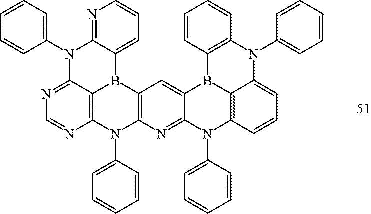 [SMILES: c1ccc(N2c3ccccc3B3c4cc5c(nc4N(c4ccccc4)c4cccc2c43)N(c2ccccc2)c2ncnc3c2B5c2cccnc2N3c2ccccc2)cc1] 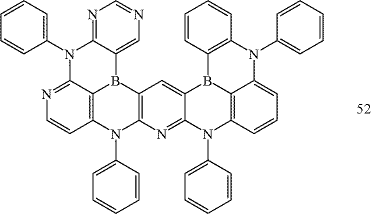 [SMILES: c1ccc(N2c3ccccc3B3c4cc5c(nc4N(c4ccccc4)c4cccc2c43)N(c2ccccc2)c2ccnc3c2B5c2cncnc2N3c2ccccc2)cc1] 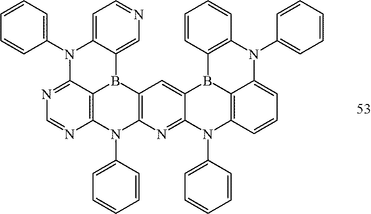 [SMILES: c1ccc(N2c3ccccc3B3c4cc5c(nc4N(c4ccccc4)c4cccc2c43)N(c2ccccc2)c2ncnc3c2B5c2cnccc2N3c2ccccc2)cc1] 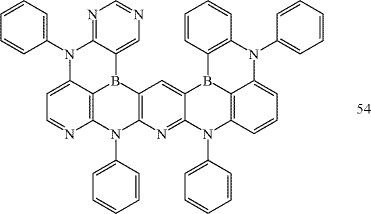 [SMILES: c1ccc(N2c3ccccc3B3c4cc5c(nc4N(c4ccccc4)c4cccc2c43)N(c2ccccc2)c2nccc3c2B5c2cncnc2N3c2ccccc2)cc1] 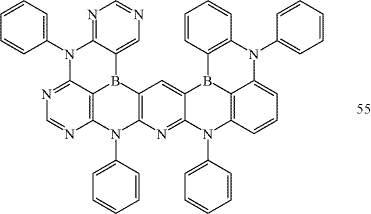 [SMILES: c1ccc(N2c3ccccc3B3c4cc5c(nc4N(c4ccccc4)c4cccc2c43)N(c2ccccc2)c2ncnc3c2B5c2cncnc2N3c2ccccc2)cc1] 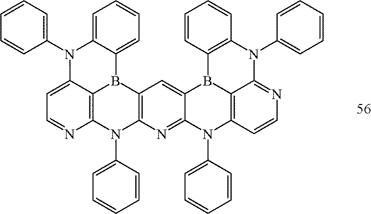 [SMILES: c1ccc(N2c3ccccc3B3c4cc5c(nc4N(c4ccccc4)c4nccc2c43)N(c2ccccc2)c2ccnc3c2B5c2ccccc2N3c2ccccc2)cc1] 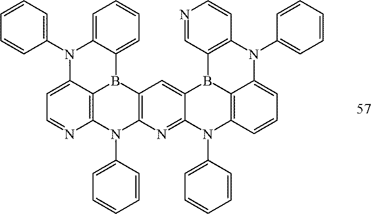 [SMILES: c1ccc(N2c3ccncc3B3c4cc5c(nc4N(c4ccccc4)c4cccc2c43)N(c2ccccc2)c2nccc3c2B5c2ccccc2N3c2ccccc2)cc1] 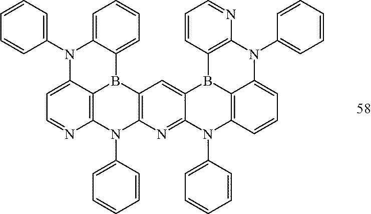 [SMILES: c1ccc(N2c3ccccc3B3c4cc5c(nc4N(c4ccccc4)c4nccc2c43)N(c2ccccc2)c2cccc3c2B5c2cccnc2N3c2ccccc2)cc1] 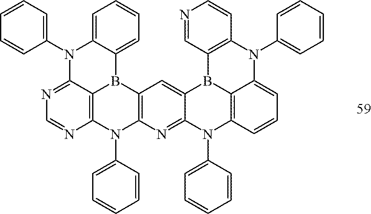 [SMILES: c1ccc(N2c3ccncc3B3c4cc5c(nc4N(c4ccccc4)c4cccc2c43)N(c2ccccc2)c2ncnc3c2B5c2ccccc2N3c2ccccc2)cc1] 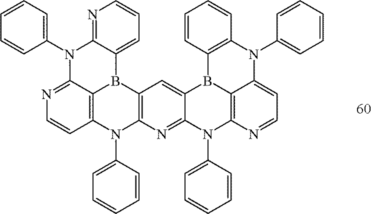 [SMILES: c1ccc(N2c3ccccc3B3c4cc5c(nc4N(c4ccccc4)c4nccc2c43)N(c2ccccc2)c2ccnc3c2B5c2cccnc2N3c2ccccc2)cc1] 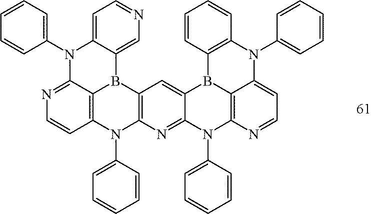 [SMILES: c1ccc(N2c3ccccc3B3c4cc5c(nc4N(c4ccccc4)c4nccc2c43)N(c2ccccc2)c2ccnc3c2B5c2cnccc2N3c2ccccc2)cc1] 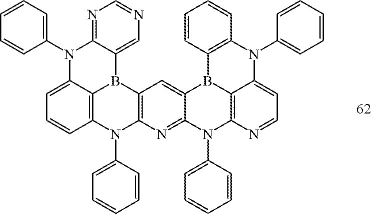 [SMILES: c1ccc(N2c3ccccc3B3c4cc5c(nc4N(c4ccccc4)c4nccc2c43)N(c2ccccc2)c2cccc3c2B5c2cncnc2N3c2ccccc2)cc1] 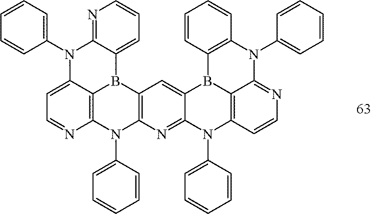 [SMILES: c1ccc(N2c3ccnc4c3B(c3ccccc3N4c3ccccc3)c3cc4c(nc32)N(c2ccccc2)c2nccc3c2B4c2cccnc2N3c2ccccc2)cc1] 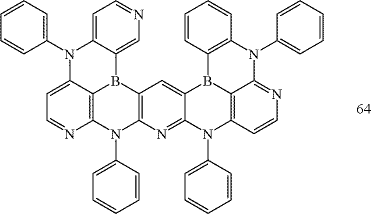 [SMILES: c1ccc(N2c3ccncc3B3c4cc5c(nc4N(c4ccccc4)c4nccc2c43)N(c2ccccc2)c2ccnc3c2B5c2ccccc2N3c2ccccc2)cc1] 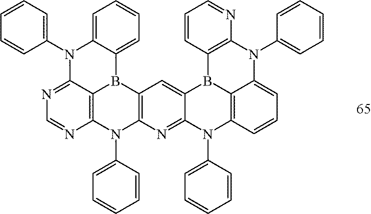 [SMILES: c1ccc(N2c3cccc4c3B(c3cccnc32)c2cc3c(nc2N4c2ccccc2)N(c2ccccc2)c2ncnc4c2B3c2ccccc2N4c2ccccc2)cc1] 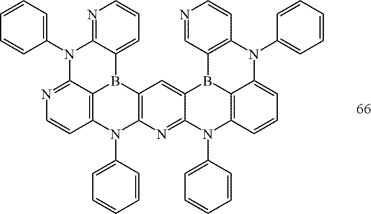 [SMILES: c1ccc(N2c3ccncc3B3c4cc5c(nc4N(c4ccccc4)c4cccc2c43)N(c2ccccc2)c2ccnc3c2B5c2cccnc2N3c2ccccc2)cc1] 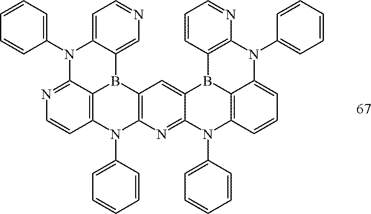 [SMILES: c1ccc(N2c3cccc4c3B(c3cccnc32)c2cc3c(nc2N4c2ccccc2)N(c2ccccc2)c2ccnc4c2B3c2cnccc2N4c2ccccc2)cc1] 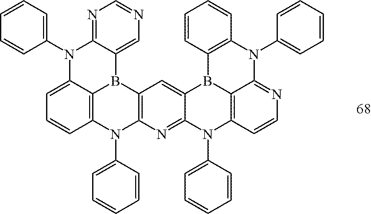 [SMILES: c1ccc(N2c3cccc4c3B(c3cncnc32)c2cc3c(nc2N4c2ccccc2)N(c2ccccc2)c2ccnc4c2B3c2ccccc2N4c2ccccc2)cc1] 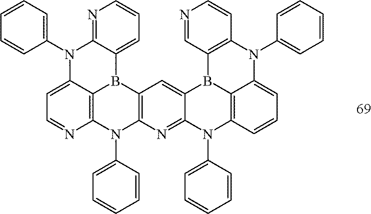 [SMILES: c1ccc(N2c3ccncc3B3c4cc5c(nc4N(c4ccccc4)c4cccc2c43)N(c2ccccc2)c2nccc3c2B5c2cccnc2N3c2ccccc2)cc1] 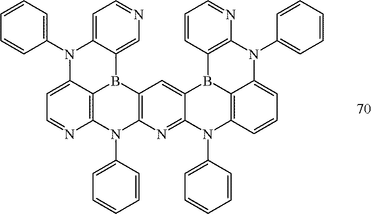 [SMILES: c1ccc(N2c3ccncc3B3c4cc5c(nc4N(c4ccccc4)c4nccc2c43)N(c2ccccc2)c2cccc3c2B5c2cccnc2N3c2ccccc2)cc1] 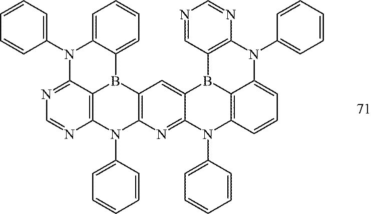 [SMILES: c1ccc(N2c3cccc4c3B(c3cncnc32)c2cc3c(nc2N4c2ccccc2)N(c2ccccc2)c2ncnc4c2B3c2ccccc2N4c2ccccc2)cc1] 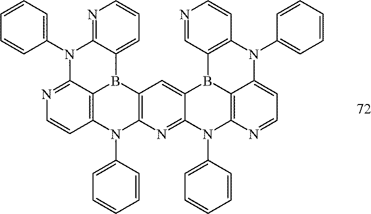 [SMILES: c1ccc(N2c3ccncc3B3c4cc5c(nc4N(c4ccccc4)c4nccc2c43)N(c2ccccc2)c2ccnc3c2B5c2cccnc2N3c2ccccc2)cc1] 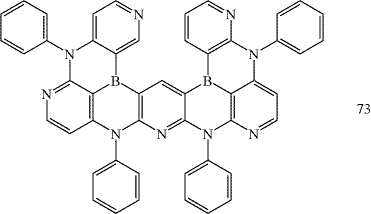 [SMILES: c1ccc(N2c3ccnc4c3B(c3cnccc3N4c3ccccc3)c3cc4c(nc32)N(c2ccccc2)c2nccc3c2B4c2cccnc2N3c2ccccc2)cc1] 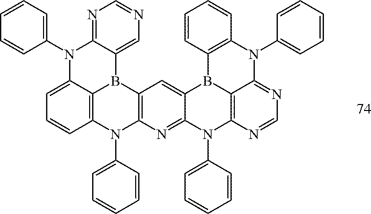 [SMILES: c1ccc(N2c3cccc4c3B(c3cncnc32)c2cc3c(nc2N4c2ccccc2)N(c2ccccc2)c2ncnc4c2B3c2ccccc2N4c2ccccc2)cc1] 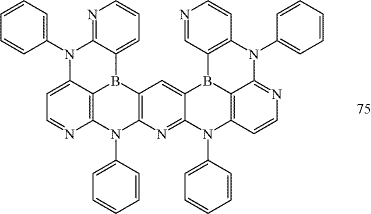 [SMILES: c1ccc(N2c3ccnc4c3B(c3cnccc3N4c3ccccc3)c3cc4c(nc32)N(c2ccccc2)c2nccc3c2B4c2cccnc2N3c2ccccc2)cc1] 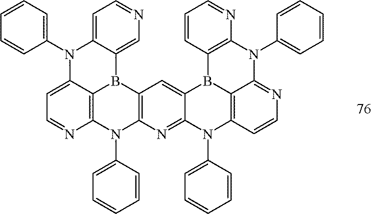 [SMILES: c1ccc(N2c3ccncc3B3c4cc5c(nc4N(c4ccccc4)c4nccc2c43)N(c2ccccc2)c2ccnc3c2B5c2cccnc2N3c2ccccc2)cc1] 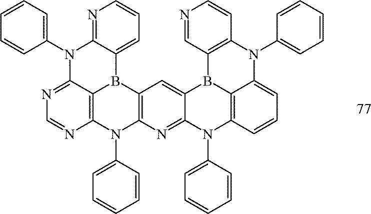 [SMILES: c1ccc(N2c3ccncc3B3c4cc5c(nc4N(c4ccccc4)c4cccc2c43)N(c2ccccc2)c2ncnc3c2B5c2cccnc2N3c2ccccc2)cc1] 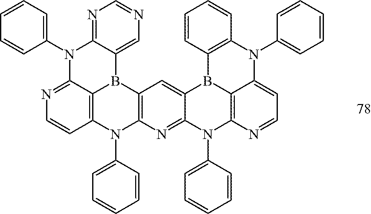 [SMILES: c1ccc(N2c3ccccc3B3c4cc5c(nc4N(c4ccccc4)c4nccc2c43)N(c2ccccc2)c2ccnc3c2B5c2cncnc2N3c2ccccc2)cc1] 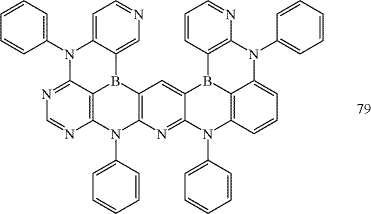 [SMILES: c1ccc(N2c3cccc4c3B(c3cccnc32)c2cc3c(nc2N4c2ccccc2)N(c2ccccc2)c2ncnc4c2B3c2cnccc2N4c2ccccc2)cc1] 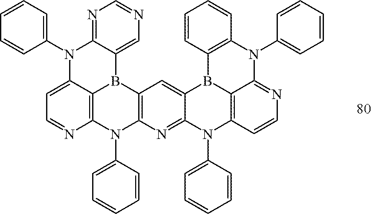 [SMILES: c1ccc(N2c3ccnc4c3B(c3ccccc3N4c3ccccc3)c3cc4c(nc32)N(c2ccccc2)c2nccc3c2B4c2cncnc2N3c2ccccc2)cc1] 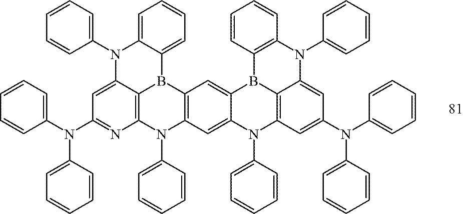 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)nc(c32)N5c2ccccc2)cc1] 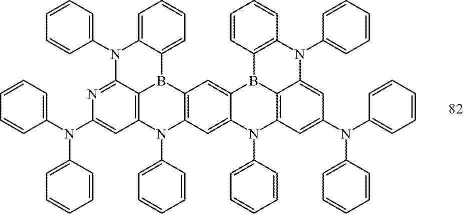 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3nc(N(c4ccccc4)c4ccccc4)cc(c32)N5c2ccccc2)cc1] 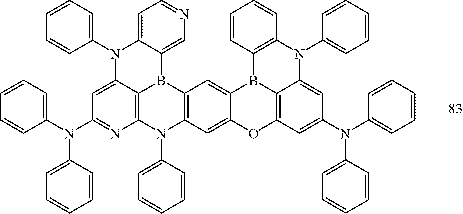 [SMILES: c1ccc(N(c2ccccc2)c2cc3c4c(c2)N(c2ccccc2)c2ccccc2B4c2cc4c(cc2O3)N(c2ccccc2)c2nc(N(c3ccccc3)c3ccccc3)cc3c2B4c2cnccc2N3c2ccccc2)cc1] 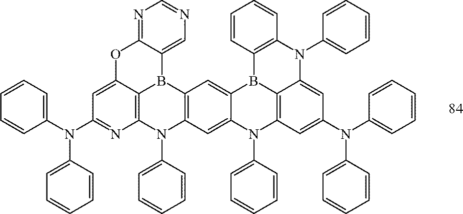 [SMILES: c1ccc(N(c2ccccc2)c2cc3c4c(c2)N(c2ccccc2)c2cc5c(cc2B4c2ccccc2N3c2ccccc2)B2c3cncnc3Oc3cc(N(c4ccccc4)c4ccccc4)nc(c32)N5c2ccccc2)cc1] 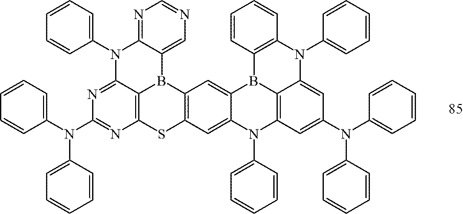 [SMILES: c1ccc(N(c2ccccc2)c2cc3c4c(c2)N(c2ccccc2)c2cc5c(cc2B4c2ccccc2N3c2ccccc2)B2c3cncnc3N(c3ccccc3)c3nc(N(c4ccccc4)c4ccccc4)nc(c32)S5)cc1] 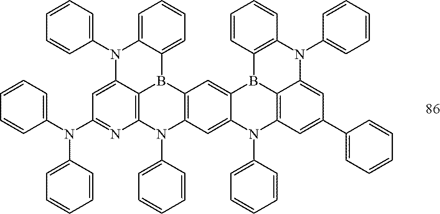 [SMILES: c1ccc(-c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)nc(c32)N5c2ccccc2)cc1] 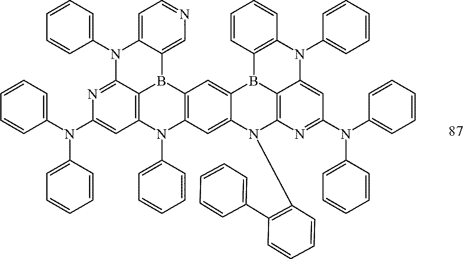 [SMILES: c1ccc(-c2ccccc2N2c3cc4c(cc3B3c5ccccc5N(c5ccccc5)c5cc(N(c6ccccc6)c6ccccc6)nc2c53)B2c3cnccc3N(c3ccccc3)c3nc(N(c5ccccc5)c5ccccc5)cc(c32)N4c2ccccc2)cc1] 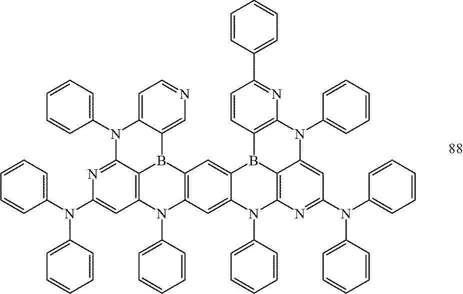 [SMILES: c1ccc(-c2ccc3c(n2)N(c2ccccc2)c2cc(N(c4ccccc4)c4ccccc4)nc4c2B3c2cc3c(cc2N4c2ccccc2)N(c2ccccc2)c2cc(N(c4ccccc4)c4ccccc4)nc4c2B3c2cnccc2N4c2ccccc2)cc1] 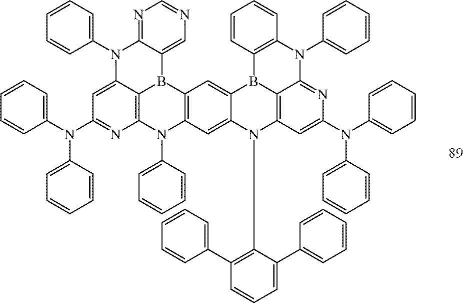 [SMILES: c1ccc(-c2cccc(-c3ccccc3)c2N2c3cc4c(cc3B3c5ccccc5N(c5ccccc5)c5nc(N(c6ccccc6)c6ccccc6)cc2c53)B2c3cncnc3N(c3ccccc3)c3cc(N(c5ccccc5)c5ccccc5)nc(c32)N4c2ccccc2)cc1] 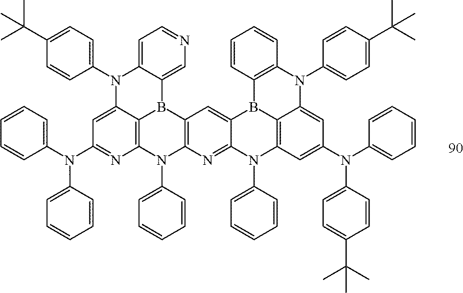 [SMILES: CC(C)(C)c1ccc(N(c2ccccc2)c2cc3c4c(c2)N(c2ccccc2)c2nc5c(cc2B4c2ccccc2N3c2ccc(C(C)(C)C)cc2)B2c3cnccc3N(c3ccc(C(C)(C)C)cc3)c3cc(N(c4ccccc4)c4ccccc4)nc(c32)N5c2ccccc2)cc1] 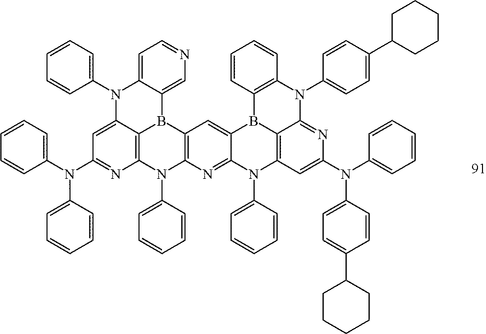 [SMILES: c1ccc(N(c2ccc(C3CCCCC3)cc2)c2cc3c4c(n2)N(c2ccc(C5CCCCC5)cc2)c2ccccc2B4c2cc4c(nc2N3c2ccccc2)N(c2ccccc2)c2nc(N(c3ccccc3)c3ccccc3)cc3c2B4c2cnccc2N3c2ccccc2)cc1] 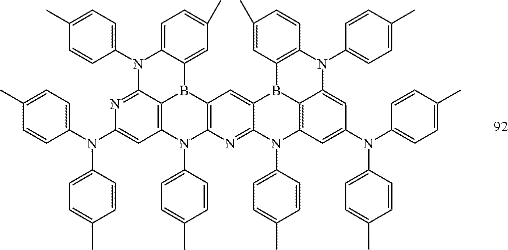 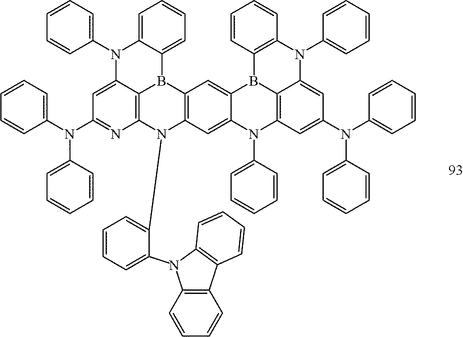 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)nc(c32)N5c2ccccc2-n2c3ccccc3c3ccccc32)cc1] 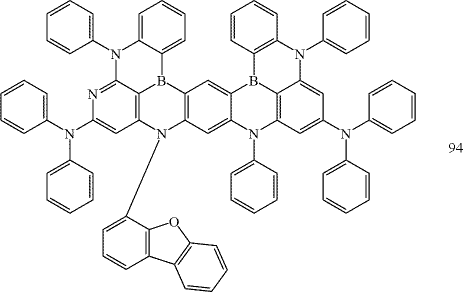 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3nc(N(c4ccccc4)c4ccccc4)cc(c32)N5c2cccc3c2oc2ccccc23)cc1] 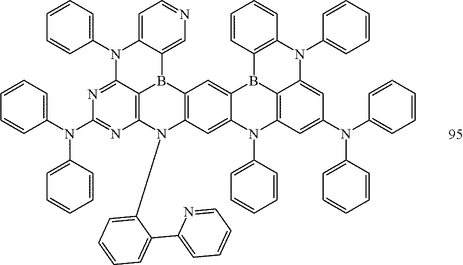 [SMILES: c1ccc(N(c2ccccc2)c2cc3c4c(c2)N(c2ccccc2)c2cc5c(cc2B4c2ccccc2N3c2ccccc2)B2c3cnccc3N(c3ccccc3)c3nc(N(c4ccccc4)c4ccccc4)nc(c32)N5c2ccccc2-c2ccccn2)cc1] 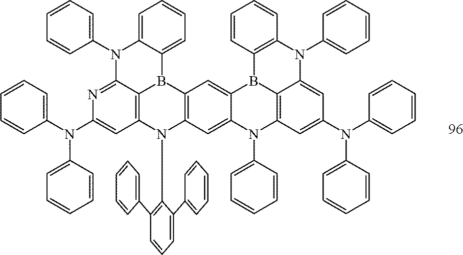 [SMILES: c1ccc(-c2cccc(-c3ccccc3)c2N2c3cc4c(cc3B3c5ccccc5N(c5ccccc5)c5nc(N(c6ccccc6)c6ccccc6)cc2c53)B2c3ccccc3N(c3ccccc3)c3cc(N(c5ccccc5)c5ccccc5)cc(c32)N4c2ccccc2)cc1] 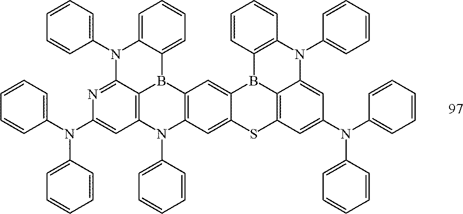 [SMILES: c1ccc(N(c2ccccc2)c2cc3c4c(c2)N(c2ccccc2)c2ccccc2B4c2cc4c(cc2S3)N(c2ccccc2)c2cc(N(c3ccccc3)c3ccccc3)nc3c2B4c2ccccc2N3c2ccccc2)cc1] 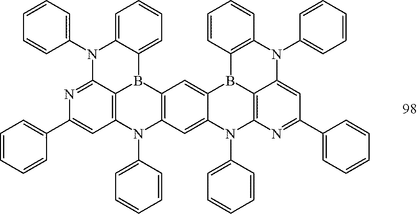 [SMILES: c1ccc(-c2cc3c4c(n2)N(c2ccccc2)c2ccccc2B4c2cc4c(cc2N3c2ccccc2)N(c2ccccc2)c2nc(-c3ccccc3)cc3c2B4c2ccccc2N3c2ccccc2)cc1] 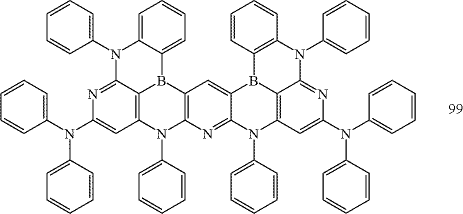 [SMILES: c1ccc(N(c2ccccc2)c2cc3c4c(n2)N(c2ccccc2)c2ccccc2B4c2cc4c(nc2N3c2ccccc2)N(c2ccccc2)c2cc(N(c3ccccc3)c3ccccc3)nc3c2B4c2ccccc2N3c2ccccc2)cc1] 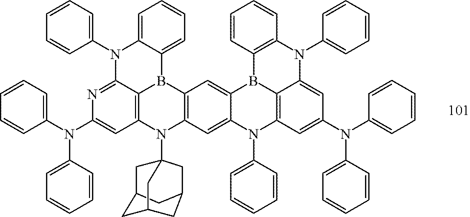 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3nc(N(c4ccccc4)c4ccccc4)cc(c32)N5C23CC4CC(CC(C4)C2)C3)cc1] 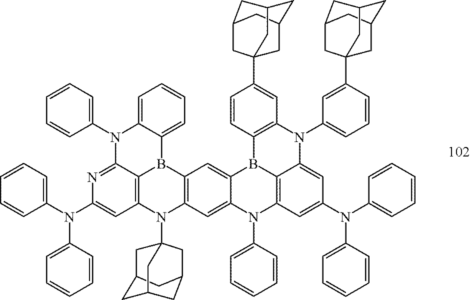 [SMILES: c1ccc(N(c2ccccc2)c2cc3c4c(c2)N(c2ccccc2)c2cc5c(cc2B4c2ccc(C46CC7CC(CC(C7)C4)C6)cc2N3c2cccc(C34CC6CC(CC(C6)C3)C4)c2)B2c3ccccc3N(c3ccccc3)c3nc(N(c4ccccc4)c4ccccc4)cc(c32)N5C23CC4CC(CC(C4)C2)C3)cc1] 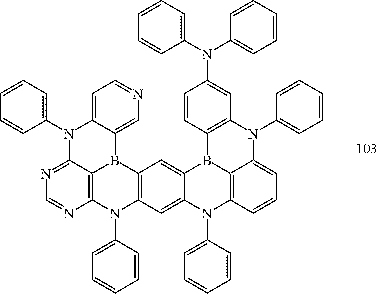 [SMILES: c1ccc(N(c2ccccc2)c2ccc3c(c2)N(c2ccccc2)c2cccc4c2B3c2cc3c(cc2N4c2ccccc2)N(c2ccccc2)c2ncnc4c2B3c2cnccc2N4c2ccccc2)cc1] 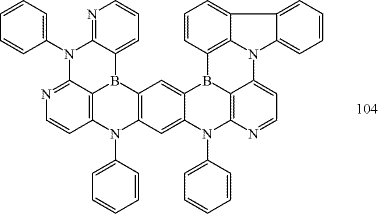 [SMILES: c1ccc(N2c3cc4c(cc3B3c5cccnc5N(c5ccccc5)c5nccc2c53)B2c3c(ccnc3N4c3ccccc3)-n3c4ccccc4c4cccc2c43)cc1] 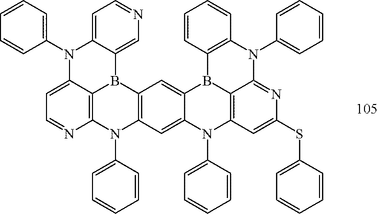 [SMILES: c1ccc(Sc2cc3c4c(n2)N(c2ccccc2)c2ccccc2B4c2cc4c(cc2N3c2ccccc2)N(c2ccccc2)c2nccc3c2B4c2cnccc2N3c2ccccc2)cc1] 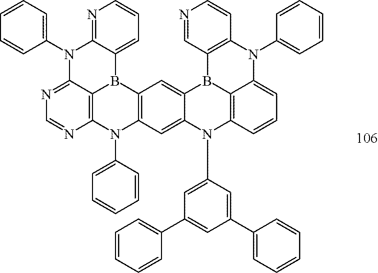 [SMILES: c1ccc(-c2cc(-c3ccccc3)cc(N3c4cc5c(cc4B4c6cnccc6N(c6ccccc6)c6cccc3c64)B3c4cccnc4N(c4ccccc4)c4ncnc(c43)N5c3ccccc3)c2)cc1] 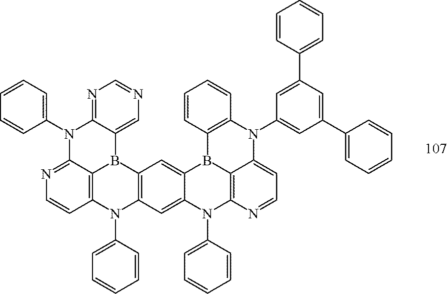 [SMILES: c1ccc(-c2cc(-c3ccccc3)cc(N3c4ccccc4B4c5cc6c(cc5N(c5ccccc5)c5nccc3c54)N(c3ccccc3)c3ccnc4c3B6c3cncnc3N4c3ccccc3)c2)cc1] 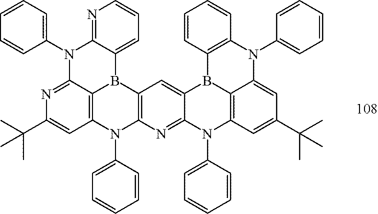 [SMILES: CC(C)(C)c1cc2c3c(c1)N(c1ccccc1)c1nc4c(cc1B3c1ccccc1N2c1ccccc1)B1c2cccnc2N(c2ccccc2)c2nc(C(C)(C)C)cc(c21)N4c1ccccc1] 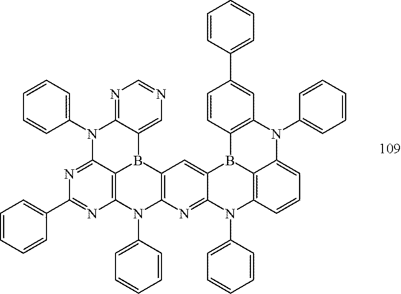 [SMILES: c1ccc(-c2ccc3c(c2)N(c2ccccc2)c2cccc4c2B3c2cc3c(nc2N4c2ccccc2)N(c2ccccc2)c2nc(-c4ccccc4)nc4c2B3c2cncnc2N4c2ccccc2)cc1] 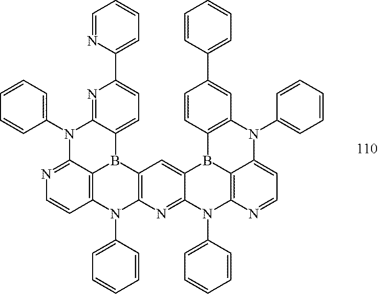 [SMILES: c1ccc(-c2ccc3c(c2)N(c2ccccc2)c2ccnc4c2B3c2cc3c(nc2N4c2ccccc2)N(c2ccccc2)c2ccnc4c2B3c2ccc(-c3ccccn3)nc2N4c2ccccc2)cc1] 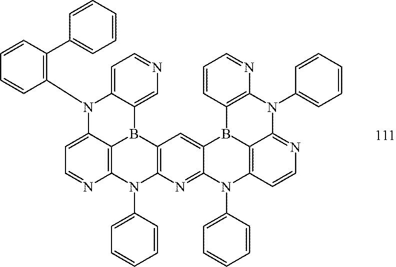 [SMILES: c1ccc(-c2ccccc2N2c3ccncc3B3c4cc5c(nc4N(c4ccccc4)c4nccc2c43)N(c2ccccc2)c2ccnc3c2B5c2cccnc2N3c2ccccc2)cc1] 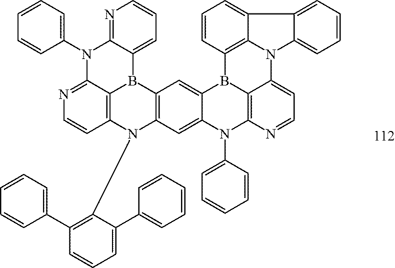 [SMILES: c1ccc(-c2cccc(-c3ccccc3)c2N2c3cc4c(cc3B3c5cccnc5N(c5ccccc5)c5nccc2c53)B2c3c(ccnc3N4c3ccccc3)-n3c4ccccc4c4cccc2c43)cc1] 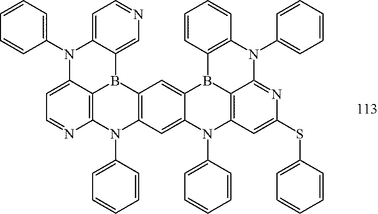 [SMILES: c1ccc(Sc2cc3c4c(n2)N(c2ccccc2)c2ccccc2B4c2cc4c(cc2N3c2ccccc2)N(c2ccccc2)c2nccc3c2B4c2cnccc2N3c2ccccc2)cc1] 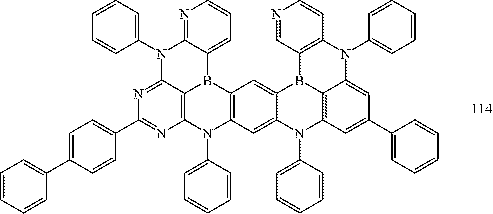 [SMILES: c1ccc(-c2ccc(-c3nc4c5c(n3)N(c3ccccc3)c3ncccc3B5c3cc5c(cc3N4c3ccccc3)N(c3ccccc3)c3cc(-c4ccccc4)cc4c3B5c3cnccc3N4c3ccccc3)cc2)cc1] 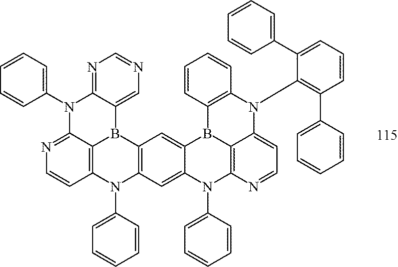 [SMILES: c1ccc(-c2cccc(-c3ccccc3)c2N2c3ccccc3B3c4cc5c(cc4N(c4ccccc4)c4nccc2c43)N(c2ccccc2)c2ccnc3c2B5c2cncnc2N3c2ccccc2)cc1] 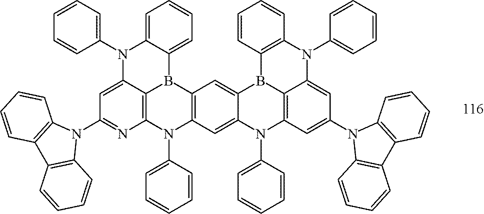 [SMILES: c1ccc(N2c3ccccc3B3c4cc5c(cc4N(c4ccccc4)c4cc(-n6c7ccccc7c7ccccc76)cc2c43)N(c2ccccc2)c2nc(-n3c4ccccc4c4ccccc43)cc3c2B5c2ccccc2N3c2ccccc2)cc1] 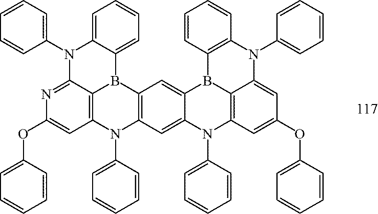 [SMILES: c1ccc(Oc2cc3c4c(c2)N(c2ccccc2)c2cc5c(cc2B4c2ccccc2N3c2ccccc2)B2c3ccccc3N(c3ccccc3)c3nc(Oc4ccccc4)cc(c32)N5c2ccccc2)cc1] 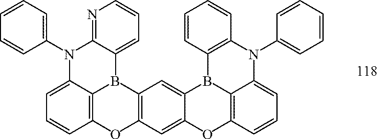 [SMILES: c1ccc(N2c3ccccc3B3c4cc5c(cc4Oc4cccc2c43)Oc2cccc3c2B5c2cccnc2N3c2ccccc2)cc1] 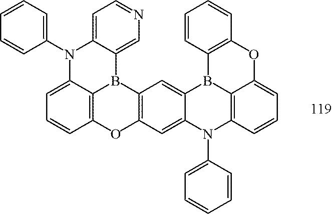 [SMILES: c1ccc(N2c3ccncc3B3c4cc5c(cc4Oc4cccc2c43)N(c2ccccc2)c2cccc3c2B5c2ccccc2O3)cc1] 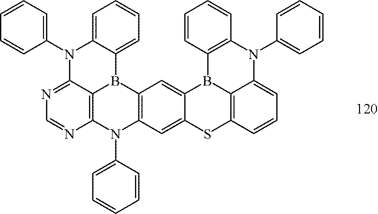 [SMILES: c1ccc(N2c3ccccc3B3c4cc5c(cc4Sc4cccc2c43)N(c2ccccc2)c2ncnc3c2B5c2ccccc2N3c2ccccc2)cc1] 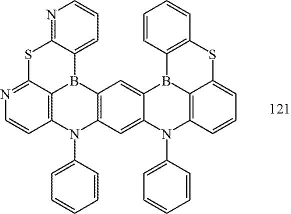 [SMILES: c1ccc(N2c3cc4c(cc3B3c5ccccc5Sc5cccc2c53)B2c3cccnc3Sc3nccc(c32)N4c2ccccc2)cc1] 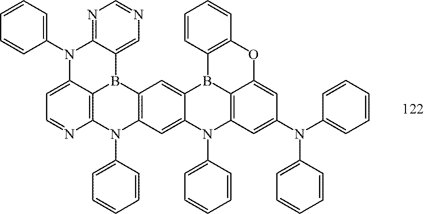 [SMILES: c1ccc(N(c2ccccc2)c2cc3c4c(c2)N(c2ccccc2)c2cc5c(cc2B4c2ccccc2O3)B2c3cncnc3N(c3ccccc3)c3ccnc(c32)N5c2ccccc2)cc1] 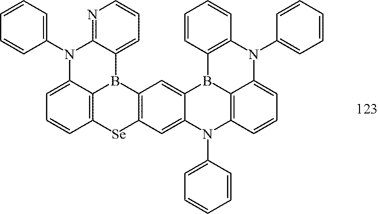 [SMILES: c1ccc(N2c3ccccc3B3c4cc5c(cc4N(c4ccccc4)c4cccc2c43)[Se]c2cccc3c2B5c2cccnc2N3c2ccccc2)cc1] 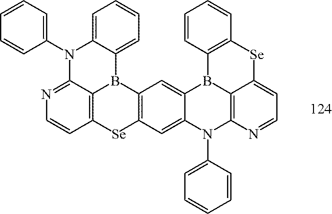 [SMILES: c1ccc(N2c3ccccc3B3c4cc5c(cc4[Se]c4ccnc2c43)N(c2ccccc2)c2nccc3c2B5c2ccccc2[Se]3)cc1] 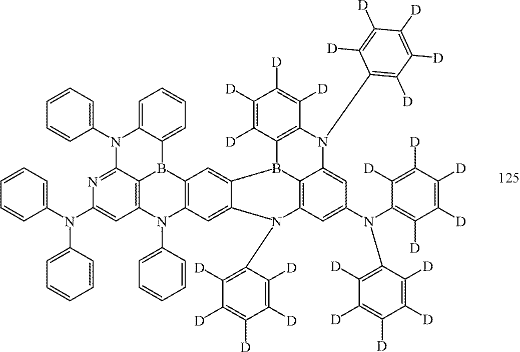 [SMILES: [2H]c1c([2H])c([2H])c(N2c3cc4c(cc3B3c5c2cc(N(c2c([2H])c([2H])c([2H])c([2H])c2[2H])c2c([2H])c([2H])c([2H])c([2H])c2[2H])cc5N(c2c([2H])c([2H])c([2H])c([2H])c2[2H])c2c([2H])c([2H])c([2H])c([2H])c23)B2c3ccccc3N(c3ccccc3)c3nc(N(c5ccccc5)c5ccccc5)cc(c32)N4c2ccccc2)c([2H])c1[2H]] 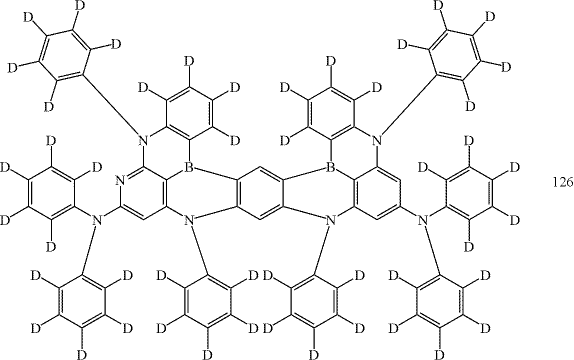 [SMILES: [2H]c1c([2H])c([2H])c(N2c3cc4c(cc3B3c5c2cc(N(c2c([2H])c([2H])c([2H])c([2H])c2[2H])c2c([2H])c([2H])c([2H])c([2H])c2[2H])cc5N(c2c([2H])c([2H])c([2H])c([2H])c2[2H])c2c([2H])c([2H])c([2H])c([2H])c23)B2c3c(cc(N(c5c([2H])c([2H])c([2H])c([2H])c5[2H])c5c([2H])c([2H])c([2H])c([2H])c5[2H])nc3N(c3c([2H])c([2H])c([2H])c([2H])c3[2H])c3c([2H])c([2H])c([2H])c([2H])c32)N4c2c([2H])c([2H])c([2H])c([2H])c2[2H])c([2H])c1[2H]]
.
